(19) United States
(12) Patent Application Publication
(10) Pub. No.: US 2017/0229591 A1
(43) Pub. Date: Aug. 10, 2017

(54) SYSTEMS AND METHODS FOR MONOLITHICALLY ISLED SOLAR PHOTOVOLTAIC CELLS AND MODULES

(71) Applicant: Solexel, Inc., Milpitas, CA (US)

(72) Inventor: Mehrdad M. Moslehi, Los Altos, CA (US)

(21) Appl. No.: 15/417,804

(22) Filed: Jan. 27, 2017

Related U.S. Application Data
(62) Division of application No. 14/072,759, filed on Nov. 5, 2013.
(60) Provisional application No. 61/722,620, filed on Nov. 5, 2012.

(51) Int. Cl. H01L 31/0224; H01L 31/048; H01L 31/0443; H02S 40/34; H02J 3/38; H01L 31/05; H02S 20/25

(52) U.S. Cl. CPC H01L 31/02245; H01L 31/0516; H01L 31/048; H02S 20/25; H02S 40/34; H02J 3/385; H01L 31/0443

(57) ABSTRACT

According to one aspect of the disclosed subject matter, a monolithically isled solar cell is provided. The solar cell comprises a semiconductor layer having a light receiving frontside and a backside opposite the frontside and attached to an electrically insulating backplane. A trench isolation pattern partitions the semiconductor layer into electrically isolated isles on the electrically insulating backplane. A first metal layer having base and emitter electrodes is positioned on the semiconductor layer backside. A patterned second metal layer providing cell interconnection and connected to the first metal layer by via plugs is positioned on the backplane.

### CROSS-REFERENCE TO RELATED APPLICATIONS

This application is a divisional of U.S. application Ser. No. 14/072,759 filed Nov. 5, 2013 which claims the benefit of U.S. Provisional Application No. 61/722,620 filed on Nov. 5, 2012, which are all hereby incorporated by reference in their entirety.

### FIELD OF THE INVENTION

The present disclosure relates in general to the fields of solar photovoltaic (PV) cells and modules, and more particularly to monolithically isled or tiled photovoltaic (PV) solar cells and associated modules providing numerous benefits.

### BACKGROUND

Crystalline silicon photovoltaic (PV) modules, as of 2012, account for approximately at least 85% of the overall global PV annual demand market and cumulative globally installed PV capacity. The manufacturing process for crystalline silicon PV is based on the use of crystalline silicon solar cells, starting with mono-crystalline or multi-crystalline silicon wafers made of czochralski (CZ) silicon ingots or cast silicon bricks. Non-crystalline-silicon-based thin film PV modules (for example CdTe, CIGS, organic, and amorphous silicon PV modules) may offer the potential for low cost manufacturing process but typically provide much lower conversion efficiencies (in the range of up to about 14% in STC module efficiency) for commercial thin-film PV modules as compared to the mainstream crystalline silicon PV modules (which may provide module efficiencies in the range of approximately 14% up to about 20%, and mostly in the range of about 14% to 17%), and an unproven long-term track record of field reliability as compared to well-established crystalline silicon solar PV modules. The leading-edge crystalline silicon PV modules offer superior overall energy conversion performance, long-term field reliability, non-toxicity, and life cycle sustainability compared to various other PV technologies. Moreover, recent progress and advancements have driven the overall manufacturing cost of crystalline silicon PV modules to below $0.80/Wp. Disruptive monocrystalline silicon technologies—such as high-efficiency thin monocrystalline silicon solar cells fabricated using reusable crystalline silicon templates, thin (e.g., crystalline silicon absorber thickness from approximately 10 μm up to about 100 μm, and typically ≦70 μm) epitaxial silicon, thin silicon support using backplane attachment/lamination, and porous silicon lift-off technology—offer the promise of high-efficiency (solar cell and/or module efficiencies of at least 20% under Standard Test Conditions or STC) and PV module manufacturing cost at well below $0.50/Wp at mass manufacturing scale.

Current crystalline silicon (or other semiconductor absorber material) solar cell structures and processing methods often suffer from several disadvantages relating to cell bow and cell cracking/breakage during and/or after cell processing as well as during the operation of crystalline silicon PV modules installed in the field. Solar cell processing often induces significant stresses (e.g., thermal and/or mechanical stresses) on a semiconductor substrate which may lead to thermally-induced warpage and crack generation and propagation (by thermal cycling or mechanical stresses). Bowed or non-planar solar cell substrates pose significant challenges and possible manufacturing yield degradation during solar cell processing (such as during processing of crystalline silicon solar cells), and may present requirements for clamping down the solar cell substrate and/or the substrate edges onto a supporting substrate carrier to flatten the cell substrate during manufacturing process. Flattening solutions may complicate the solar cell manufacturing process, resulting in increased manufacturing cost and/or some manufacturing throughput and yield compromises. Bowed or non-planar solar cell substrates may further result in cell microcracks and/or breakage problems during module lamination and also subsequently during the PV module operation in the field (resulting in PV module power degradation or loss). These problems may be further aggravated in larger area solar cells, such as the commonly used 156 mm×156 mm format (square or pseudo square) solar cells.

Further, conventional solar cells, particularly those based on an interdigitated back-contact or IBC design, often require relatively thick metallization patterns—due to the relatively high cell electrical current—which may add complexity to cell processing, increase material costs, and add significant physical stresses to the cell semiconductor material. Thermal and mechanical stresses induced by relatively thick (e.g., in the thickness range of 10's of microns for IBC cell metallization) metallization patterns on the solar cell frontside and/or backside, coupled with the coefficient of thermal expansion or CTE mismatch between conductive metals (e.g., plated copper used for IBC solar cells or screen-printed aluminum-containing and/or silver-containing metallization pastes used for conventional front-contact solar cells) and semiconductor materials (e.g., thin crystalline silicon absorber layer) may substantially increase the risk of producing microcracks, cell breakage, and cell bowing during cell processing (i.e., during and after cell metallization) and module processing (during and after cell-to-cell interconnections and module lamination assembly) as well as during field operation of the installed PV modules (i.e. due to weather conditions, temperature changes, wind-induced and/or snow-load-induced and/or installation-related module bending stresses).

Additionally, crystalline silicon modules often utilize relatively expensive external bypass diodes, which must be capable of handling relatively high forward-biased electrical currents in the range of approximately several amperes up to about 10 amperes and relatively high reverse bias voltages in the range of approximately 10 volts to 20 volts, in order to eliminate hot-spot effects caused by the partial or full shading of solar cells and to prevent the resulting potential solar cell and module reliability failures. Such shade-induced hot-spot phenomena, which are caused by reverse biasing of the shaded cell or cells in a PV module, may permanently damage the affected PV cells as well as the PV module encapsulation material and cell-to-cell interconnections, and even cause fire hazards, if the sunlight arriving at the surface of the PV cells in a PV module is partially blocked or not sufficiently uniform within the PV module—for instance, due to full or even partial shading of one or a plurality of solar cells. Bypass diodes are often placed on sub-strings of the PV module—typically one external bypass diode per sub-string of 20 solar cells in a standard 60-cell crystalline silicon solar module with three 20-cell sub-strings or one external bypass diode per sub-string of 24 solar cells in a 72-cell crystalline silicon solar module with three 24-cell sub-strings, while many other module formats and configurations with different numbers of embedded solar cells are possible for modules with any number of cells. This connection configuration with external bypass diodes across the series-connected cell strings prevents the reverse bias hot spots due to any shaded cells and enables the PV modules to operate with a relatively high degree of reliability throughout their lifetime under various real life shading or partial shading and soiling conditions. In the absence of solar cell shading or soiling, each cell in the string essentially acts as an electrical current source with relatively matched electrical current values with the other cells in the series-connected string of cells, with the external bypass diode in the sub-string being reversed biased with the total voltage of the sub-string in the module (for example, 20 cells in a series-connected string create approximately about 10V to 12V reverse bias across the bypass diode in a crystalline silicon PV system). With shading of a cell in a string, the shaded cell is reverse biased, turning on the bypass diode for the sub-string containing the shaded cell, thereby allowing the current from the good/non-shaded solar cells in the non-shaded sub-strings to flow in the external bypass circuit. While the external bypass diodes (typically three external bypass diodes included in the standard mainstream 60-cell crystalline silicon PV module junction box) protect the PV module and cells in case of shading of the cells, they can also actually result in significant loss of power harvesting and energy yield for the installed PV systems.

### BRIEF SUMMARY OF THE INVENTION

Therefore, a need has arisen for high efficiency solar cell fabrication methods and designs. In accordance with the disclosed subject matter, methods and structures for monolithically isled solar cells and modules are provided. These innovations substantially reduce or eliminate disadvantages and problems associated with previously developed solar cells.

According to one aspect of the disclosed subject matter, a monolithically isled solar cell is provided. The solar cell comprises a semiconductor layer having a light receiving frontside and a backside opposite the frontside and attached to an electrically insulating backplane. A trench isolation pattern partitions the semiconductor layer into electrically isolated isles on the electrically insulating backplane. A first metal layer having base and emitter electrodes is positioned on the semiconductor layer backside. A patterned second metal layer providing cell interconnection and connected to the first metal layer by via plugs is positioned on the backplane.

Technical advantages of the innovative aspects disclosed herein include but are not limited to: enhanced flexibility and crack mitigation; reduced cell bow and improved planarity; scaled-up voltage and scaled-down cell current, resulting in reduced ohmic losses; and, a reduction in cell metallization thickness requirements.

These and other advantages of the disclosed subject matter, as well as additional novel features, will be apparent from the description provided herein. The intent of this summary is not to be a comprehensive description of the subject matter, but rather to provide a short overview of some of the subject matter's functionality. Other systems, methods, features and advantages here provided will become apparent to one with skill in the art upon examination of the following FIGURES and detailed description. It is intended that all such additional systems, methods, features and advantages included within this description be within the scope of the claims.

### BRIEF DESCRIPTION OF THE DRAWINGS

The features, natures, and advantages of the disclosed subject matter may become more apparent from the detailed description set forth below when taken in conjunction with the drawings in which like reference numerals indicate like features and wherein:

FIG. 1 is a top view diagram of a square-shaped single isle master cell;

FIG. 2 is a top view diagram of a square-shaped 4×4 isled square master cell (or isled cell “icell”);

FIGS. 3A and 3B are cross-sectional diagrams showing a backplane-attached solar cell after solar cell processing steps including isolation trench formation;

FIG. 4 is a representative process flow for the fabrication of backplane-attached solar cells using epitaxial silicon lift-off processing;

FIGS. 5A through 5C are manufacturing process flows for the formation of back-contact back-junction solar cells. FIG. 5A shows a process flow based on epitaxial silicon and porous silicon lift-off processing, FIG. 5B shows a process flow based on starting crystalline silicon wafers, and FIG. 5C shows a process flow based on epitaxial silicon and lift-off processing;

FIGS. 5D and 5E are cross-sectional diagrams showing a backplane-attached solar cell;

FIGS. 6A and 6B are top view diagrams of a square-shaped 3×3 and 5×5 isled square icell, respectively;

FIGS. 7A and 7B are top view diagrams of embodiments a triangular-shaped 8 isled square icell;

FIGS. 7C, 7D, and 7E are top view diagrams of embodiments a triangular-shaped 16, 36, and 32 isled square icell, respectively;

FIG. 8 is a schematic diagram showing an equivalent circuit model of a typical solar cell with edge effects;

FIG. 9A is a backside view diagram showing a busbarless first metallization layer pattern (M1) formed on a square-shaped 4×4 isled icell and FIG. 9B is an expanded view of a portion of FIG. 9A;

FIGS. 10A and 10B are backside view diagrams showing a busbarless first metallization layer pattern (M1) formed on a square-shaped 3×3 and 5×5 isled icell, respectively;

FIG. 11A is a backside view diagram showing a busbarless first metallization layer pattern (M1) formed on a triangular-shaped 36 isled icell and FIG. 11B is an expanded view of a portion of FIG. 11A;

FIG. 12A is a backside view diagram showing a second metallization layer pattern (M2) formed on a square-shaped 5×5 isled icell and FIG. 12B is an expanded view of a portion of FIG. 12A;

FIG. 13 is a backside view diagram showing a second metallization layer pattern (M2) unit cell having interdigitated tapered base and emitter fingers;

FIG. 14A is a backside view diagram showing a second metallization layer pattern (M2) formed on a square-shaped 4×4 isled icell and FIG. 14B is an expanded view of a portion of FIG. 14A;

FIGS. 15A and 15B are backside view diagrams showing a second metallization layer pattern (M2) formed on a square-shaped 3×3 and 5×5 isled icell, respectively;

FIG. 16A is a top view diagram of an isled master cell (icell), each isle having a monolithically-integrated bypass switch (MIBS);

FIGS. 16B and 16C are cross-sectional diagrams detailing MIBS rim or full-periphery diode solar cell embodiments of the back-contact/back-junction solar cell for one isle (or unit cell such as I₁₁ in FIG. 16A);

FIG. 17 is a schematic diagram showing an all-series electrically connected icell;

FIGS. 18A and 18B are schematic diagrams showing an icell having an all-series electrically connected and hybrid parallel-series electrically connected 4×4 array of isles (the design of FIG. 18B referred to as 2×8HPS design);

FIG. 18C is a schematic diagram showing an icell having a hybrid parallel-series electrically connected 8×8 array of isles (referred to as 8×8HPS design);

FIGS. 19A, 19B, and 19C show position of a shade management switch on the icells of FIGS. 18A, 18B, and 18C, respectively;

FIG. 20 is a top view diagram of a pseudo-square shaped master cell substrate;

FIG. 21 is a schematic diagram showing a pseudo square-shaped icell having a hybrid parallel-series electrical connection;

FIG. 22 is a schematic diagram showing a pseudo square-shaped icell having an all-series electrical connection;

FIGS. 23A and 23B are schematic diagrams showing a master cell overview and the relative position of emitter and base busbars depending on the number of isles and M2 interconnection design;

FIGS. 24 through 27 are schematic diagrams depicting 60-cell module connection designs;

FIGS. 28A and 28B are schematic diagrams showing module connections for 600 VDC PV systems using 60-cell PV modules comprising all-series icells as compared to hybrid parallel-series icells; and

FIGS. 29A and 29B are schematic diagrams showing module connections for 1000 VDC PV systems using 60-cell PV modules comprising all-series icells as compared to hybrid parallel-series icells.

### DETAILED DESCRIPTION

The following description is not to be taken in a limiting sense, but is made for the purpose of describing the general principles of the present disclosure. The scope of the present disclosure should be determined with reference to the claims. Exemplary embodiments of the present disclosure are illustrated in the drawings, like numbers being used to refer to like and corresponding parts of the various drawings.

Importantly, the exemplary dimensions and calculations disclosed for embodiments are provided both as detailed descriptions for specific embodiments and to be used as general guidelines when forming and designing solar cells in accordance with the disclosed subject matter.

And although the present disclosure is described with reference to specific embodiments, such as backplane-attached/back-contact solar cells such as interdigitated back-contact (IBC) solar cells using monocrystalline silicon substrates and other described fabrication materials, one skilled in the art could apply the principles discussed herein to other solar cells including but not limited to non-IBC back-contact solar cells (such as Metallization Wrap-Through or MWT back-contact solar cells, traditional front contact cells, other fabrication materials including alternative semiconductor materials (such as materials comprising one or a combination of silicon, gallium arsenide, germanium, gallium nitride, other binary and ternary semiconductors, etc.), technical areas, and/or embodiments without undue experimentation.

Further, while the isled (also called tiled) master cell architectures (also referred to herein as icell, an acronym for Isled Cell) and representative manufacturing process flow descriptions are described with reference to thin epitaxial silicon back-contact/back-junction IBC solar cells formed using porous silicon lift-off processing on reusable monocrystalline templates and flexible backplanes, the novel concepts and embodiments disclosed herein can also be applied and effectively utilized in numerous other types of solar cells (and resulting solar PV modules) including, but not limited to:
Thin epitaxial silicon back-contact/back-junction IBC solar cells formed using porous silicon lift-off processing on reusable multi-crystalline templates, and either flexible or rigid backplanes;
Thin epitaxial silicon back-contact/back-junction IBC solar cells formed using porous silicon lift-off processing on reusable monocrystalline templates and relatively rigid backplanes;
Thin epitaxial Silicon Heterojunction (SHJ) solar cells formed using porous silicon lift-off processing on reusable multi-crystalline templates, and either flexible or rigid backplanes;
Back-junction/back-contact IBC solar cells formed using wire-sawn Czochralski (CZ) or Float-Zone (FZ) monocrystalline wafers and flexible backplanes;
Back-junction/back-contact IBC solar cells formed using wire-sawn Czochralski (CZ) or Float-Zone (FZ) monocrystalline wafers and rigid backplanes;
Back-junction/back-contact IBC solar cells formed using wire-sawn cast or ribbon multi-crystalline wafers, and flexible backplanes;
Back-junction/back-contact IBC solar cells formed using wire-sawn cast or ribbon multi-crystalline wafers, and rigid backplanes;
Back-contact non-IBC (e.g., Metallization Wrap-Through or MWT) solar cells formed using wire-sawn cast multi-crystalline wafers and flexible backplanes;
Back-contact non-IBC (e.g., Metallization Wrap-Through or MWT) solar cells formed using wire-sawn cast multi-crystalline wafers and rigid backplanes;
Back-contact non-IBC (e.g., Metallization Wrap-Through or MWT) solar cells formed using wire-sawn Czochralski (CZ) or Float-Zone (FZ) monocrystalline wafers and flexible backplanes;
Back-contact non-IBC (e.g., Metallization Wrap-Through or MWT) solar cells formed using wire-sawn Czochralski (CZ) or Float-Zone (FZ) monocrystalline wafers and rigid backplanes;
Semiconductor Heterojunction (SHJ) solar cells formed using wire-sawn Czochralski (CZ) or Float-Zone (FZ) monocrystalline wafers and flexible backplanes;
Semiconductor Heterojunction (SHJ) solar cells formed using wire-sawn Czochralski (CZ) or Float-Zone (FZ) monocrystalline wafers and rigid backplanes;
Front-contact solar cells formed using wire-sawn Czochralski (CZ) or Float-Zone (FZ) monocrystalline wafers and flexible backplanes;
Front-contact solar cells formed using wire-sawn Czochralski (CZ) or Float-Zone (FZ) monocrystalline wafers and rigid backplanes;
Front-contact solar cells formed using wire-sawn cast monocrystalline wafers and flexible backplanes;
Front-contact solar cells formed using wire-sawn cast monocrystalline wafers and rigid backplanes; and
Any of the above-mentioned solar cells using a different semiconductor material other than crystalline silicon.

The terms isle, island, tile, paver, sub-cell, and/or mini-cell are used interchangeably herein to describe the electrically and physically isolated individual semiconductor regions formed monolithically from a master cell substrate (i.e., an initial continuous semiconductor substrate) attached to a common or continuous backplane layer or sheet. The term isled master cell, icell, or modified main cell refers to the plurality of isles or sub-cells formed from the same original semiconductor substrate layer and the subsequent modified isled solar cell. The original semiconductor layer or substrate from which the mini-cells are formed may be referred to as a master cell.

Further, term backplane may be used herein to describe a combination of materials on the cell backside—such as metallization layers and electrically insulating layer attached to the solar cell backside—providing mechanical and structural support to a master cell (and its plurality of isles or mini-cells), and to enable an advanced solar cell interconnection design. Alternatively and in some instances, the term backplane may be used to describe a material layer, such as an electrically insulating flexible prepreg layer, formed and positioned on the backside of the solar cell, hence, enabling a solar cell metallization structure comprising at least two metallization layers on the cell backside. The backplane layer may be made of either a rigid or flexible thin sheet of material (for instance, with backplane sheet thickness in the range of up to about 250 microns). For applications involving back-contact solar cells (including either interdigitated back-contact—IBC or metallization-wrap-through—MWT), the backplane layer may be made of an electrically insulating material (either a flexible or a rigid material). For applications involving front-contact solar cells, the backplane layer may be either electrically or electrically conducting. In most instances, the term backplane refers to the continuous thin sheet of support material, including but not limited to a thin sheet of prepreg material, which can be either flexible or rigid. The use of flexible backplane sheet in conjunction in accordance with the disclosed subject matter also enables packaging the solar cells in flexible, lightweight PV modules (not requiring much heavier glass cover sheets for frontside or for both frontside and backside).

The present application provides various structures and methods for monolithic isled solar cells and modules. The term monolithic integrated circuit is used to describe a plurality of semiconductor devices and corresponding electrical interconnections that are fabricated onto a slice of semiconductor material layer, also known as the semiconductor substrate. Hence, a monolithic integrated circuit is typically manufactured on a thin continuous slice or layer of a semiconductor material such as crystalline silicon. The monolithic icell structures described herein are monolithic semiconductor integrated circuits as the integrated sub-cells are all formed or manufactured on a slice of semiconductor substrate layer (from either a starting semiconductor wafer or a grown semiconductor layer formed by a vapor-phase or liquid-phase growth method such as epitaxial deposition). Further, the combination of a continuous backplane attached to the semiconductor substrate layer backside enables monolithic integrated icell embodiments in accordance with the disclosed subject matter.

Physically or regionally isolated isles (i.e., the initial semiconductor substrate partitioned into a plurality of substrate isles supported on a shared continuous backplane) are formed from one initially continuous semiconductor layer or substrate—thus the resulting isles (for instance, trench isolated from one another using trench isolation regions or cuts through the semiconductor substrate) are monolithic—attached to and supported by a continuous backplane (for example a flexible backplane such as an electrically insulating prepreg layer). The completed solar cell comprises a plurality of monolithically integrated isles or mini-cells, in some instances attached to a flexible backplane (e.g., one made of a prepreg materials, for example having a relatively good Coefficient of Thermal Expansion or CTE match to that of the semiconductor substrate material), providing increased solar cell flexibility and pliability while suppressing or even eliminating micro-crack generation and crack propagation or breakage in the semiconductor substrate layer. Further, a flexible monolithically isled (or monolithically integrated group of isles) cell (also called an icell) provides improved cell planarity and relatively small or negligible cell bow throughout solar cell processing steps such as any optional semiconductor layer thinning etch, texture etch, post-texture clean, PECVD passivation and anti-reflection coating (ARC) processes (and in some processing embodiments also allows for sunny-side-up PECVD processing of the substrates due to mitigation or elimination of thermally-induced cell warpage), and final solar cell metallization. While the solar cells disclosed herein may be used to produce rigid glass-covered PV modules, the structures and methods disclosed herein also enable flexible, lightweight PV modules formed from the monolithic isled master cells (i.e., icells) which substantially decrease or eliminate solar cell micro-cracking during module lamination and also during PV module operation in the field. These flexible, lightweight PV modules may be used in a variety of markets and applications including, but not limited to, the residential rooftop (including residential Building-Integrated Photovoltaics or BIPV rooftop shingles/tiles), commercial rooftop, ground mount utility-scale power plants, portable and transportable PV power generation, automotive (such as solar PV sunroof), and other specialty applications.

Aspects of the innovations disclosed herein, either individually or in combination, may provide the following advantages among others:
An isled solar cell (icell) enables scaling of the solar cell voltage and current, specifically scaling up the solar cell voltage (in other words increasing the master cell output voltage) and scaling down the solar cell current (in other words decreasing the master cell output current) based on the number (e.g., N×N array) of cell isles/tiles (or sub-cells) which, among numerous other advantages including reduced metallization sheet conductance or thickness requirements (hence, reduced metallization material and process cost), lowers the maximum electrical current rating requirement for associated embedded power electronics components such as the embedded shade management diodes (e.g., lower current rating Schottky or pn junction diodes), or the embedded Maximum-Power-Point Tracking (MPPT) power optimizers (such as embedded MPPT DC-to-DC micro-converters or MPPT DC-to-AC micro-inverters). This may reduce the sizing (e.g., footprint and/or package thickness) and cost of embedded power electronics components such as the bypass switches (bypass switches with higher current ratings typically have higher costs as compared to bypass switches with lower current ratings), and improve the embedded power electronics device (such as the bypass switch used for distributed shade management, or the MPPT power optimizer used for distributed enhanced power/energy harvest from the PV module) performance due to the reduced electrical current (for instance, flowing through the bypass switch when it is activated and forward-biased to protect a shaded solar cell). A lower-rated current (for example, about 1 to 2 A) Schottky barrier diode typically costs much less, can have a much smaller package, and dissipates much less power than a 10 A to 20 A Schottky barrier diode. The embodiments disclosed herein (for instance, using N×N isles for the master cell or icell), with icell electrical interconnection configured to provide higher cell voltage (with a scale-up factor of up to N×N) and lower cell current (with a scale-down factor of up to N×N) can reduce the resulting solar cell current while increasing the solar cell voltage for the same solar cell power in order to enable the use of lower cost, smaller, and less power-dissipating bypass diode. For example, consider a crystalline silicon master cell or icell with a maximum-power-point voltage of Vₘₚ≈0.60V and maximum-power-point current of Iₘₚ≈9.3 A (with the solar cell producing a maximum-power-point power of Pₘₚ≈5.6 W). A master cell or icell with a 5×5 array of mini-cells (N=5), with all the isles or sub-cells connected in electrical series (S=25), for example using a combination of a first level metal (M1) on the backside of the solar cell and a second level metal (M2) on an electrically insulating backplane layer as described further herein, will result in a modified cell with Vₘₚ=15V and Iₘₚ=0.372 A—in other words, the master cell or icell voltage is scaled up by a factor of 25 and the master cell or icell current is scaled down by the same factor of 25 (compared to the solar cell of the same master cell size but without the icell structures disclosed herein).
Higher conversion-efficiency, embedded/distributed lower cost, and smaller footprint Maximum-Power-Point Tracking (MPPT) power optimizer (DC-to-DC or DC-to-AC) chips with superior performance such as dynamic range response may be embedded within the module laminate and/or integrated directly on the backsides of the solar cells (for instance, on the backplanes of the backplane-attached icells disclosed herein) due to the higher voltage and lower current master cell (icell) made of a plurality of isles or mini-cells. In one embodiment, the icell may use an inexpensive single-chip MPPT power optimizer (DC-to-DC micro-converter or DC-to-AC micro-inverter).
Allows for inexpensive implementation of distributed cell-level integrated shade management an embedded bypass switch connected to each icell, providing higher effective energy yield for the installed PV modules in the field. In one embodiment, this may comprise a monolithically integrated bypass switch (MIBS) formed peripherally around each isle so that during partial shading only the affected/shaded tiles or mini-cells are shunted while the remaining ones produce and deliver electrical power.
The scaled down electrical current of an isled solar cell (an icell)—for instance, decreased by a factor of N×N isles—decreases the required patterned metallization sheet conductance and thickness due to the reduced ohmic losses. In other words, the metallization sheet conductance and thickness requirements are relaxed due to substantially reduced ohmic losses. A thinner solar cell metallization structure has a number of benefits relating to solar cell processing and may provide significant manufacturing cost reduction (for instance, much less metallization material required per cell) as well as reducing thermal and mechanical stresses relating to relatively thick (e.g., 10's of microns for interdigitated back-contact or solar cells) metallization structures and the CTE mismatch between conductive metal and semiconductor material. Usually the metallization materials such as copper or aluminum have much higher CTE compared to the semiconductor materials. For instance, linear CTEs of aluminum, copper, and silver (high-conductivity metals) are about 23.1 ppm/° C., 17 ppm/° C., and 18 ppm/° C., respectively. However, the linear CTE of silicon is around 3 ppm/° C. Therefore, there is a relatively large CTE mismatch between these high-conductivity metallization materials and silicon. These relatively large CTE mismatches between the metallization materials and silicon can cause serious cell manufacturing yield and PV module reliability problems, particularly when using relatively thick metallization structures for solar cells (such as thick plated copper used in the IBC solar cells).
In a multi-layer metallization pattern, such as the dual layer metallization patterns described herein for interdigitated back-contact (IBC) solar cells, the second level metal (M2), for example comprising aluminum or copper, can be made much thinner due to the current and voltage scaling of the icell architecture, and thus deposited without wet plating and using a process which is substantially less mechanically stressful on the cell and chemically intrusive to the cell (for example a dry processing method such as physical-vapor deposition—PVD such as metal evaporation and/or plasma sputtering—or metal paste screen printing or metal ink printing by inkjet printing, etc.).
In some instances, the cost of material forming the backplane (such as prepreg) is reduced as the icell architecture using a plurality of flexible isles reduces/relaxes the CTE requirements of the prepreg (for instance, by relaxing the relative CTE matching requirement between the backplane layer and semiconductor substrate). Relative CTE matching requirements between the backplane sheet and the semiconductor substrate are reduced as there is less continuous cell area attached to the backplane (because of the trench isolation regions partitioning the semiconductor substrate into a plurality of isles or sub-cells on the continuous backplane sheet)—the continuous mini-cell area attached to the continuous backplane is defined by the isle area or region surrounded by trench isolation.
Trench separated and electrically partitioned substrate regions for isles provide relative flexibility, further mitigate cell bow, and maintain relative planarity across the master cell (entire icell area) during cell processing (and in some instances also allowing for cell passivation processing such as sunnyside-up cell PECVD deposition) and reduce long term material stresses after cell fabrication, module lamination, and during the operation of the PV modules in the field under varying weather conditions.

Important applications of the disclosed innovations include but are not limited to: flexible solar cells and flexible, lightweight PV modules for the residential rooftop, Building-Integrated PhotoVoltaics (BIPV) in residential and commercial buildings, commercial rooftop, ground-mount utility-scale power plants, automotive applications, portable electronics, portable and transportable power generation, and other specialty applications. The embodiments disclosed herein include both rigid or flexible solar cells which may be packaged or laminated into rigid glass-covered solar PV modules for a wide range of applications, including the above-mentioned residential rooftop, commercial rooftop, BIPV, ground-mount utility, automotive, portable and transportable power generation, and other specialty applications.

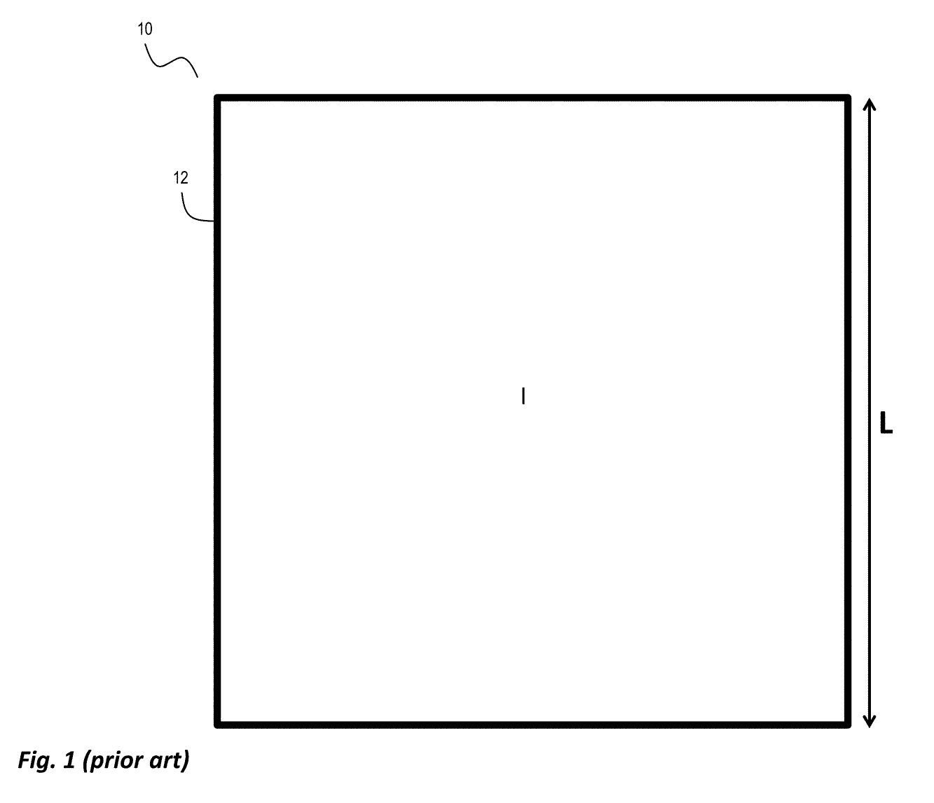

FIG. 1 is a representative schematic diagram of a square-shaped single isle for cell pattern—prior art standard solar cell geometry without plurality of isles to create an icell. Although shown as a full-square-shaped cell here, the solar cell may be shaped as pseudo square, rectangular, other polygonal shapes, or any other geometrical shape of interest. FIG. 1 is a schematic diagram showing a top or plan view of a single-isle I (or non-isled or non-tiled) standard square-shaped solar cell 10 defined by cell peripheral boundary or edge regions 12 and having a side length L. Current or mainstream crystalline silicon solar cells are often rectangular/square shaped (mostly either full square or pseudo square shaped wafers) with cell square area on the order of X by X (with X typically being in the range of about 100 mm up to 210 mm or even larger values), for example, 125 mm×125 mm or 156 mm×156 mm or 210 mm×210 mm solar cells. And although a square shaped solar cell is used as an exemplary master cell (master cell is defined as a single solar cell made from an original continuous semiconductor substrate) shape herein, master cells may come in various shapes (for example pseudo-square) and have various geometrical dimensions.

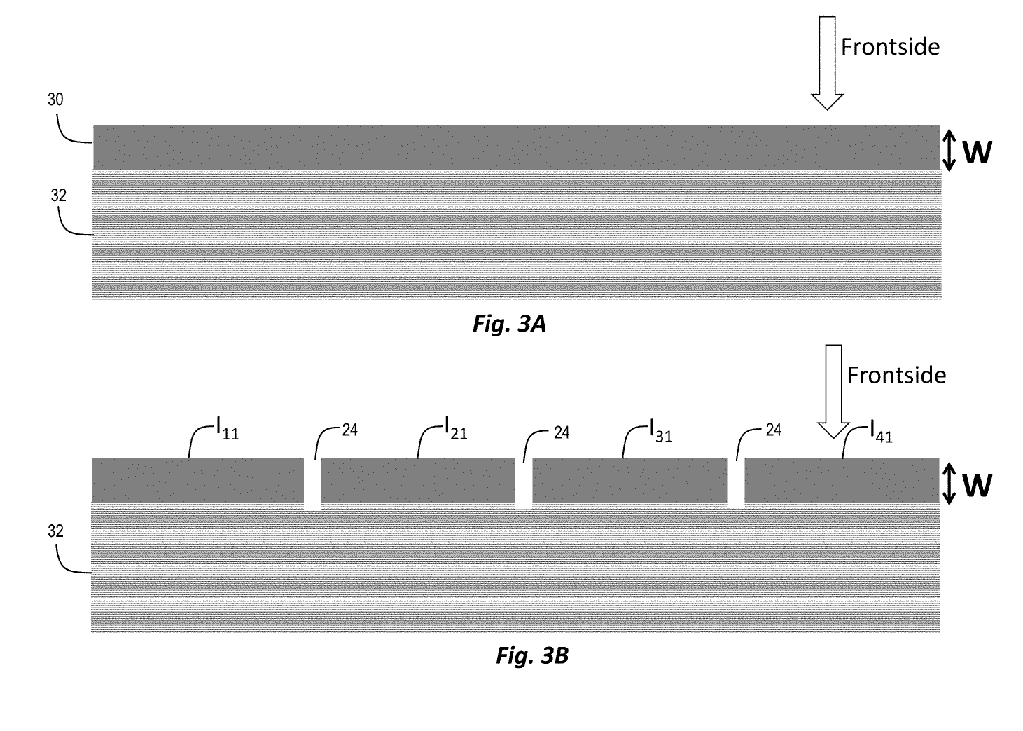

Cell peripheral boundary or edge region 12 has a total length of 4 L, thus solar cell 10 has a total peripheral dimension of 4 L. Assuming a solar cell semiconductor (e.g., silicon substrate layer) absorber thickness of W (see the cross-sectional diagram of FIG. 3A), the cell edge area as a fraction of the cell active area is defined as the ratio R where R=(4LW)/(L²)=4 W/L. For a thin-silicon solar cell having L=156 mm and W=40 μm (microns) thick silicon substrate (for example an epitaxially grown silicon also known as epi, layer, or alternatively s silicon layer formed from an original wire-sawn CZ or FZ or multi-crystalline silicon wafer): R=4×40×10⁻³/156, thus R=0.0010 (or 0.10%). And for a more conventional standard solar cell with W=200 μm thick silicon substrate (for example, from a CZ monocrystalline wafer or a cast multicrystalline wafer): R=0.0050 (or 0.50%). Generally, a solar cell structure should have a relatively small edge area as compared to active cell area (also called edge to cell ratio)—for instance, less than about 5%, and in some instances less than about 1%—in order to minimize the edge-related solar cell recombination losses which may result in reduced open-circuit voltage and/or reduced short-circuit current, and hence, reduced solar cell conversion efficiency. The edge-induced losses can be substantially mitigated by proper passivation of the solar cell edge regions and through isolation/separation of the emitter junction region from the edge region (hence, providing allowance for larger edge area fraction without loss of solar cell efficiency).

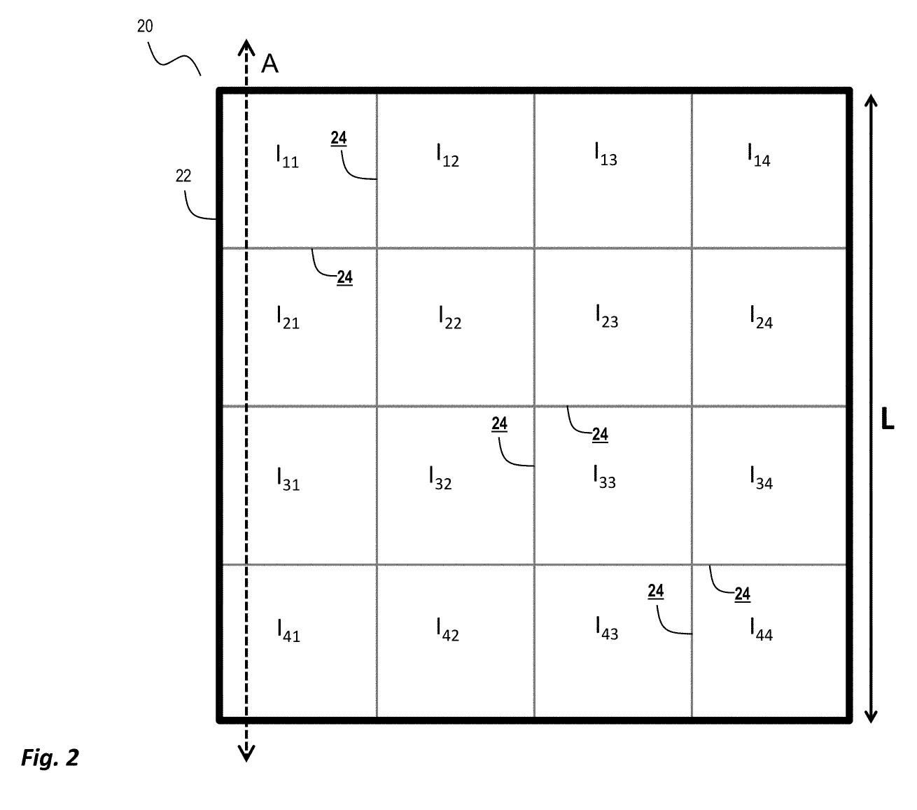

FIG. 2 is a representative schematic plan view (frontside or sunnyside view) diagram of an icell pattern (shown for square-shaped isles and square-shaped icell) along with uniform-size (equal-size) square-shaped isles for N×N=4×4=16 isles (or sub-cells, mini-cells, tiles). This schematic diagram shows a plurality of isles (shown as 4×4=16 isles) partitioned by trench isolation regions. FIG. 2 is a schematic diagram of a top or plan view of a 4×4 uniform isled (tiled) master solar cell or icell 20 defined by cell peripheral boundary or edge region 22, having a side length L, and comprising sixteen (16) uniform square-shaped isles formed from the same original continuous substrate and identified as I₁₁ through I₄₄ attached to a continuous backplane on the master cell backside (backplane and solar cell backside not shown). Each isle or sub-cell or mini-cell or tile is defined by an internal isle peripheral boundary (for example, an isolation trench cut through the master cell semiconductor substrate thickness and having a trench width substantially smaller than the isle side dimension, with the trench width no more than 100's of microns and in some instances less than or equal to about 100 μm—for instance, in the range of a few up to about 100 μm) shown as trench isolation or isle partitioning borders 24. Main cell (or icell) peripheral boundary or edge region 22 has a total peripheral length of 4L; however, the total icell edge boundary length comprising the peripheral dimensions of all the isles comprises cell peripheral boundary 22 (also referred to as cell outer periphery) and trench isolation borders 24. Thus, for an icell comprising N×N isles or mini-cells in a square-shaped isle embodiment, the total icell edge length is N× cell outer periphery. In the representative example of FIG. 2 showing an icell with 4×4=16 isles, N=4, so total cell edge length is 4× cell outer periphery 4L=16L (hence, this icell has a peripheral dimension which is 4 times larger than that of the standard prior art cell shown in FIG. 1). For a square-shaped master cell or icell with dimensions 156 mm×156 mm, square isle side dimensions are approximately 39 mm×39 mm and each isle or sub-cell has an area of 15.21 cm² per isle.

FIGS. 3A and 3B are representative schematic cross-sectional view diagrams of a backplane-attached solar cell during different stages of solar cell processing. FIG. 3A shows the simplified cross-sectional view of the backplane-attached solar cell after processing steps and before formation of the partitioning trench regions. FIG. 3B shows the simplified cross-sectional view of the backplane-attached solar cell after some processing steps and after formation of the partitioning trench regions to define the trench-partitioned isles. FIG. 3B shows the schematic cross-sectional view of the icell of FIG. 2 along the view axis A of FIG. 2 for an icell pattern (shown for square-shaped isles and square-shaped icell), indicating the uniform-size (equal-size) square-shaped isles for N×N=4×4=16 isles (or sub-cells, mini-cells, tiles).

FIGS. 3A and 3B are schematic cross-sectional diagrams of a monolithic master cell semiconductor substrate on a backplane before formation of trench isolation or partitioning regions, and a monolithic isled or tiled solar cell on a backplane formed from a master cell after formation of trench isolation or partitioning regions, respectively. FIG. 3A comprises semiconductor substrate 30 having width (semiconductor layer thickness) W and attached to backplane 32 (e.g., an electrically insulating continuous backplane layer, for instance, a thin flexible sheet of prepreg) similar to that shown in FIG. 1. FIG. 3B is a cross-sectional diagram of an isled solar cell (icell)—shown as a cross-sectional diagram along the A axis of the cell of FIG. 2. Shown, FIG. 3B comprises isles or mini-cells I₁₁, I₂₁, I₃₁, and I₄₁ each having a trench-partitioned semiconductor layer width (thickness) W and attached to backplane 32. The semiconductor substrate regions of the mini-cells are physically and electrically isolated by an internal peripheral partitioning boundary, trench partitioning borders 24. The semiconductor regions of isles or mini-cells I₁₁, I₂₁, I₃₁, and I₄₁ are monolithically formed from the same continuous semiconductor substrate shown in FIG. 3A. The icell of FIG. 3B may be formed from the semiconductor/backplane structure of FIG. 3A by forming internal peripheral partitioning boundaries in the desired mini-cell shapes (e.g., square shaped mini-cells or isles) by trenching through the semiconductor layer to the attached backplane (with the trench-partitioned isles or mini-cells being supported by the continuous backplane). Trench partitioning of the semiconductor substrate to form the isles does not partition the continuous backplane sheet, hence the resulting isles remain supported by and attached to the continuous backplane layer or sheet. Trench partitioning formation process through the initially continuous semiconductor substrate thickness may be performed by, for example, pulsed laser ablation or dicing, mechanical saw dicing, ultrasonic dicing, plasma dicing, water jet dicing, or another suitable process (dicing, cutting, scribing, and trenching may be used interchangeably to refer to the process of trench isolation process to form the plurality of isles or mini-cells or tiles on the continuous backplane). Again, the backplane structure may comprise a combination of a backplane support sheet in conjunction with a patterned metallization structure, with the backplane support sheet providing mechanical support to the semiconductor layer and structural integrity for the resulting icell (either a flexible solar cell using a flexible backplane sheet or a rigid solar cell using a rigid backplane sheet or a semi-flexible solar cell using a semi-flexible backplane sheet). Again, while we may use the term backplane to the combination of the continuous backplane support sheet and patterned metallization structure, more commonly we use the term backplane to refer to the backplane support sheet (for instance, an electrically insulating thin sheet of prepreg) which is attached to the semiconductor substrate backside and supports both the icell semiconductor substrate regions and the overall patterned solar cell metallization structure.

As previously noted, crystalline (both mono-crystalline and multi-crystalline) silicon photovoltaics (PV) modules currently account for over approximately 85% of the overall global solar PV market, and the starting crystalline silicon wafer cost of these crystalline silicon PV modules currently constitutes about 30% to 50% of the total PV module manufacturing cost (with the exact ratio depending on the technology type and various economic factors). And while the primary embodiments provided herein are described as back-contact/back-junction (Inter-digitated Back-Contact or IBC) solar cells, the monolithic isled solar cell (or icell) innovations disclosed herein are extendible and applicable to various other solar cell architectures such as Metallization Wrap-Through (MWT) back-contact solar cells, Semiconductor HeteroJunction (SHJ) solar cells, front-contact/back-junction solar cells, front-contact/front-junction solar cells, Passivated Emitter and Rear Contact (PERC) solar cells, as well as other front-contact/front-junction solar cells, with all of the above-mentioned cell designs using crystalline silicon (for instance, either mono-crystalline silicon or multi-crystalline silicon with final cell silicon layer thickness in the range of a few microns up to about 200 microns), or another crystalline (mono-crystalline or multi-crystalline) semiconductor absorber material (including but not limited to germanium, gallium arsenide, gallium nitride, or other semiconductor materials, or a combination thereof). The monolithic isled solar cell (or icell) innovations disclosed herein are extendible and applicable to compound semiconductor multi junction solar cells.

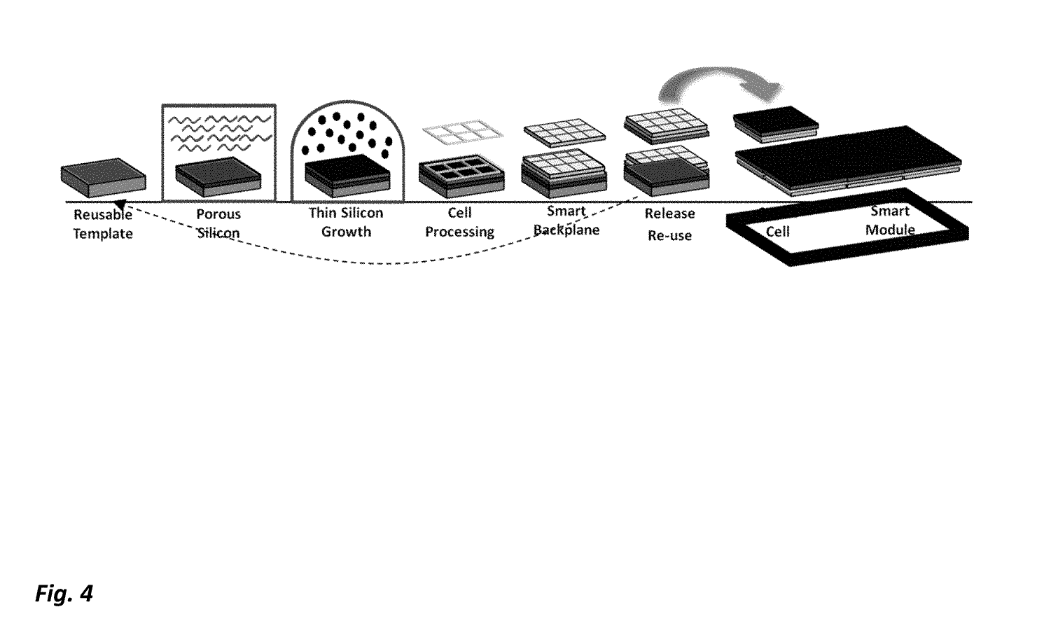

A key advantage of the disclosed monolithically isled solar cells or icells is that they may be monolithically fabricated during cell processing and easily integrated into existing solar cell fabrication process flows. The isled master cell embodiments disclosed herein may be used in conjunction with numerous backplane-attached solar cell designs, processing methods, and semiconductor substrate materials, including the backplane-attached, back-contact solar cells fabricated using epitaxial silicon lift-off process flow shown in FIG. 4. FIG. 4 shows the schematic diagram of a general back-contact solar cell manufacturing process flow highlighting key processing steps of one such cell fabrication process—a crystalline-silicon solar cell manufacturing process using relatively thin (in the thickness range of a few microns up to about 100 microns) epitaxial silicon lift-off processing which substantially reduces silicon material usage and eliminates several process steps in the traditional crystalline silicon solar cell manufacturing steps to create low-cost, high-efficiency, back-junction/back-contact crystalline silicon solar cells and modules. Specifically, the process flow of FIG. 4 shows the fabrication of backplane-attached crystalline silicon solar cells having backplanes attached to the backsides of the solar cells (for instance, prepreg backplane sheets laminated to the backsides of the solar cells) for solar cells and modules with optional allowances for smart cell and smart module design (i.e., allowing for embedded distributed electronics components for enhanced power harvest from the solar cells and modules), formed using a reusable crystalline (either mono-crystalline or multi-crystalline) silicon template and epitaxial silicon deposition on a seed and release layer of porous silicon, which may utilize and integrate the monolithically isled cell (icell) structures and methods disclosed herein.

The solar cell process flow of FIG. 4 may be used to form monolithic isled solar cells or icells. The process shown in FIG. 4 starts with a reusable (to be reused at least a few times, in some instances between about 10 up to about 100 times) crystalline silicon template, for example a p-type monocrystalline or multi-crystalline silicon wafer, onto which a thin (a fraction of micron up to several microns) sacrificial layer of porous silicon with controlled porosity is formed (for example by an electrochemical etch process for template surface modification in an HF/IPA or HF/acetic acid wet chemistry in the presence of an electrical current). The porous silicon layer may have at least two layers with a lower porosity surface layer and a higher porosity buried layer. The starting material or reusable crystalline silicon template may be a single crystalline (also known as mono-crystalline) silicon wafer, for example formed using crystal growth methods such as float zone (FZ), czochralski (CZ), magnetic stabilized CZ (MCZ), and may further optionally comprise epitaxial layers grown over such silicon wafers. Alternatively, the starting material or reusable crystalline silicon template may be a multi-crystalline silicon wafer, for example formed using either casting or ribbon, and may further optionally comprise epitaxial layers grown over such silicon wafers. The template semiconductor doping type may be either p or n (often relatively heavy p-type doping to facilitate porous silicon formation), and the wafer shape, while most commonly square shaped, may be any geometric or non-geometric shape such as quasi-square (pseudo square), hexagonal, round, etc.

Upon formation of the sacrificial porous silicon layer, which serves both as a high-quality epitaxial seed layer as well as a subsequent separation/lift-off layer for the resulting epitaxial silicon layer, a thin layer (for example a layer thickness in the range of a few microns up to about 100 microns, and in some instances an epitaxial silicon thickness less than approximately 50 microns) of in-situ-doped (for instance, doped with phosphorus to form a n-type epitaxial silicon layer) crystalline (either mono-crystalline or multi-crystalline) silicon is formed on the sacrificial porous silicon layer, also called epitaxial growth. The in-situ-doped crystalline (either mono-crystalline layer on mono-crystalline template or multi-crystalline layer on multi-crystalline template) silicon layer may be formed, for example, by atmospheric-pressure epitaxy using a chemical-vapor deposition or CVD process in ambient comprising a silicon gas such as trichlorosilane or TCS and hydrogen (and the desired dopant gas such as PH₃ for n-type phosphorus doping).

After completion of a portion of solar cell processing steps (including in some instances, backside doped emitter formation, backside passivation, doped base and emitter contact regions for subsequent metallization contacts to the base and emitter regions, and solar cell metallization), a rather inexpensive backplane layer may attached to the thin epi layer for permanent cell support and reinforcement as well as to support formation of the high-conductivity cell metallization structure of the solar cell (for instance, using a two-layer metallization structure using a patterned first layer of metallization or M1 on the solar cell backside prior to the backplane attachment and a patterned second layer of metallization or M2 on the backside of the backplane-attached solar cell after the backplane attachment and after the lift-off release of the backplane-attached solar cell from the reusable template). The continuous backplane material may be made of a thin (for instance, with a thickness in the range of about 50 microns to about 250 microns thick), flexible, and electrically insulating polymeric material sheet such as an inexpensive prepreg material commonly used in printed circuit boards which meets cell process integration and reliability requirements. The partially-processed back-contact, back-junction (IBC) backplane-attached solar cell (for instance, with a solar cell area of about 100 mm×100 mm, 125 mm×125 mm, 156 mm×156 mm, 210 mm×210 mm or larger, or solar cell area in the range of about 100 cm² to 100's of cm² and even larger) is then separated and lifted off (released) from the reusable template along the mechanically-weakened sacrificial porous silicon layer (for example through a Mechanical Release or MR lift-off process, breaking off the higher porosity porous silicon interface to enable lift-off release) and the template may be conditioned (e.g., cleaned) and re-used multiple times (for instance, between about 10 and 100 times) to reduce the overall solar cell manufacturing cost. The remaining post-lift-off solar cell processing may then be performed on the backplane-attached solar cell, for example first on the solar cell sunny-side (or frontside) which is exposed after being lifted off and released from the template. Solar cell frontside or sunny-side processing may include, for instance, completing frontside texturization (for instance, using an alkaline or acidic texturing), post-texture surface preparation (cleaning), and formation of the frontside passivation and an anti-reflection coating (ARC) using a deposition process. The frontside passivation and ARC layer may be deposited using a Plasma-Enhanced Chemical-Vapor Deposition (PECVD) process and/or another suitable processing method.

The monolithically isled cell (icell) structures and methods disclosed herein may be integrated into device fabrication, such as the exemplary disclosed solar cell fabrication process flow, without substantially altering or adding manufacturing process steps or tools and thus without substantially adding to the cost of manufacturing the solar cell and without substantially altering the main solar cell manufacturing process flow. In fact, the monolithically isled cell (icell) structures and methods disclosed herein can reduce the cost of manufacturing the solar cell, for instance, by reducing the metallization cost (using less metallization material and lower cost metallization process) and/or by improving the solar cell and module manufacturing yield (due to substantial mitigation of solar cell micro-cracks or breakage).

In one embodiment, scribing (also known as trenching or cutting or dicing), of the master cell semiconductor substrate to form the internal isle partitioning trench boundaries and creating the plurality of trench-partitioned isles or mini-cells or sub-cells or tiles may be performed from the frontside or sunnyside (after lift-off release of the backplane-attached epitaxial silicon substrate layer), using a suitable method such as pulsed laser ablation (for instance, pulsed nanoseconds laser scribing) or a mechanical scribing method or a plasma scribing method, through the master cell silicon substrate layer thickness (for example, the epitaxial silicon layer thickness may be in the range of about a few microns up to about 100 μm). Pulsed laser ablation scribing (or another suitable trench scribing method as described before) may be performed such that scribing through the thickness of the semiconductor substrate layer forms relatively narrow (e.g., width of less than 100 microns) trench isolation borders all the way through the entire thickness of the thin silicon layer and essentially stops at/on the backplane (removal and scribing of the continuous backplane material layer being rather small or negligible)—thus monolithically producing fully partitioned monolithic isles (or sub-cells or mini-cells or tiles) supported on a continuous backplane layer. Partitioning trench formation methods to form the plurality of isles and their associated trench partitioning boundaries in a master cell substrate having a thickness in the range of about a few microns to as large as about 200 microns (master cell substrate thickness or width shown as W in FIGS. 2) include, for example: pulsed laser scribing (or dicing, or trenching), such as by pulsed nanoseconds laser ablation (using a suitable laser wavelength such as UV, green, IR, etc.); ultrasonic scribing or dicing; mechanical trench formation such as by using a mechanical saw or blade; patterned chemical etching (both wet and plasma etching); screen printing of an etch paste following by etching activation and rinsing of the etch paste residue, or any combination of known or the above mentioned trench formation methods. Pulsed laser ablation processing for trench formation may provide several advantages allowing for the direct patterning of the isle or mini-cell boundaries with relatively high process throughput, enabling formation of relatively narrow trenches (e.g., less than about 100 microns trench width), and without any process consumable (hence, very low process cost). However, irrespective of the trench formation method used to partition the plurality of isles or sub-cells, special care should be taken to reduce or minimize the trench width—for example, it may be desired to make the partitioning trench width less than about 100 microns, in order to make the solar cell area loss due to the icell partitioning trenches a relatively small to negligible fraction of the total icell area (for instance less than about 1% of the total icell area). This will ensure that the loss of icell total-area efficiency due to the partitioning trenches is rather negligible (e.g., less than 1% relative). Pulsed nanoseconds laser ablation processing is capable of high-throughput formation of trenches with trench width well below 100 microns (e.g., about 10 to 60 microns). For example, for a square-shaped icell with the master cell area of 156 mm×156 mm and 4×4=16 isles (or mini-cells) and partitioning trenches with trench width of 50 microns (0.05 mm), for example, formed by pulsed laser ablation trenching, the area fraction R of the total trench planar surface area A trench to the total master cell area (or the icell area A_{icell}) can be calculated as follows: R=A_{trench}/A_{icell}=6×156 mm×0.05 mm/(156 mm×156 mm) or R=0.00192. Therefore, this represents an area fraction R of 0.00192 or about 0.2%. This is an extremely small area fraction, ensuring negligible loss of total-area icell efficiency as a result of the partitioning trench areas. In reality, the loss of total-area icell efficiency would be smaller than 0.2% relative under these conditions, since the direct and/or diffused sunlight impinging on the trench isolation or partitioning areas can be at least partially and possibly mostly absorbed on the isle semiconductor edge regions and contribute to the photo-generation process.

The monolithic isled (tiled) solar cell fabrication methods and structures described herein are applicable to various semiconductor (for example including but not limited to crystalline silicon, such as thin epitaxial silicon or thin crystalline silicon wafer) solar cells (for example, front contact or back contact solar cells of various designs with cell semiconductor absorber having a thickness in the range of about a few microns up to about 200 microns), including those formed using epitaxial silicon lift-off processing (as described earlier) or those formed using crystalline silicon wafers, such as mono-crystalline (CZ or MCZ or FZ) wafers or multi-crystalline wafers (cast or ribbon-grown wafers).

For back-contact/back-junction square-shaped cells (for example high-efficiency back-contact/back-junction IBC cells formed using either epitaxial silicon lift-off processing or crystalline silicon wafer cells with backplane reinforcement), the master cell isles (also called tiles, pavers, sub-cells, or mini-cells) may be formed (for example, using pulsed nanoseconds laser scribing of crystalline silicon substrate) as an array of N×N square-shaped isles, N×M rectangular-shaped isles, K triangular-shaped isles, or any geometrically shaped isles or combination thereof on the shared master cell (icell) continuous backplane. In the case of solar cells fabricated using epitaxial lift-off processing, the isle partitioning trench formation process may occur immediately after the lift-off release of the partially-processed backplane-attached master cell and before the remaining processing steps such as frontside surface texturing and post-texture surface cleaning, or immediately after frontside texturing and post-texture surface cleaning and before the process(es) to form the front-surface passivation and anti-reflection coating (ARC) layer(s). Performing the process to form the partitioning or isolation trenches (i.e., trenching process) by pulsed laser scribing or another suitable method (such as one of the other methods described earlier including but not limited to mechanical dicing) before the wet etch texture process (to form the solar cell frontside texture for reduced optical reflection losses) has an added advantage of removing any trenching-process-induced silicon edge damage through wet etching and removal of damaged silicon during the wet texture etch process (which also etches several microns of silicon, including any damaged silicon in the partitioning trench sidewalls, during the texture etch process).

In some solar cell processing embodiments, including those representative process flows described in detail herein, no additional separate fabrication process equipment may be needed for the formation of the monolithically isled master cells (icells). In other words, the formation of trench-partitioned mini-cells or isles within each icell may be integrated fairly easily and seamlessly in solar cell fabrication methods. And in some cases, the monolithic isled solar cell (icell) fabrication process may improve the solar cell fabrication process flow through a reduction of solar cell manufacturing cost, for example, by reducing the cost of solar cell metallization, such as, for instance, by eliminating the need for a copper plating process and associated manufacturing equipment and facilities requirements for copper plating.

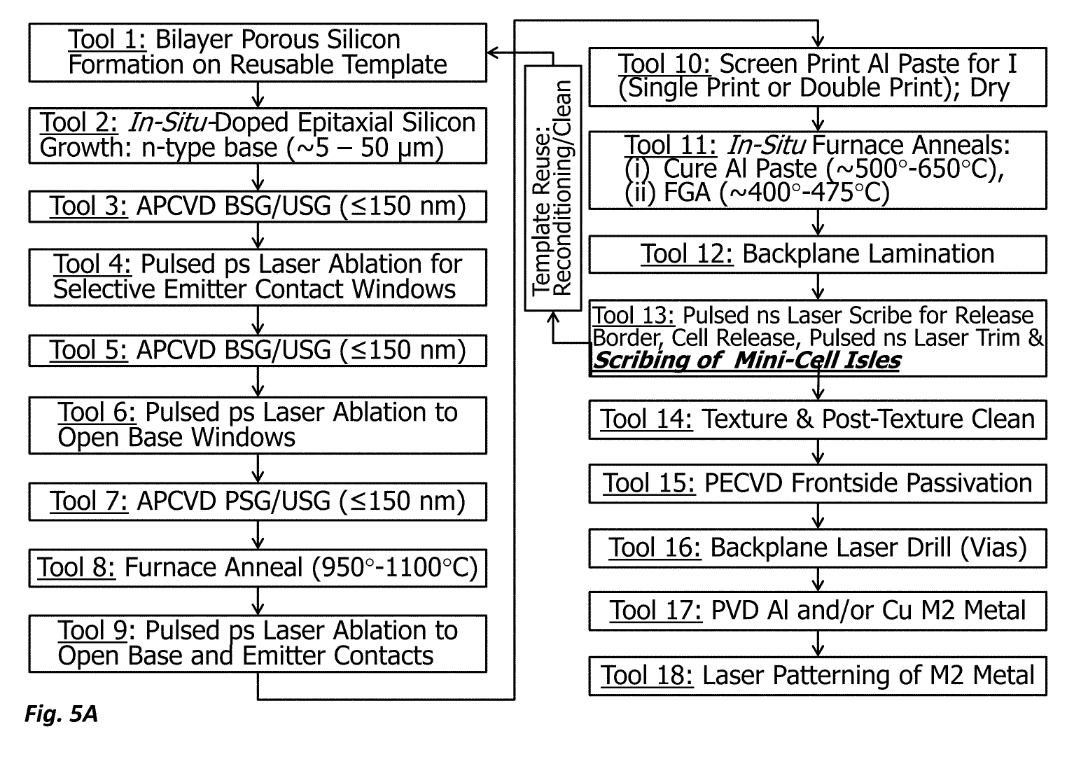

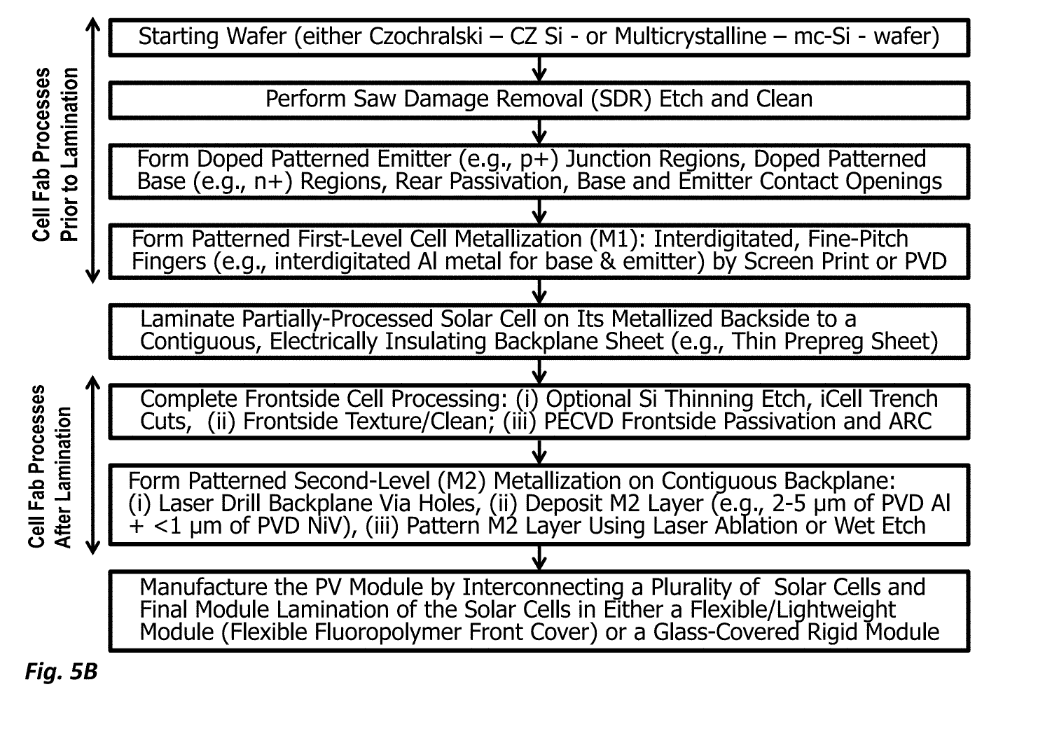

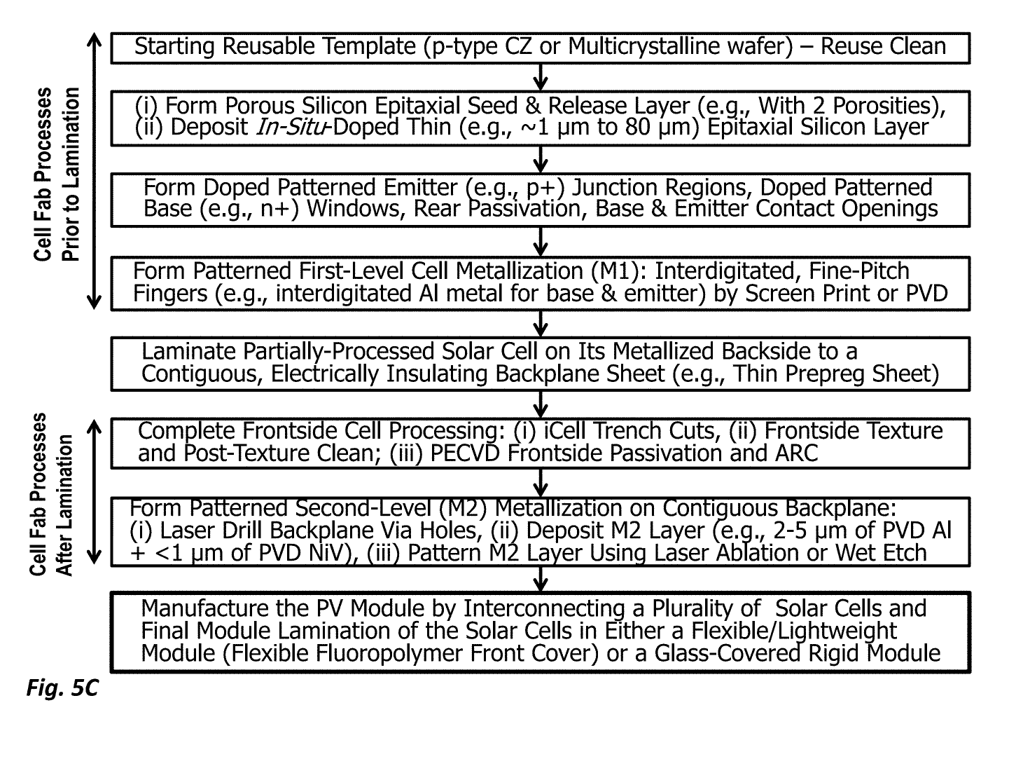

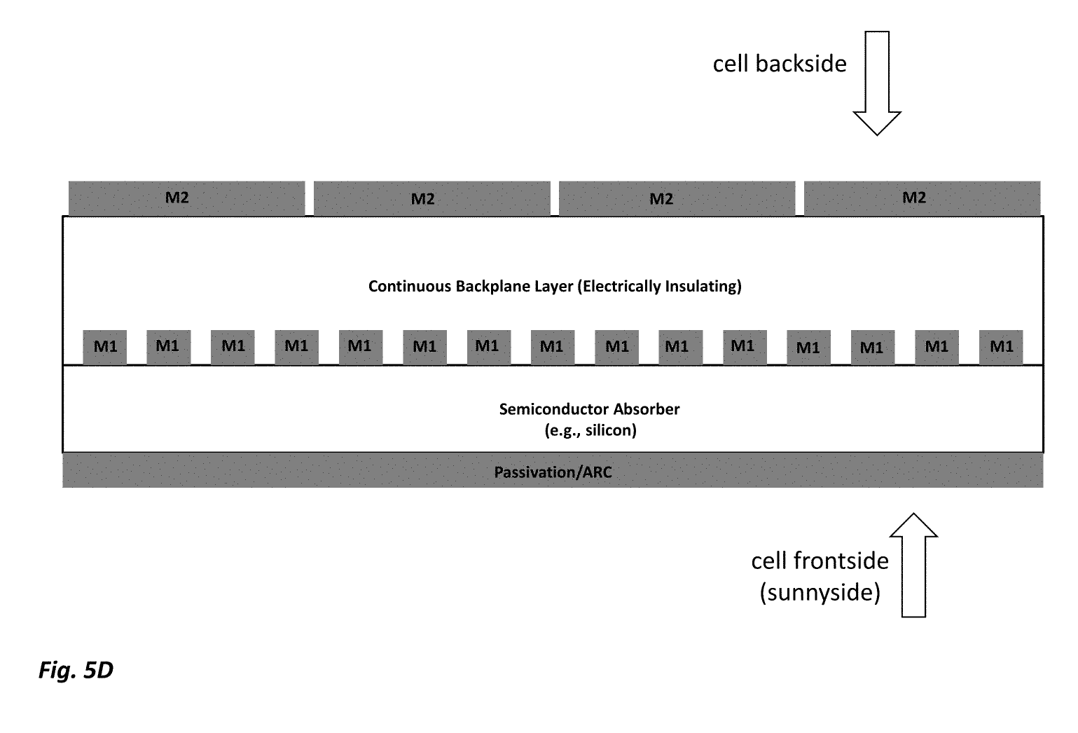

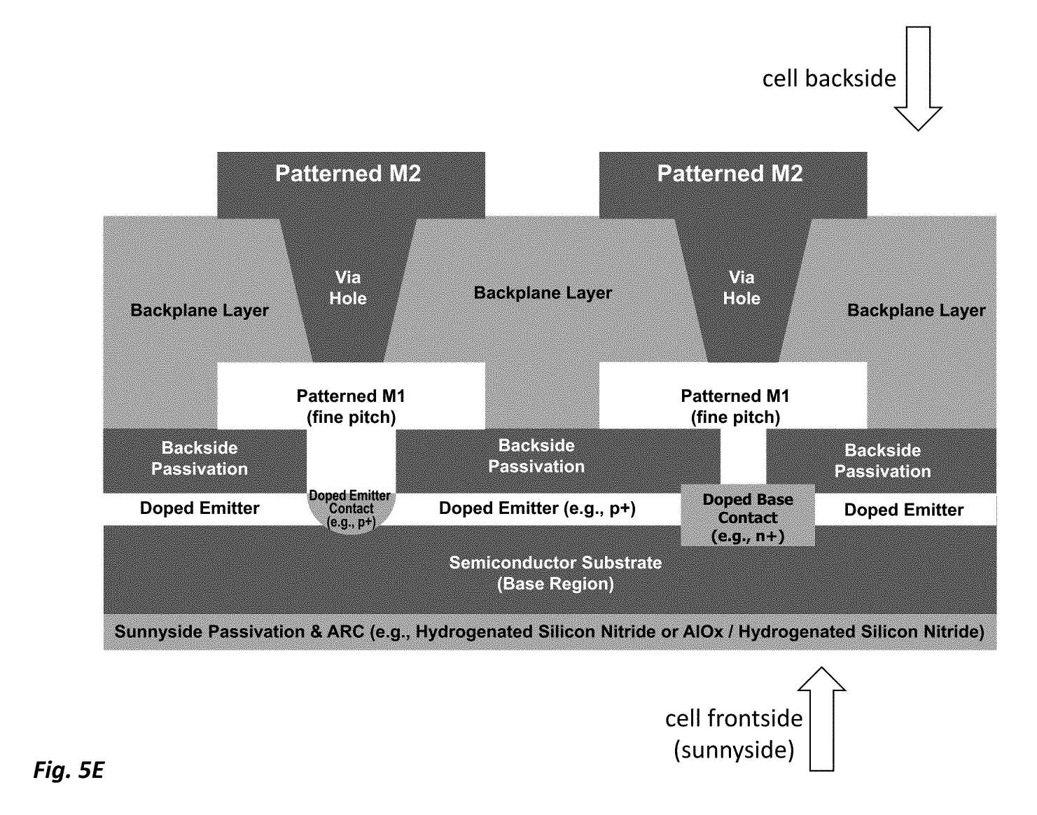

FIG. 5A is a representative backplane-attached icell manufacturing process flow based on epitaxial silicon and porous silicon lift-off processing. This process flow is for fabrication of backplane-attached, back-contact/back-junction solar cells (icells) using two patterned layers of solar cell metallization (M1 and M2). This example is shown for a solar cell with selective emitter, i.e., a main patterned field emitter with lighter emitter doping formed using a lighter boron-doped silicate glass (first BSG layer with smaller boron doping deposited by Tool 3), and more heavily-boron-doped emitter contact regions using a more heavily boron-doped silicate glass (second BSG layer with larger boron doping deposited by Tool 5). While this example is shown for an IBC solar cell using a double-BSG selective emitter process, the icell designs are applicable to a wide range of other solar cell structures and process flows, including but not limited to the IBC solar cells without selective emitter (i.e., same emitter boron doping in the field emitter and emitter contact regions). This example is shown for an IBC icell with an n-type base and p-type emitter. However, the polarities can be changed so that the solar cell has p-type base and n-type emitter instead.

FIG. 5A is a representative manufacturing process flow embodiment for the fabrication of back-contact back-junction crystalline monolithic isled silicon solar cells (icells). Specifically, FIG. 5A provides for the formation of an epitaxial (epi) solar cell, optionally with a monolithically integrated bypass switch (MIBS) pn junction diode, and having a double borosilicate glass (BSG) selective emitter. As shown in this flow, mini-cell trench isolation regions are formed at Tool 13, after cell release border scribe and cell lift-off release and before texturization of the exposed released side (also known as frontside or sunnyside of the resulting icell). Alternatively, the mini-cell trench isolation regions may be formed after texture and post texture clean in Tool 14, and before frontside passivation (shown as PECVD). Performing the pulsed laser scribing before wet etch texture (texture and post texture clean using Tool 14) may have an added advantage of removing any laser-induced scribed silicon edge damage through wet etching and removal of damaged silicon.

A representative process flow for forming a monolithic isled (tiled) back-contact/back-junction (IBC) solar cell using epitaxial silicon lift-off processing may comprise the following fabrication steps: 1) start with reusable crystalline (mono-crystalline or multi-crystalline) silicon template; 2) form porous silicon on template (for example, bilayer porous silicon with a lower porosity surface layer and a higher porosity buried layer using anodic etch in HF/IPA or HF/acetic acid); 3) deposit epitaxial silicon with in-situ doping (for instance, n-type phosphorus doped epitaxial silicon); 4) perform back-contact/back-junction cell processing while the epitaxial silicon substrate resides on its template, including formation of patterned field emitter junction, backside passivation, doped base and emitter contact regions for subsequent metallized solar cell ohmic contacts, and formation of a first metallization layer (also known as M1)—see FIG. 5A for an example of a back-contact/back-junction (IBC) solar cell fabrication process flow comprising a selective emitter process (with more lightly doped field emitter and more heavily doped emitter contact regions) using double-BSG (BSG is boron-doped silicate glass or boron doped silicon oxide layer formed, for instance, by an atmospheric-pressure chemical-vapor deposition or APCVD process) process flow for selective emitter formation (other methods of selective emitter formation may be used instead of double BSG process, for instance, using screen printed dopant pastes); 5) attach or laminate backplane layer or sheet on back-contact cell backside; 6) laser scribe release border (lift off release boundary) around the backplane boundary at least partially into epitaxial silicon layer thickness and then release by a lift-off process (e.g., mechanical release lift-off to separate the backplane-attached epitaxial silicon substrate from the reusable template by breaking off the mechanically weakened higher porosity porous silicon layer); 7) perform the trenching (also called scribing or cutting or dicing) process using pulsed nanoseconds laser ablation (or one of the other suitable trench isolation formation methods as described earlier) from the solar cell sunnyside (opposite the backplane side) to monolithically partition the silicon substrate into the plurality of mini-cells or isles—for instance, into an array of isles comprising 4×4=16 mini-cells (also optionally trim the master cell peripheral boundary, for instance, using pulsed laser cutting, to establish the precise master cell or icell dimensions with well-defined smooth cell boundary edges); 8) proceed with performing the remaining back-end fabrication processes such as: wet silicon etch/texture in alkaline and/or acidic chemistry (this process performs the texturization on the frontside while the chemically-resistant backplane protects the backside of the solar cell from the texturization chemistry), post-texture surface preparation including wet cleaning (this process performs the frontside surface cleaning while the chemically-resistant backplane protects the backside of the solar cell from the wet cleaning chemistry), deposition of the frontside surface passivation and anti-reflection coating (ARC) layer(s), for instance, by Plasma-Enhanced Chemical-Vapor Deposition (PECVD) or a combination of PECVD for ARC deposition (e.g., hydrogenated silicon nitride) with another process such as Atomic Layer Deposition (ALD) for passivation layer deposition (such as a thin sub-30 nm layer of aluminum oxide, amorphous silicon, or amorphous silicon oxide directly on the cleaned, textured silicon surface and underneath the silicon nitride ARC layer—if using a multi-layer frontside passivation/ARC structure, such as a two-layer structure of one of the above-mentioned passivation layers covered by the silicon nitride ARC layer, the entire stack may also be deposited using PECVD using a vacuum-integrated process). The frontside passivation and ARC layer deposition will not only cover the frontside surfaces of the mini-cells or isles, it will also cover the sidewalls of the trench-partitioned isles or mini-cells, hence, substantially improving the passivation and ARC properties of the icell by improving the passivation and light capturing properties of the trench sidewalls as well as the top surfaces of the isles. After completion of the frontside texture/cleaning/passivation and ARC deposition processes, the remaining solar cell fabrication process step involves completion of the second metallization layer (M2) on the backplane-attached solar cell backside. In order to accomplish this task, a plurality of via holes are drilled according to a pre-designed via hole pattern, for instance using laser drilling, into the thin (e.g., 25 microns up to 250 microns backplane thickness), electrically insulating, continuous backplane layer (e.g., a 25 micron to 100 micron thick laminated prepreg sheet). The number of via holes on a solar cell (e.g., 156 mm×156 mm icell) backplane may be on the order of 100's to 1000's. The via holes may have average diagonal hole dimension (e.g., average diameter of each via hole) in the range of 10's of microns to 100's of microns (for instance, about 100 microns to 300 microns). The laser-drilled via holes through the electrically insulating backplane layer are positioned to land on the interdigitated base and emitter metallization fingers (formed by the first level of patterned metallization by screen printing of a metallic paste or by physical-vapor deposition and patterning of a metal layer such as a metal comprising aluminum or aluminum-silicon alloy). These via holes will serve as the interconnection channels or plugs between the first layer of patterned metallization or M1 formed directly on the solar cell backside prior to the backplane attachment/lamination and the second layer of patterned metal or M2 to be formed immediately after formation of the laser-drilled via holes. In some instances for the icells disclosed herein, the second level of patterned metallization M2 may be formed by one of several methods, including but not limited to one or a combination of: (1) Physical-Vapor Deposition or PVD (thermal evaporation and/or electron-beam evaporation and/or plasma sputtering) of an inexpensive high-conductivity metal comprising, for instance, aluminum and/or copper (other metals may also be used) followed by pulsed laser ablation patterning, (2) Physical-Vapor Deposition or PVD (thermal evaporation and/or electron-beam evaporation and/or plasma sputtering) of an inexpensive high-conductivity metal comprising, for instance, aluminum and/or copper (other metals may also be used) followed by metal etch patterning (e.g. screen printing of an etch paste or screen printing of a resist followed by a metal wet etch process and subsequent removal of the resist), (3) Screen printing or stencil printing of a suitable metal paste (such as a paste comprising copper and/or aluminum), (4) Inkjet printing or aerosol printing of a suitable metal paste (such as a paste comprising copper and/or aluminum), (5) Patterned plating of a suitable metal, for instance, copper plating. The patterned second layer of metallization (M2) may also comprise a thin capping layer (for instance, a thin <1 micron capping layer of NiV or Ni formed by plasma sputtering or screen printing or plating) to protect the main patterned M2 (e.g., aluminum and/or copper containing high conductivity metal) and to provide a suitable surface for soldering or conductive adhesive as needed. The back-contact/back-junction (IBC) solar cells described herein may utilize two layers of patterned metallization (M1 and M2), with the first patterned metallization layer M1 forming the interdigitated base and emitter metallization fingers on each mini-cell or isle according to a fine-pitch pattern (for instance, base-emitter M1 finger pitch in the range of about 200 microns to 2 mm, and in some cases in the range of about 500 microns to about 1 mm), and the second patterned layer of metallization M2 forming the final icell metallization and interconnecting the isles or mini-cells according to a pre-specified current and voltage scaling factor. Patterned M2 may be patterned substantially orthogonal or perpendicular to patterned M1 and have a much larger finger-to-finger pitch than patterned M1 fingers. This will substantially facilitate fabrication of patterned M2 according to a low-cost, high-yield manufacturing process. Patterned M2 not only formed the final icell patterned metallization, it also forms the electrically conductive via plugs through the laser-drilled via holes in order to complete the M2-to-M1 interconnections based on desired icell metallization structure.

It is also possible to extend the icell concept so that the second layer of patterned metallization M2 can be used to not only complete the individual master cell (or icell) electrical interconnections, but also monolithically interconnect a plurality of icells sharing the same continuous backplane layer, hence, resulting in a Monolithic Module structure facilitated and enabled by the icells embodiments and with numerous additional benefits. FIG. 5A for epitaxial silicon lift off icell representative embodiment shows the process flow for fabricating monolithic icells with each icell being attached to its own separate pre-cut continuous backplane layer, and each individual backplane attached icell being processed through the entire backend process flow after its backplane lamination. The icells processed using this approach will then be tested and sorted at the end of the process and can be assembled into the PV modules by interconnections of the icells to one another, for instance in electrical series, using tabbing and/or stringing of the cells (also involving soldering and/or conductive adhesives to interconnect the plurality of solar cells to one another as part of PV module assembly), and then completion of the module lamination and final module assembly and testing. With reference to FIG. 5A for epitaxial silicon lift off icell representative embodiment, an alternative embodiment of an icell implementation resulting in a novel monolithic module structure involves attachment or lamination of a plurality of relatively closely-spaced icells (for instance, with the adjacent icell to icell spacing in the range of 50 microns up to about 2 mm, and often in the range of about 100 microns to 1 mm) on their backsides to a larger continuous backplane sheet at the Backplane Lamination (or attachment step) performed by Tool 12. The remaining process steps after Tool 12 are performed concurrently on the plurality of icells sharing a common continuous backplane layer on their backsides (instead of being performed on the individual separate icells, each with their own separate backplane). After completion of the final metallization (patterned second layer of metal M2), the monolithic patterned M2 not only completes the metallization pattern for each icell among the plurality of the icells sharing the larger continuous backplane layer, it also completes electrical interconnections of the plurality of icells to one another according to any desired arrangement, for instance, interconnecting the icells to one another all in series or in a hybrid parallel/series arrangement. This embodiment enables fabrication of icells and the monolithic electrical interconnections among a plurality of icells on a shared continuous backplane layer, hence eliminating the need for subsequent soldering/tabbing/stringing of the icells to one another during the final module assembly. For example, in order to make 6×10=60-cell modules, an array of 6×10=60 icells are attached/laminated on their backsides immediately after completion of the patterned first layer of metal (M1)—after Tool 11 process in FIG. 5A—to a properly sized continuous backplane sheet (e.g., a sheet of prepreg) and the remaining process steps (starting with the backplane lamination/attachment process shown as Tool 12 and through the remaining backend process steps through completion of the second layer of patterned metal M2) are all performed on the large backplane-attached sheet comprising the plurality of (e.g., 6×10=60) icells. In this monolithic module example which comprises 6×10=60 icells, if each icell has dimensions of about 156 mm×156 mm and the spacing between the adjacent icells is about 1 mm, the continuous backplane layer or sheet (e.g., an aramid fiber/resin prepreg sheet with a thickness in the range of about 50 to 100 microns) to be used for attachment/lamination to the backsides of the 6×10 array of icells should have minimum dimensions of about 942 mm×1570 mm (e.g., the sheet may be made somewhat oversized to allow for backplane extensions in the side margins of the monolithic module, for instance, about 1 m×1.6 m backplane sheet dimensions in this 6×10=60 icell monolithic module example). As another example, in order to make 6×12=72-cell modules, an array of 6×12=72 icells are attached/laminated on their backsides immediately after completion of the patterned first layer of metal (M1)—after Tool 11 process in FIG. 5A—to a properly sized continuous backplane sheet (e.g., a sheet of prepreg) and the remaining process steps (starting with the backplane lamination/attachment process shown as Tool 12 and through the remaining backend process steps through completion of the second layer of patterned metal M2) are all performed on the large backplane-attached sheet comprising the plurality of (e.g., 6×12=72) icells. In this monolithic module example which comprises 6×12=72 icells, if each icell has dimensions of about 156 mm×156 mm and the spacing between the adjacent icells is about 1 mm, the continuous backplane layer or sheet (e.g., an aramid fiber/resin prepreg sheet with a thickness in the range of about 50 to 100 microns) to be used for attachment/lamination to the backsides of the 6×12 array of icells should have minimum dimensions of about 942 mm×1884 mm (e.g., the sheet may be made somewhat oversized to allow for backplane extensions in the side margins of the monolithic module, for instance, approximately 1 m×1.9 m backplane sheet dimensions in this 6×12=72 icell monolithic module example). The monolithic interconnections of the plurality of icells on a shared continuous backplane layer using the second layer of patterned metal M2 results in further reduction of the overall solar cell and PV module manufacturing cost as well as improved projected reliability of the PV modules during field operation (due to the elimination of soldered tabs, strings).

The embodiments of this invention can be applied to solar cells using this type of process flow as outlined in the representative process flow of FIG. 5A, as well as many other solar cell designs (as described before) and solar cell fabrication process flows including but not limited to the solar cells fabricated from starting monocrystalline wafers (e.g., Czochralski or CZ, Float Zone or FZ) or multi-crystalline wafers (from cast crystalline bricks or formed by a ribbon pulling process) or epitaxial growth or other substrate fabrication methods. Moreover, icell embodiments may be applied to other semiconductor materials besides silicon as described before, including but not limited to gallium arsenide, germanium, gallium nitride, other compound semiconductors, or a combination thereof.

FIG. 5B is a high level solar cell and module fabrication process flow embodiment using starting crystalline (mono-crystalline or multi-crystalline) silicon wafers. FIG. 5B shows a high-level icell process flow for fabrication of backplane-attached back-contact/back-junction (IBC) icells using two layers of metallization: M1 and M2. The first layer or level of patterned cell metallization M1 is formed as essentially the last process step among a plurality of front-end cell fab processes prior to the backplane lamination to the partially processed icell (or a larger continuous backplane attached to a plurality of partially processed icells when fabricating monolithic modules as described earlier). The front-end cell fab processes outlined in the top 4 boxes of FIG. 5B essentially complete the back-contact/back-junction solar cell backside structure through the patterned M1 layer. Patterned M1 is designed to conform to the icell isles (mini-cells) and comprises a fine-pitch interdigitated metallization pattern as described for the epitaxial silicon icell process flow outlined in FIG. 5A. In FIG. 5B, the fifth box from the top involves attachment or lamination of the backplane layer or sheet to the partially processed icell backside (or to the backsides of a plurality of partially processed icells when making a monolithic module)—this process step is essentially equivalent to the one performed by Tool 12 in FIG. 5A in case of epitaxial silicon lift-off process). In FIG. 5B, the sixth and seventh boxes from the top outline the back-end or post-backplane-attachment (also called post-lamination) cell fab processes to complete the remaining frontside (optional silicon wafer thinning etch to form thinner silicon absorber layer if desired, partitioning trenches, texturization, post-texturization cleaning, passivation and ARC) as well as the via holes and second level or layer of patterned metallization M2. The “post-lamination” processes (or the back-end cell fab processes performed after the backplane attachment) outlined in the sixth and seventh boxes of FIG. 5B essentially correspond to the processes performed by Tools 13 through 18 for the epitaxial silicon lift off process flow shown in FIG. 5A. The bottom box in FIG. 5B describes the final assembly of the resulting icells into either flexible, lightweight PV modules or into rigid glass-covered PV modules. If the process flow results in a monolithic module comprising a plurality of icells monolithically interconnected together by the patterned M2 (as described earlier for the epitaxial silicon lift off process flow), the remaining PV module fabrication process outlined in the bottom box of FIG. 5B would be simplified since the plurality of the interconnected icells sharing a larger continuous backplane and the patterned M2 metallization for cell-to-cell interconnections are already electrically interconnected and there is no need for tabbing and/or stringing and/or soldering of the solar cells to one another. The resulting monolithic module can be laminated into either a flexible, lightweight PV module (for instance, using a thin flexible fluoropolymer cover sheet such as ETFE or PFE on the frontside instead of rigid/heavy glass cover sheet) or a rigid, glass-covered PV module.

FIG. 5C illustrates an alternative high level solar cell (icell) and module fabrication process flow embodiment using epitaxial silicon and porous silicon lift-off processing as compared to the process flow of FIG. 5A. FIG. 5C also shows a high-level icell process flow for fabrication of backplane-attached back-contact/back-junction (IBC) icells using two layers of metallization: M1 and M2. The first layer or level of patterned cell metallization M1 is formed as essentially the last process step among a plurality of front-end cell fab processes prior to the backplane lamination to the partially processed icell using epitaxial silicon as the solar cell absorber (or a larger continuous backplane attached to a plurality of partially processed epitaxial icells after lift-off release of the individual partially processed icells, when fabricating monolithic modules as described earlier). The front-end cell fab processes outlined in the top 4 boxes of FIG. 5C essentially complete the back-contact/back-junction solar cell backside structure through the patterned M1 layer. Patterned M1 is designed to conform to the icell isles (mini-cells) and comprises a fine-pitch interdigitated metallization pattern as described for the epitaxial silicon icell process flow outlined in FIG. 5A. In FIG. 5C, the fifth box from the top involves attachment or lamination of the backplane layer or sheet to the partially processed epitaxial icell backside (or using a larger continuous backplane sheet to be attached to the backsides of a plurality of partially processed and released icells when making a monolithic module)—this process step is essentially equivalent to the one performed by Tool 12 in FIG. 5A in case of the earlier epitaxial silicon lift-off process flow). In FIG. 5C, the sixth and seventh boxes from the top outline the back-end or post-backplane-attachment (also called post-lamination) cell fab processes to complete the remaining frontside (icell partitioning trenches, texturization, post-texturization cleaning, passivation and ARC) as well as the via holes and second level or layer of patterned metallization M2. The “post-lamination” processes (or the back-end cell fab processes performed after the backplane attachment) outlined in the sixth and seventh boxes of FIG. 5C essentially correspond to the processes performed by Tools 13 through 18 for the epitaxial silicon lift off process flow shown in FIG. 5A. The bottom box in FIG. 5C describes the final assembly of the resulting icells into either flexible, lightweight PV modules or into rigid glass-covered PV modules. If the process flow results in a monolithic module comprising a plurality of icells monolithically interconnected together by the patterned M2 (as described earlier for the epitaxial silicon lift off process flow), the remaining PV module fabrication process outlined in the bottom box of FIG. 5C would be simplified since the plurality of the interconnected icells sharing a larger continuous backplane and the patterned M2 metallization for cell-to-cell interconnections are already electrically interconnected and there is no need for tabbing and/or stringing and/or soldering of the solar cells to one another. The resulting monolithic module can be laminated into either a flexible, lightweight PV module (for instance, using a thin flexible fluoropolymer cover sheet such as ETFE or PFE on the frontside instead of rigid/heavy glass cover sheet) or a rigid, glass-covered PV module.

FIG. 5D is a high level cross-sectional device diagram showing an expanded and selective simplified view of a mini-cell or isle among a plurality of isles in an icell after solar cell fabrication steps of an interdigitated back-contact (IBC) solar cell embodiment. Detailed doped emitter and base regions, optional front-surface field (FSF) and/or optional back-surface field (BSF) regions, contacts for M1 metallization, and conductive via plugs connecting patterned M1 to patterned M2 through the electrically-insulating continuous backplane layer are not shown.

FIG. 5E is a more detailed cross-sectional diagram showing an expanded view of a mini-cell or isle among a plurality of isles in an icell after solar cell fabrication steps of an interdigitated back-contact (IBC) solar cell embodiment. These cross-sectional diagrams are provided as descriptive embodiments to further detail cell architectures which may be used in accordance with the disclosed subject matter.

In practice, the isolation trenches partitioning the main initially continuous semiconductor substrate through the substrate layer thickness (either from a starting crystalline semiconductor wafer or from an epitaxially grown crystalline layer) into a plurality of mini-cells (or isles or sub-cells or tiles) on the continuous supporting backplane layer have average trench width which may be on the order of about 10's of microns (or in the range of about 10 microns to about 100 microns). As described earlier, trench isolation regions partitioning the backplane-attached semiconductor layer into a plurality of mini-cells (or isles or sub-cells or tiles) may be formed by using either pulsed laser ablation/scribing or another technique, for instance, by mechanical dicing/scribing or ultrasonic dicing/scribing or water jet dicing/scribing or another method (the terms scribing, dicing, cutting, and ablation are used interchangeably herein when describing the icell partitioning or isolation trench formation process; moreover, the terms partitioning trenches or isolation trenches are used interchangeably in this document when referring to the trench pattern formed through the semiconductor layer thickness to form a plurality of isles or mini-cells, all supported by and attached to a continuous backplane layer or sheet which is attached to the partially processed semiconductor substrate prior to the partitioning trench formation process). A suitable trench partitioning or isolation formation process such as a pulsed laser scribing or cutting process selectively cuts through the semiconductor layer and effectively stops on the backplane layer or sheet after cutting essentially through the entire thickness of the semiconductor layer without a substantial removal of the backplane material (hence, negligible or relatively small trenching of the backplane layer to maintain the integrity of the continuous backplane sheet). For instance, the partitioning trench formation process, such as a pulsed nanoseconds ablation scribing process, can be performed to form the desired partitioning trench pattern by cutting through the semiconductor layer thickness based on the desired trench pattern, while limiting the backplane sheet material removal to relatively small range between zero and less than a fraction of the backplane layer thickness (e.g., backplane material trenching depth limited to between zero and less than about 20% of the backplane layer thickness). This will ensure the overall mechanical, physical, and electrical integrity of the monolithic icell (or the monolithic module in the case of fabricating monolithic modules using a plurality of icells attached to a shared backplane sheet).

The methods and structures described herein provide for a master monolithic cell (icell) comprising trench-partitioned or trench-isolated isles (also referred to as tiles, pavers, sub-cells, or mini-cells). And while a common master monolithic cell (icell) shape is a square, the master cell (icell) may be chosen to have any desired geometrical shapes and dimensions, for example a full square, pseudo square, rectangle, pseudo-rectangle, parallelogram, hexagon, triangle, any polygon, circle, ellipse, or a combination thereof. The most common shapes used for crystalline silicon solar cells and modules are the full-square and pseudo-square solar cells. Furthermore, the trench-partitioned isles may be formed of various and individually different geometrical shapes and/or sizes (areas and side/diagonal dimensions), or may be uniformly sized and shaped (in other words uniformly sized and shaped isles having the same geometrical shapes and areas as one another). One consideration determining the shapes and sizes of the isles making up the solar cell is the desired degree of backplane-attached solar cell flexibility or bendability and pliability (when using a flexible backplane sheet such as a prepreg sheet) while minimizing or eliminating crack generation or crack propagation in resulting solar cell comprising the semiconductor absorber layer and in the solar cell metallization structure. In some instances, it may be desired to position relatively smaller isles (for example smaller triangular shaped or square shaped isles) proximate the master cell (icell) edge regions and relatively larger isles (for example square shaped) proximate the master cell (icell) center region (or the region away from the icell edges) since the solar cell edges may be more susceptible to crack formation and propagation during and after cell processing, during module lamination, and also during the field operation of the resulting PV modules. In other instances, and depending the on the isle electrical connection design, the isles (or a subgroup of isles connected in electrical parallel arrangement) may have a uniform shape to produce uniform current under uniform illumination. Importantly, any number of isle shapes and/or sizes may be used dependent on other considerations such as master cell (icell) flexibility/bendability and isle-to-isle electrical interconnection designs to produce the desired icell voltage and current scaling factor.

For a square-shaped or rectangular-shaped master cell (icell) having an array of square-shaped or rectangular-shaped isles attached to a shared continuous backplane, the isles may be an N×N array where N is an integer with N≧2 (for example N×N is greater than or equal to four, or in other words there are at least four isles in an icell). In general, an icell may have as few as 2 isles or subcells (e.g., a square-shaped icell with 2 sub-cells or isles may have two triangular isles). The icell configurations with N×N isles present the advantage of simplicity in terms of the icell processing and interconnection design, as well as good compatibility with full-square and pseudo-square solar cells. Alternatively, the isles may be in an N×M array where N and M are both integers (for example N×M is greater than or equal to 2, in other words there are at least two isles). Using a flexible continuous (or continuous) backplane, the degree of icell flexibility or bendability or pliability may be increased for larger values of N×N or N×M, and/or by using relatively smaller sized isles near the cell edge regions (compared to the isles away from the edge regions). For example, for a 156 mm×156 mm square-shaped or pseudo-square shaped icell, an icell with 4×4=16 isles (e.g., uniform area isles) will be more flexible or bendable than an icell with 3×3=9 isles (e.g., uniform area isles). Improved flexibility/bendability of icells are desirable attributes for flexible, lightweight PV modules. And while the number of isles in any shape may be increased or decreased depending on desired master cell flexibility or bendability or pliability, the removal of semiconductor material to form the partitioning trenches and corresponding increased cell edge area (total trench sidewall areas of the isles or mini-cells) should be limited, for example to no more than about 2% of the master cell (icell) area (the ratio R as discussed earlier in this document), and in some cases to less than 1% of the icell area.

In some instances, it may be desirable to increase cell pliability by shaping isles (tiles, mini-cells), for instance into certain geometrically shaped mini-cells such as triangular-shaped isles (mini-cells). For example, to enhanced cell flexibility or pliability in various bending directions (e.g., along X, Y, and diagonal axes) for a square-shaped or rectangular-shaped master cell (icell), the isles may be an array of triangles, or a combination of squares (and/or rectangles) and triangles (in some embodiments, square-shaped isles proximate the master cell center region and triangular isles proximate the cell edge regions). Importantly, various combinations of isle shapes and arrangements within the master cell (icell) may be formed in accordance with the disclosed subject matter.

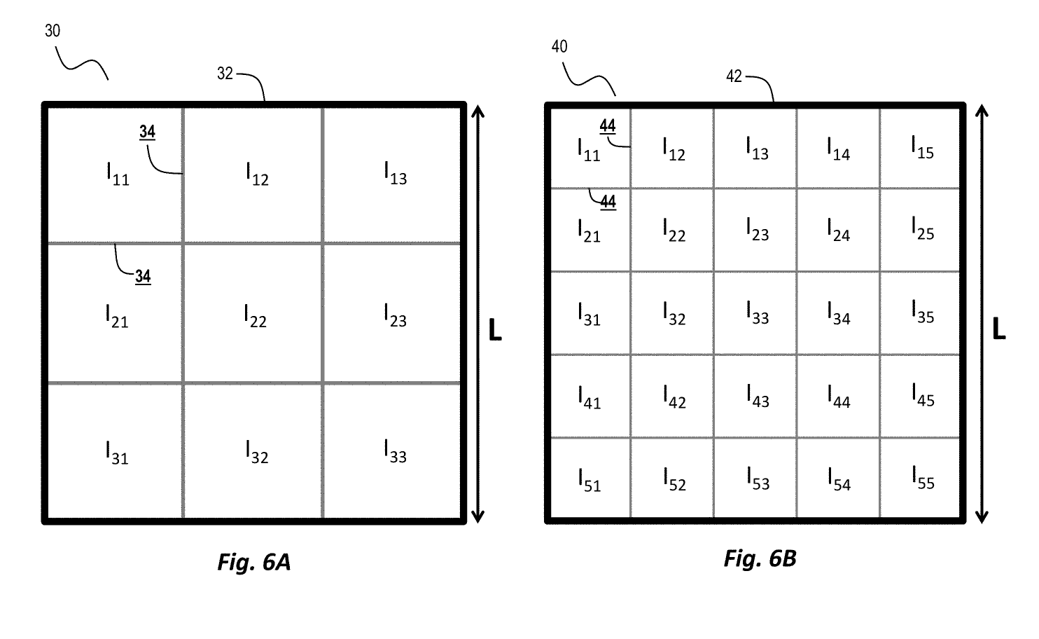

FIGS. 6A and 6B are diagrams of backplane-attached solar cell (icell) embodiments showing arrays of uniform square shaped mini-cells (i.e., isles or mini-cells all having essentially the same areas). FIG. 6A is a representative schematic plan view (frontside or sunnyside view) diagram of an icell pattern (shown for square-shaped isles and square-shaped icell) along with uniform-size (equal-size) square-shaped isles for N×N=3×3=9 isles (or sub-cells, mini-cells, tiles). This schematic diagram shows a plurality of isles (shown as 3×3=9 isles) partitioned by trench isolation regions. FIG. 6B is a representative schematic plan view (frontside or sunnyside view) diagram of an icell pattern (shown for square-shaped isles and square-shaped icell) along with uniform-size (equal-size) square-shaped isles for N×N=5×5=25 isles (or sub-cells, mini-cells, tiles). This schematic diagram shows a plurality of isles (shown as 5×5=25 isles) partitioned by trench isolation regions.

FIG. 6A is a schematic diagram of a top or plan view of a 3×3 uniform isled (tiled) master solar cell or icell 30 defined by cell peripheral boundary or edge region 32, having a side length L, and comprising nine (9) uniform square-shaped isles formed from the same original continuous substrate and identified as I₁₁ through I₃₃ attached to a continuous (continuous) backplane on the master cell backside (backplane and solar cell backside not shown). Each isle or sub-cell or mini-cell or tile is defined by an internal isle peripheral boundary (for example, an isolation trench cut through the master cell semiconductor substrate thickness and having a trench width substantially smaller than the isle side dimension, with the trench width no more than 100's of microns and often less than or equal to about 100 μm—for instance, a few up to about 100 μm) shown as trench isolation or isle partitioning borders 34. Main cell (or icell) peripheral boundary or edge region 32 has a total peripheral length of 4L; however, the total icell edge boundary length comprising the peripheral dimensions of all the isles comprises cell peripheral boundary 32 (also referred to as cell outer periphery) and trench isolation borders 34. Thus, for an icell comprising N×N isles or mini-cells in a square-shaped isle embodiment, the total icell edge length is N×cell outer periphery. In the representative example of FIG. 6A showing an icell with 3×3=9 isles, N=3, so total cell edge length is 3× cell outer periphery 4L=12L (hence, this icell has a peripheral dimension which is 3 times larger than that of the standard prior art cell shown in FIG. 1). For a square-shaped master cell or icell with dimensions 156 mm×156 mm, square isle side dimensions are approximately 52 mm×52 mm and each isle or sub-cell has an area of 27.04 cm² per isle.

FIG. 6B is a schematic diagram of a top or plan view of a 5×5 uniform isled (tiled) master solar cell or icell 40 defined by cell peripheral boundary or edge region 42, having a side length L, and comprising twenty five (25) uniform square-shaped isles formed from the same original continuous substrate and identified as I₁₁ through I₅₅ attached to a continuous (continuous) backplane on the master cell backside (backplane and solar cell backside not shown). Each isle or sub-cell or mini-cell or tile is defined by an internal isle peripheral boundary (for example, an isolation trench cut through the master cell semiconductor substrate thickness and having a trench width substantially smaller than the isle side dimension, with the trench width no more than 100's of microns and often less than or equal to about 100 μm—for instance, a few up to about 100 μm) shown as trench isolation or isle partitioning borders 44. Main cell (or icell) peripheral boundary or edge region 42 has a total peripheral length of 4L; however, the total icell edge boundary length comprising the peripheral dimensions of all the isles comprises cell peripheral boundary 42 (also referred to as cell outer periphery) and trench isolation borders 44. Thus, for an icell comprising N×N isles or mini-cells in a square-shaped isle embodiment, the total icell edge length is N×cell outer periphery. In the representative example of FIG. 6B showing an icell with 5×5=25 isles, N=5, so total cell edge length is 5× cell outer periphery 4L=20L (hence, this icell has a peripheral dimension which is 5 times larger than that of the standard prior art cell shown in FIG. 1). For a square-shaped master cell or icell with dimensions 156 mm×156 mm, square isle side dimensions are approximately 31.2 mm×31.2 mm and each isle or sub-cell has an area of 9.73 cm² per isle. In some instances when balanced with other considerations, it may be desired to keep total cell edge length (cumulative lengths of the sidewall edges of all the isles in an icell) to 24L (for example in a 6×6 array) in order to limit the total icell edge length and sidewall area.

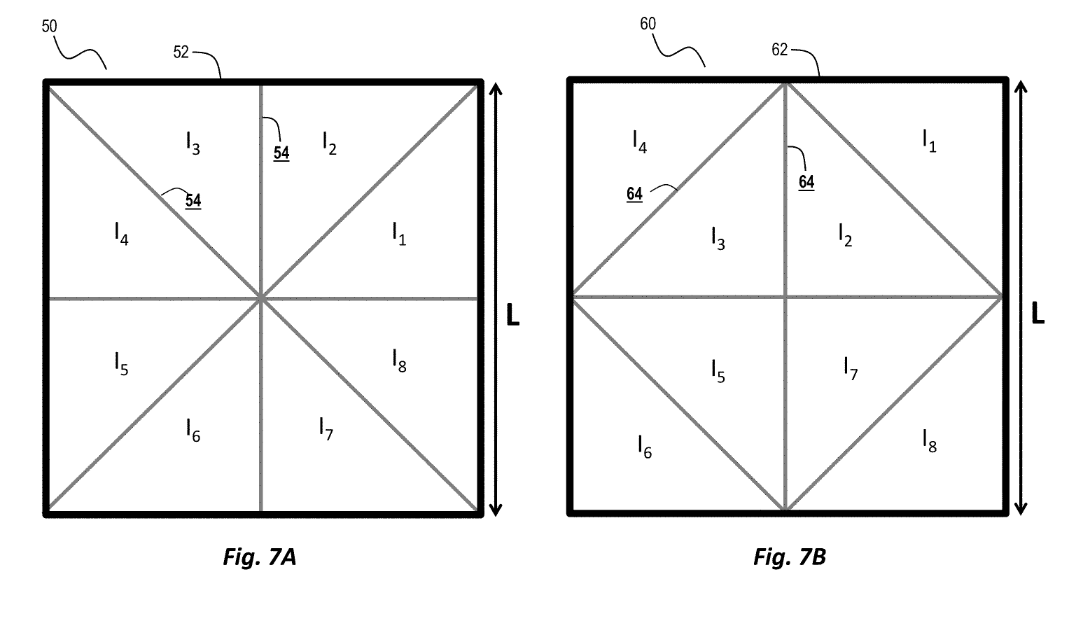

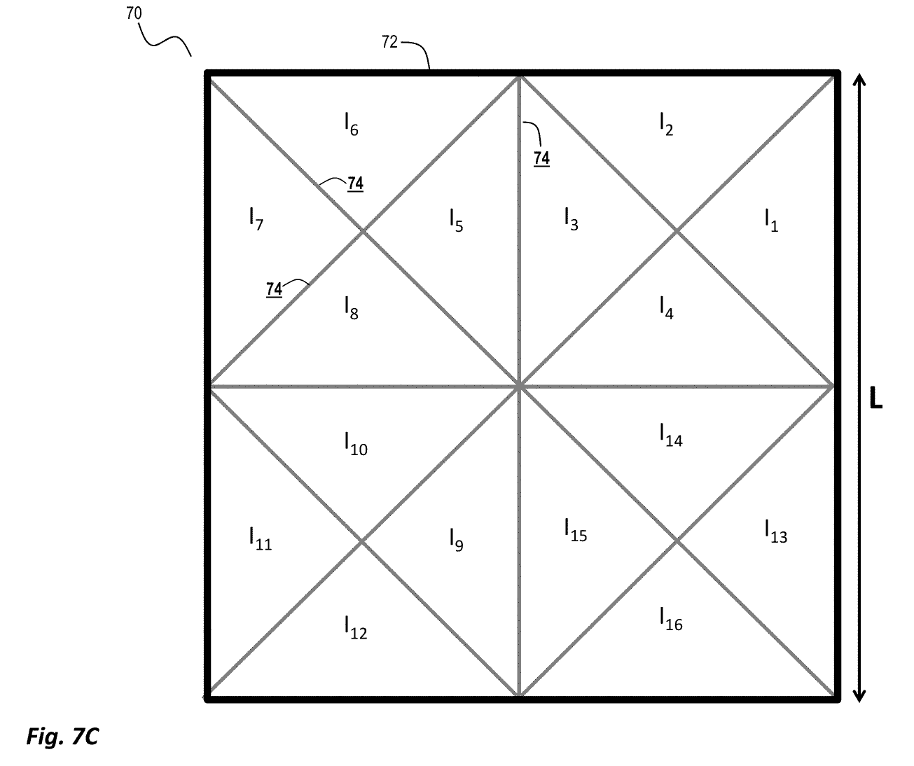

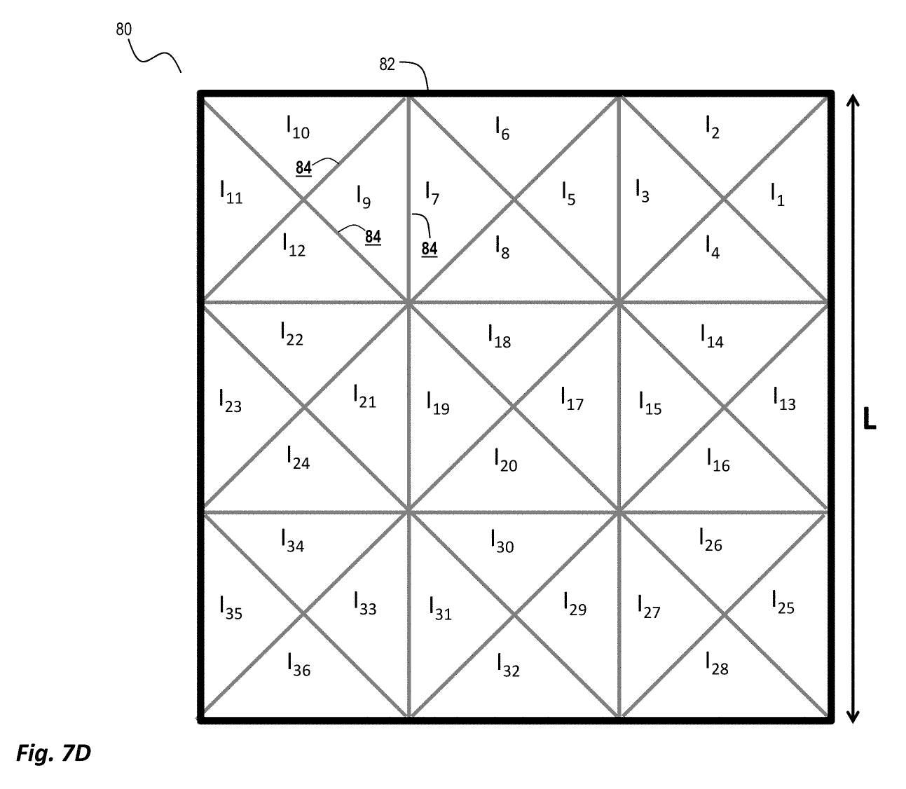

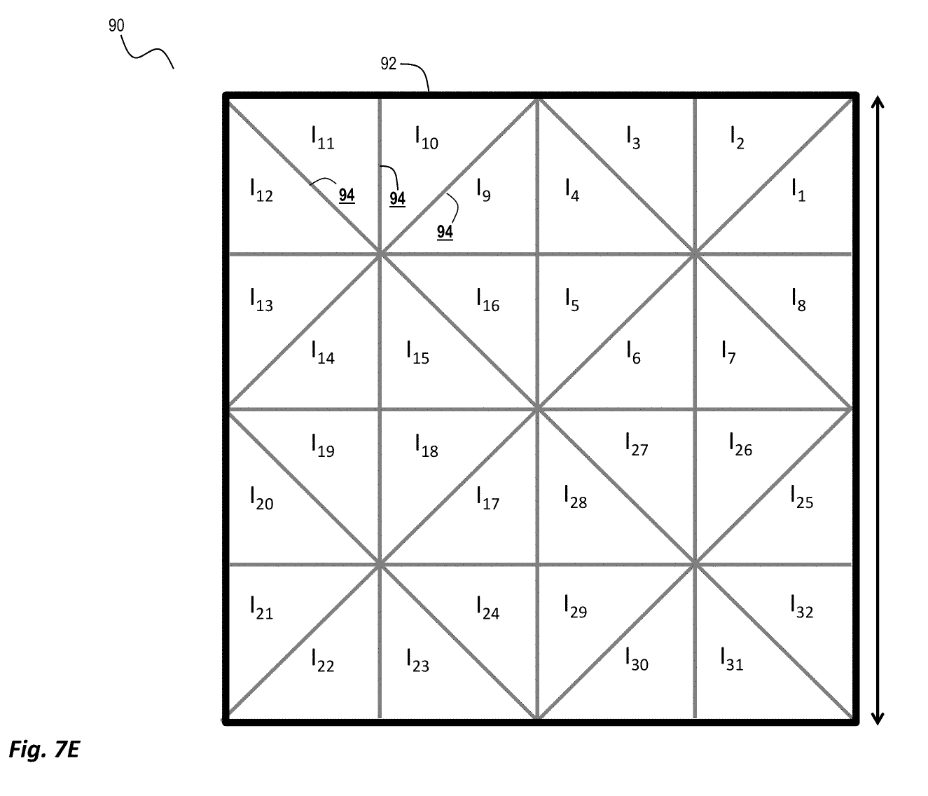

FIGS. 7A and 7E are representative plan view diagrams of solar cell embodiments (icells) with triangular shaped isles or mini-cells. FIG. 7A is a representative schematic plan view (frontside or sunnyside view) diagram of an icell pattern (shown for triangular-shaped isles and square-shaped icell) along with uniform-size (equal-size) triangular-shaped isles (or sub-cells, mini-cells, tiles) with K=2×4=8 triangular isles—a pair of triangular isles per square quadrant of the icell. This schematic diagram shows a plurality of isles (shown as K=2×4=8 isles) partitioned by trench isolation regions. FIG. 7B is a representative schematic plan view (frontside or sunnyside view) diagram of an icell pattern (shown for triangular-shaped isles and square-shaped icell) along with uniform-size (equal-size) triangular-shaped isles (or sub-cells, mini-cells, tiles) with K=2×4=8 triangular isles—a pair of triangular isles per square quadrant of the icell. This schematic diagram shows a plurality of isles (shown as K=2×4=8 isles) partitioned by trench isolation regions. The trench isolation pattern for the icell in FIG. 7B is slightly different than that in FIG. 7A. FIG. 7C is a representative schematic plan view (frontside or sunnyside view) diagram of an icell pattern (shown for triangular-shaped isles and square-shaped icell) along with uniform-size (equal-size) triangular-shaped isles (or sub-cells, mini-cells, tiles) with K=4×4=16 triangular isles—four triangular isles per square quadrant of the icell. This schematic diagram shows a plurality of isles (shown as K=4×4=16 isles) partitioned by trench isolation regions. The number of triangular isles (mini-cells) in this embodiment is twice the number of triangular isles (mini-cells) in the icell embodiments of FIG. 7A and FIG. 7B. FIG. 7D is a representative schematic plan view (frontside or sunnyside view) diagram of an icell pattern (shown for triangular-shaped isles and square-shaped icell) along with uniform-size (equal-size) triangular-shaped isles (or sub-cells, mini-cells, tiles) with K=4×3×3=36 triangular isles—four triangular isles per square quadrant of the icell. This schematic diagram shows a plurality of isles (shown as K=4×3×3=36 isles) partitioned by trench isolation regions. The number of triangular isles (mini-cells) in this embodiment is 4.5 times the number of triangular isles (mini-cells) in the icell embodiments of FIG. 7A and FIG. 7B.

FIG. 7E is a representative schematic plan view (frontside or sunnyside view) diagram of an icell pattern (shown for triangular-shaped isles and square-shaped icell) along with uniform-size (equal-size) triangular-shaped isles (or sub-cells, mini-cells, tiles) with K=2×4×4=32 triangular isles—eight triangular isles per square quadrant of the icell. This schematic diagram shows a plurality of isles (shown as 2×4×4=32 isles) partitioned by trench isolation regions. The number of triangular isles (mini-cells) in this embodiment is 4 times the number of triangular isles (mini-cells) in the icell embodiments of FIG. 7A and FIG. 7B.

FIG. 7A is a diagram of a top view of uniform triangular-shaped isles in an isled master solar cell or icell 50 defined by cell peripheral boundary 52 and having a side length L and comprising eight uniform (equal areas) triangular-shaped isles I₁ through I₈. Each isle or sub-cell or mini-cell or tile is defined by an internal isle peripheral boundary (for example, an isolation trench cut through the master cell semiconductor substrate thickness and having a trench width substantially smaller than the isle side dimension, with the trench width no more than 100's of microns and often less than or equal to about 100 μm—for instance, a few up to about 100 μm) shown as trench isolation or isle partitioning borders 54. Main cell (or icell) peripheral boundary or edge region 52 has a total peripheral length of 4L; however, the total icell edge boundary length comprising the peripheral dimensions of all the isles comprises cell peripheral boundary 52 (also referred to as cell outer periphery) and trench isolation borders 54. In the representative example of FIG. 7A showing an icell with K=2×4=8 triangular isles, K=8, so total cell edge length is 3.4142× cell outer periphery 4L=13.567L (hence, this icell has a peripheral dimension which is 3.4142 times larger than that of the standard prior art cell shown in FIG. 1). For a square-shaped master cell or icell with dimensions 156 mm×156 mm, triangular isle side dimensions are approximately 78 mm×78 mm (for the two equal right-angle sides of the triangle) and each isle or sub-cell has an area of 30.42 cm² per isle.

FIG. 7B is a diagram of a top view of uniform triangular-shaped isles in an isled master solar cell or icell 60 defined by cell peripheral boundary 62 and having a side length L and comprising an alternative arrangement of eight uniform (equal areas) triangular-shaped isles I₁ through I₈, as compared to the triangular isles or mini-cells pattern of FIG. 7A. Each isle or sub-cell or mini-cell or tile is defined by an internal isle peripheral boundary (for example, an isolation trench cut through the master cell semiconductor substrate thickness and having a trench width substantially smaller than the isle side dimension, with the trench width no more than 100's of microns and in some cases less than or equal to about 100 μm—for instance, a few up to about 100 μm) shown as trench isolation or isle partitioning borders 64. Main cell (or icell) peripheral boundary or edge region 62 has a total peripheral length of 4L; however, the total icell edge boundary length comprising the peripheral dimensions of all the isles comprises cell peripheral boundary 62 (also referred to as cell outer periphery) and trench isolation borders 64. In the representative example of FIG. 7B showing an icell with K=2×4=8 triangular isles, K=8, so total cell edge length is 3.4142× cell outer periphery 4L=13.567L (hence, this icell has a peripheral dimension which is 3.4142 times larger than that of the standard prior art cell shown in FIG. 1). For a square-shaped master cell or icell with dimensions 156 mm×156 mm, triangular isle side dimensions are approximately 78 mm×78 mm (for the two equal right-angle sides of the triangle) and each isle or sub-cell has an area of 30.42 cm² per isle.

FIG. 7C is a diagram of a top view of uniform triangular-shaped isles in an isled master solar cell or icell 70 defined by cell peripheral boundary 72 and having a side length L and comprising an arrangement of sixteen uniform (equal areas) triangular-shaped isles I₁ through I₁₆. Each isle or sub-cell or mini-cell or tile is defined by an internal isle peripheral boundary (for example, an isolation trench cut through the master cell semiconductor substrate thickness and having a trench width substantially smaller than the isle side dimension, with the trench width no more than 100's of microns and in some cases less than or equal to about 100 μm—for instance, a few up to about 100 μm) shown as trench isolation or isle partitioning borders 74. Main cell (or icell) peripheral boundary or edge region 72 has a total peripheral length of 4L; however, the total icell edge boundary length comprising the peripheral dimensions of all the isles comprises cell peripheral boundary 72 (also referred to as cell outer periphery) and trench isolation borders 74. In the representative example of FIG. 7C showing an icell with K=4×2×2=16 triangular isles, K=16, so total cell edge length is 4.8284× cell outer periphery 4L=19.313L (hence, this icell has a peripheral dimension which is 4.8284 times larger than that of the standard prior art cell shown in FIG. 1). For a square-shaped master cell or icell with dimensions 156 mm×156 mm, each triangular isle or sub-cell in this embodiment has an area of 15.21 cm² per isle.

FIG. 7D is a diagram of a top view of uniform triangular-shaped isles in an isled master solar cell or icell 80 defined by cell peripheral boundary 82 and having a side length L and comprising an arrangement of sixteen uniform (equal areas) triangular-shaped isles I₁ through I₃₆. Each triangular isle or sub-cell or mini-cell or tile is defined by an internal isle peripheral boundary (for example, an isolation trench cut through the master cell semiconductor substrate thickness and having a trench width substantially smaller than the isle side dimension, with the trench width no more than 100's of microns and often less than or equal to about 100 μm—for instance, a few up to about 100 μm) shown as trench isolation or isle partitioning borders 84. Main cell (or icell) peripheral boundary or edge region 82 has a total peripheral length of 4L; however, the total icell edge boundary length comprising the peripheral dimensions of all the isles comprises cell peripheral boundary 82 (also referred to as cell outer periphery) and trench isolation borders 84. In the representative example of FIG. 7D showing an icell with K=4×3×3=36 triangular isles, K=36, so total cell edge length is 7.2426× cell outer periphery 4L=28.970L (hence, this icell has a peripheral dimension which is 7.2426 times larger than that of the standard prior art cell shown in FIG. 1). For a square-shaped master cell or icell with dimensions 156 mm×156 mm, each triangular isle or sub-cell in this embodiment has an area of 6.76 cm² per isle.

FIG. 7E is a diagram of a top view of uniform triangular-shaped isles in an isled master solar cell or icell 90 defined by cell peripheral boundary 92 and having a side length L and comprising an arrangement of thirty two uniform (equal areas) triangular-shaped isles I₁ through I₃₂. Each triangular isle or sub-cell or mini-cell or tile is defined by an internal isle peripheral boundary (for example, an isolation trench cut through the master cell semiconductor substrate thickness and having a trench width substantially smaller than the isle side dimension, with the trench width no more than 100's of microns and often less than or equal to about 100 μm—for instance, a few up to about 100 μm) shown as trench isolation or isle partitioning borders 94. Main cell (or icell) peripheral boundary or edge region 92 has a total peripheral length of 4L; however, the total icell edge boundary length including the peripheral dimensions of all the isles comprises cell peripheral boundary 92 (also referred to as cell outer periphery) and trench isolation borders 94. In the representative example of FIG. 7E showing an icell with K=2×4×4=32 triangular isles, K=32, so total cell edge length is 6.8284× cell outer periphery 4L=27.313L (hence, this icell has a peripheral dimension which is 6.8284 times larger than that of the standard prior art cell shown in FIG. 1). For a square-shaped master cell or icell with dimensions 156 mm×156 mm, triangular isle side dimensions are approximately 39 mm×39 mm (for the two equal right-angle sides of the triangle) and each triangular isle or sub-cell in this embodiment has an area of 7.605 cm² per isle.

Thus, design of isles or mini-cells may include various geometrical shapes such as squares, triangles, rectangles, trapezoids, polygons, honeycomb hexagonal isles, or many other possible shapes and sizes. The shapes and sizes of isles, as well as the number of isles in an icell may be selected to provide optimal attributes for one or a combination of the following considerations: (i) overall crack elimination or mitigation in the master cell (icell); (ii) enhanced pliability and flexibility/bendability of master cell (icell) without crack generation and/or propagation and without loss of solar cell or module performance (power conversion efficiency); (iii) reduced metallization thickness and conductivity requirements (and hence, reduced metallization material consumption and processing cost) by reducing the master cell (icell) current and increasing the icell voltage (through series connection or a hybrid parallel-series connection of the isles in the monolithic icell, resulting in scaling up the voltage and scaling down the current); and (iv) providing relatively optimum combination of electrical voltage and current ranges in the resulting icell to facilitate and enable implementation of inexpensive distributed embedded electronics components on the icells and/or within the laminated PV modules comprising icells, including but not limited to at least one bypass switch (e.g., rectifying pn junction diode or Schottkty barrier diode) per icell, maximum-power-point tracking (MPPT) power optimizers (at least a plurality of MPPT power optimizers embedded in each module, with each MPPT power optimizer dedicated to at least 1 to a plurality of series-connected and/or parallel-connected icells), PV module power switching (with remote control on the power line in the installed PV array in order to switch the PV modules on or off as desired), module status (e.g., power delivery and temperature) during operation of the PV module in the field, etc. For example and as described earlier, in some applications and instances when considered along with other requirements, it may be desired to have smaller (for example triangular shaped) isles near the periphery of the master cell (icell) to reduce crack propagation and/or to improve flexibility/bendability of the resulting icells and flexible, lightweight PV modules.

A full-square master cell (icell) having an array of equivalently or uniformly sized N×N square-shaped isles or a plurality of equally sized triangular-shaped isles may be formed to match the photo-generated electrical current among isles or subgroups of isles connected in series. Thus, the square-shaped master cell (icell) may comprise N×N uniform (equally sized in terms of the isle areas) square-shaped or nearly square-shaped isles (with N being an integer: 2, 3, 4, . . . ) or K uniform triangular-shaped isles (with K being an integer, for example an even integer, equal to 4 or larger).

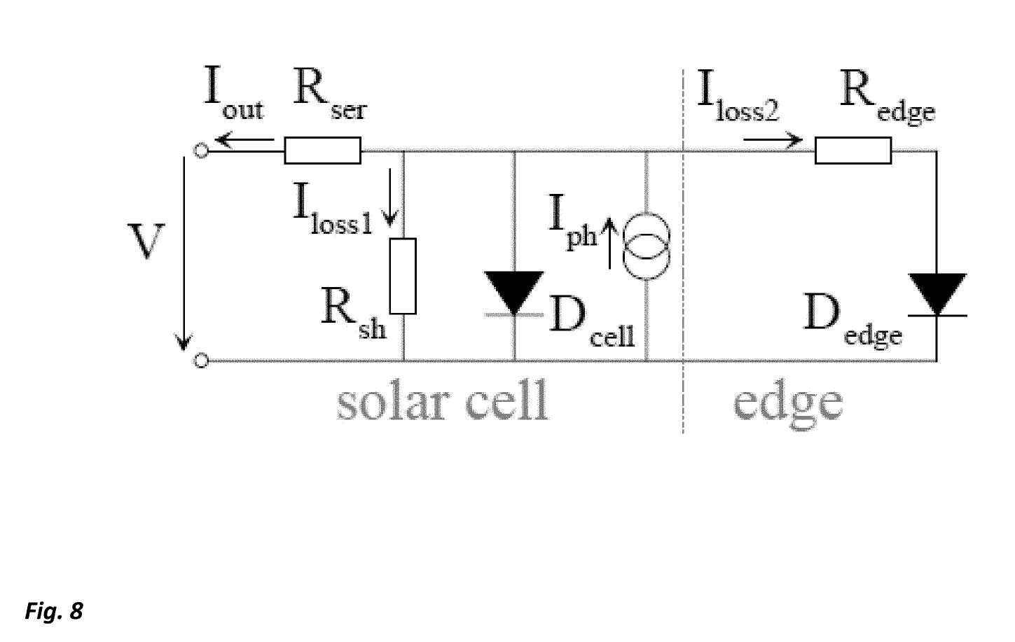

FIG. 8 is a schematic circuit diagram showing a simplified equivalent circuit model of a typical solar cell with edge recombination effects (as well as finite series resistance and shunt resistance values, and finite dark current). A realistic solar cell includes parasitic series and shunt resistances as well as edge recombination effects and dark current, all having detrimental impacts on the solar cell performance. An ideal solar cell has a zero series resistance, an infinite shunt resistance, zero dark current, and negligible or zero edge recombination effects. For known conventional crystalline silicon solar cells, a typical ratio of crystalline silicon wafer solar cell edge area to cell active (sunnyside) area is on the order of at least 0.50%.

The increased edge length of the monolithic isled solar cells (icells) described herein may (but not necessarily) increase solar cell edge recombination effects; however, very effective mitigation measures may be used to substantially decrease the edge effects of the mini-cell (isle) boundary trenches. Solar cell edge recombination currents may cause non-linear shunts and linear or super-linear reverse current instead of normal saturation behavior. Thus, it may be desirable to eliminate or minimize Iₗₒₛₛ₂ by substantially mitigating or minimizing the edge recombination effects. Edge recombination currents may be substantially reduced and/or eliminated by taking practical and effective measures in the design and during processing of solar cells.

Edge recombination currents are caused by edge regions that are highly disturbed and/or relatively un-passivated, and edge regions which may be in direct contact with the pn-junction (i.e., the solar cell pn junction and its depletion region contacting the edge regions). Edge losses occur due to cell damage (e.g., residual edge sidewall damage if not properly removed by an effective process, such as during the texturization wet etch after formation of the icell trenches, as described earlier) and poor or insufficient passivation of the solar cell edge sidewall areas (the main cell peripheral sidewall areas as well as the partitioning trench sidewall areas in the case of icells) and may be further exacerbated when the solar cell pn junction contacts the solar cell edge area (either around the main solar cell peripheral sidewalls and/or the partitioning trench sidewall areas in icells). To mitigate this problem, isle isolation trench formation followed by wet texture (silicon etch) also removing any residual trenching damages in the crystalline semiconductor layer sidewalls, wrap-around passivation (formed during the frontside passivation process) to passivate both the sunnyside/frontside surfaces and sidewalls of the edge regions of all the isles, and/or eliminating pn junction contact with edges of isles substantially reduce or eliminate the edge recombination effects from solar cells (icells). Measures to minimize or eliminate the trench isolation edge recombination currents in monolithic isled (tiled) solar cells (icells) which may be used individually or in combination, include: 1) separate/recess the emitter junction (for instance, the p+n emitter junction when using n-type base) of each isle (or mini-cell or sub-cell or tile) from the trench isolation edge (and from the main icell boundary edges) by a narrow base (e.g., n-type base when using n-type base and p+n emitter junction) rim, the separation may be as small as a one micron and as large as 100's of microns depending on the master cell (icell) size and isle size (and resolution of pattern formation during solar cell processing); 2) use laser scribing to form trench isolation regions from the cell sunnyside before wet etch texture process (to allow for the wet texture etch chemistry to etch off and remove any trenching-induced residual damage in the sidewalls of isles or mini-cells as well as the main boundary sidewalls of the icell; 3) perform wet etch texture which also removes a portion of crystalline silicon (for instance, from a few microns up to about 15 microns of silicon) to remove any process-induce (for instance, pulse-laser-ablation induced or mechanical dicing induce) damaged silicon from trench-partitioned edges (may be performed concurrent with the wet texture processing using either alkaline texture etch and/or acidic texture etch); and, 4) perform passivation/ARC process on the solar cell (icell) sunnyside after icell trench partitioning and wet etch texturing/surface cleaning, for instance by Plasma-Enhanced Chemical-Vapor Deposition (PECVD) and/or another suitable process such as Atomic Layer Deposition (ALD), which would also effectively cover and passivate all the sidewall edge regions, including the main icell peripheral boundary sidewalls as well as the trench sidewalls of all the isles, to substantially reduce or eliminate edge recombination loss effects. These measures will further enhance the substantial benefits of icell embodiments.

The following exemplary solar cell designs and manufacturing processes utilize a multi-layer metallization structure, and specifically two levels (or two layers) of solar cell metallization (i.e., dual layer metallization) which are physically separated by an electrically insulating backplane layer (backplane layer attached to the backside of the solar cell). For example, prior to backplane attachment (for instance, lamination of a thin prepreg sheet), the solar cell base and emitter contact metallization pattern (first layer of patterned metallization or M1) is formed directly on the solar cell backside, for instance using a relatively thin layer of screen printed paste (e.g., paste comprising aluminum or aluminum-silicon alloy) or plasma sputtered or evaporated (PVD) aluminum (or aluminum silicon alloy) material layer (followed by laser ablation or etchant patterning in the case of PVD-formed metal layer). This first patterned layer of metallization (herein also referred to as M1) defines the solar cell contact metallization pattern, such as fine-pitch interdigitated back-contact (IBC) conductor fingers defining the base and emitter metallization regions of the IBC cell. The M1 layer extracts the solar cell electrical power (current and voltage of the solar cell) and transfers the solar cell electrical power to the second patterned level/layer of higher-conductivity solar cell metallization (herein referred to as M2) formed after M1. The second layer or level of patterned metallization (M2) may comprise a relatively inexpensive and high-electrical-conductivity metal layer such as aluminum and/or copper (along with a suitable thin capping layer of NiV or Ni or another suitable capping metal).

As described with reference to the flow outlined in FIG. 4, after attachment or lamination of the backplane to the partially-processed solar cell backside (full attachment or lamination to the solar cell backside on and in around patterned M1 layer and exposed areas of the backside passivation layer), subsequent detachment of the backplane-supported solar cell from the template (in case of solar cells made using epitaxial silicon lift-off processing) OR subsequent optional silicon substrate thinning etch (in case of solar cells made using starting crystalline silicon wafers), completion of the frontside texture (e.g., using a wet alkaline or acidic wet etch texturization process) and frontside passivation and ARC deposition processes, and drilling of the via holes through the backplane layer, the patterned high sheet conductivity M2 layer is formed on the backplane (which forms both the patterned M2 layer as well as the conductive via plugs for the electrical interconnections between the patterned M2 and M1 metallization layers). Via holes (for instance, in the range of hundreds to thousands of via holes on the backplane for each solar cell) are drilled into the backplane (for example by laser drilling). These drilled via holes land on pre-specified regions of patterned M1 for subsequent electrical interconnections between the patterned M2 and M1 layers through conductive via plugs formed in these via holes (plugs may be formed concurrent with and as part of the patterned M2 formation process, or separately). Subsequently, the patterned higher-conductivity metallization layer M2 may be formed (for example, by screen printing, thermal or electron-beam evaporation, plasma sputtering, plating, or a combination thereof—using a relatively inexpensive high-conductivity M2 material comprising aluminum and/or copper). For an interdigitated back-contact (IBC) solar cell (icell) with M1 fine-pitch IBC fingers (for instance, hundreds of interdigitated M1 fingers per icell), the patterned M2 layer may be designed to be substantially orthogonal or perpendicular to the patterned M1 fingers—in other words the patterned M2 rectangular or tapered (e.g., triangular or trapezoidal) fingers are essentially perpendicular to the M1 fingers. Because of this orthogonal transformation of M2 fingers with respect to M1 fingers, the patterned M2 layer may have far fewer IBC fingers than the M1 layer (for instance, by a factor of about 10 to 50 fewer M2 fingers per mini-cell or unit-cell in some instances). Hence, the M2 layer may be formed in a much coarser pattern with much wider IBC fingers (and much larger base-emitter metal finger pitch) than the interdigitated M1 layer. Solar cell busbars may be positioned on the M2 layer, and not on the M1 layer (in other words a busbarless patterned M1 layer), to eliminate electrical shading losses associated with on-cell busbars. As both the base and emitter interconnections and busbars may be positioned on the patterned M2 layer on the solar cell backside backplane, electrical access is provided to both the base and emitter terminals of the solar cell on the backplane from the backside of the solar cell.

The continuous backplane material formed between the patterned M1 and M2 layers may be a thin sheet of an electrically insulating material, for instance, a suitable polymeric material such as an aramid fiber prepreg material, with sufficiently matching coefficient of thermal expansion (CTE) with respect to CTE of the semiconductor layer (e.g., crystalline silicon for crystalline silicon solar cells) to avoid causing excessive thermally induced stresses on the thin silicon layer. Moreover, the backplane layer should meet the solar cell process integration requirements for the backend cell fabrication processes, in particular relatively good chemical resistance during optional wet silicon thinning etch and during wet texturing of the cell frontside, and relatively good thermal stability (for instance, up to about 400° C. thermal stability) during the subsequent deposition of the frontside passivation and ARC layer(s) as well as during the subsequent M2 fabrication process (if applicable). The electrically insulating continuous backplane layer should also meet the module-level lamination processing and long-term PV module reliability requirements. While various suitable polymeric (such as plastics, fluropolymers, prepregs, etc.) and suitable non-polymeric materials (such as glass, ceramics, etc.) may be used as the electrically insulating backplane material, the desired backplane material choice depends on many considerations including, but not limited to, cost, ease of process integration, relative CTE match to silicon, thermal stability, chemical resistance, reliability, flexibility/pliability, etc.

One suitable material choice for the continuous backplane layer is prepreg sheet (comprising a combination of fibers and resin). Prepreg sheets are used as building blocks of printed circuit boards and may be made from combinations of resins and CTE-reducing fibers or particles. The backplane material may be a relatively inexpensive, low-CTE (typically with CTE <10 ppm/° C., or in some instances with CTE <5 ppm/° C.), thin (usually 50 microns to 250 microns, and in some instances in the range of about 50 to 150 microns) prepreg sheet which is relatively chemically resistant to the optional silicon thinning etch chemistry (e.g., alkaline or acidic silicon etch chemistry) and texturization chemicals (e.g., alkaline or acidic silicon texturization chemistry), and is relatively thermally stable at temperatures up to at least 180° C. (and in some instances to temperatures as high about 400° C. during the back-end solar cell processing). In the case of solar cells fabricated using epitaxial silicon lift-off processing, the prepreg sheet may be attached to the solar cell backside after completion of the solar cell backside processing through the formation of the patterned M1 layer, while still on the reusable template (before the cell lift off release process if applicable) using a thermal-vacuum laminator. Alternatively in the case of solar cells fabricated using crystalline silicon wafers (no epitaxial lift-off processing), the prepreg sheet may be attached to the solar cell wafer backside after completion of the solar cell backside processing through the formation of the patterned M1 layer, again using a thermal-vacuum laminator. Upon applying a combination of heat and pressure, the thin continuous prepreg sheet (for instance, a 50 to 250 micron thick layer of aramid fiber prepreg sheet) is permanently laminated or attached to the backside of the processed solar cell (or a plurality of solar cells in the case of monolithic module embodiment). Then, as applicable in the case of solar cells fabricated using epitaxial silicon lift-off processing, the lift-off release boundary is defined around the periphery of the solar cell (near the reusable template edges), for example by using a pulsed laser scribing tool, and the backplane-laminated solar cell is then lifted off and separated from the reusable template using a mechanical release or lift-off process (the solar cells made on starting crystalline silicon wafers do not use a lift-off release process and directly proceed to the back-end solar cell processing after the backplane attachment/lamination process). Subsequent back-end process steps may include: (i) optional silicon thinning etch in the case of solar cells made on starting crystalline silicon wafers, completion of the wet texture and passivation and ARC deposition processes on the solar cell sunnyside, (ii) completion of formation of the solar cell backplane via holes and high-conductivity second layer metallization (M2) on the backplane-attached solar cell backside (which is formed on the solar cell backplane surface). The high-conductivity metallization for patterned M2 (for example comprising aluminum and/or copper, as opposed to silver in order to reduce the overall solar cell manufacturing and material costs) including interdigitated M2 metal fingers for both the emitter and base polarities is formed on the laminated solar cell backplane comprising the laser-drilled via holes.

As noted before, the backplane material may be made of a thin (for instance, about 50 to 250 microns in thickness), flexible, and electrically insulating polymeric material sheet such as a relatively inexpensive prepreg material commonly used in printed circuit boards (PCB) and other industrial applications, which meets the overall process integration and reliability requirements. Generally, prepregs are reinforcing materials pre-impregnated with resin and ready to use to produce composite parts (prepregs may be used to produce composites faster and easier than wet lay-up systems). Prepregs may be manufactured by combining reinforcement fibers or fabrics with specially formulated pre-catalyzed resins using equipment designed to ensure consistency. Covered by a flexible backing paper, prepregs may be easily handled and remain flexible/pliable for a certain time period (out-life) at room temperature. Further, prepreg advances have produced materials which do not require refrigeration for storage, prepregs with longer shelf life, and products that cure at lower temperatures. Prepreg laminates may be cured by heating under pressure (heat-pressure lamination). Conventional prepregs are formulated for autoclave curing while low-temperature prepregs may be fully cured by using vacuum bag pressure alone at much lower temperatures.

As disclosed and discussed previously, the monolithically isled cell (icell) designs and fabrication methods disclosed herein may be integrated with known solar cell designs and fabrication process flows, including for back-contact solar cells, without substantially altering or adding manufacturing process steps or tools, and thus without substantially adding to the cost of manufacturing the solar cell. In fact, the manufacturing costs of solar cells and modules may be reduced as a result of the icell innovations (as well as the monolithic module embodiment innovations comprising icells). In one embodiment, the combination of cell designs in conjunction with a continuous backplane and metallization structure (specifically two patterned metallization layers or levels—M1 and M2) provides a back-junction/back-contact solar cell architecture. However, various combinations of the backplane and metallization layers may serve as permanent flexible or semi-flexible or rigid structural support/reinforcement and provide high-conductivity (e.g., comprising aluminum and/or copper metallization material) interconnects for a high-efficiency crystalline silicon solar cell without significantly compromising solar cell power or adding to solar cell manufacturing cost.

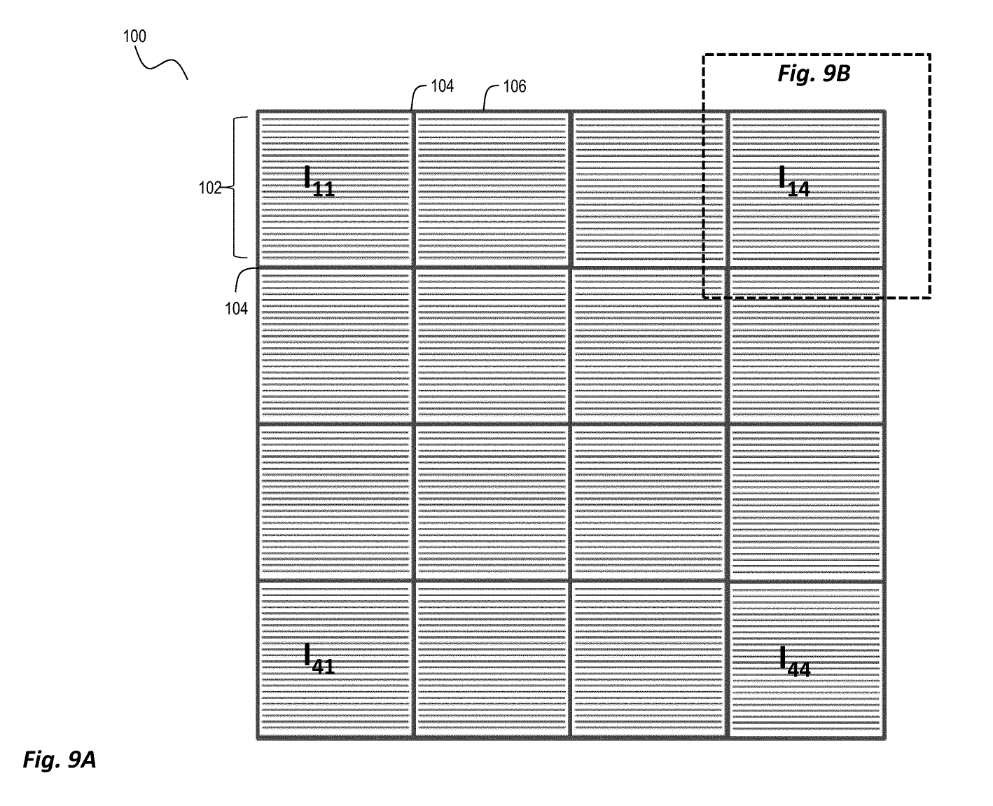

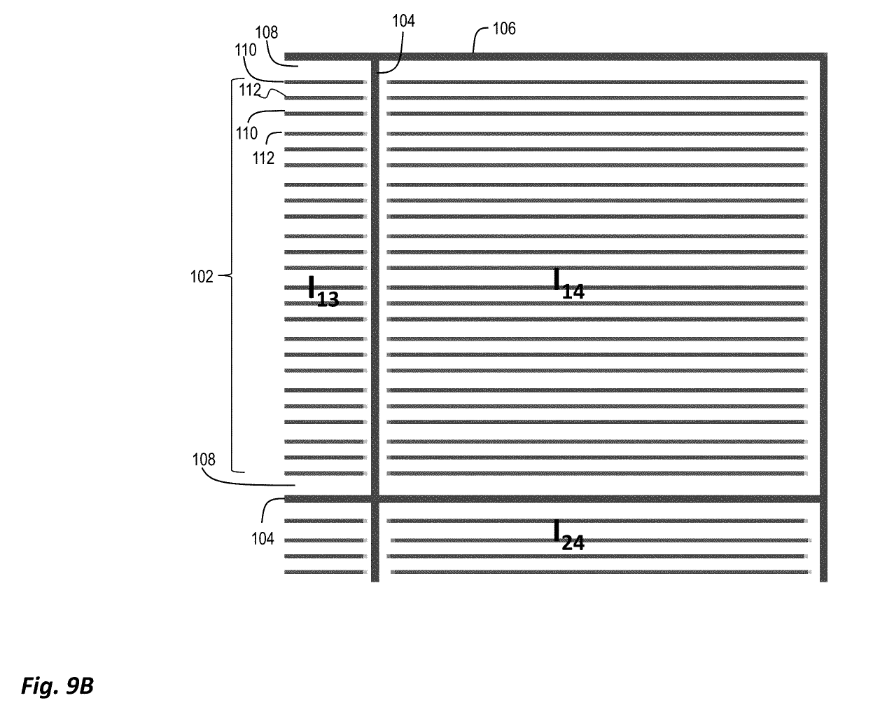

FIG. 9A is a schematic diagram showing a backside plan view of a busbarless first metallization layer pattern (M1) formed on master cell or icell with 4×4 square-shaped isles (this icell M1 pattern rear view corresponds to the frontside view shown in FIG. 2 for an icell with the same 4×4 square-shaped isles arrangement). FIG. 9B is an expanded view of a section of the schematic diagram of FIG. 9A, showing the expanded backside plan view of one of the isles of FIG. 9A (e.g., the isle designated by I14), indicating its island of busbarless first metallization layer pattern (M1) interdigitated base and emitter metal fingers, electrically isolated from the interdigitated base and emitter M1 fingers of the other isles in the icell.

FIG. 9A is a schematic diagram showing a backside plan view of a busbarless first metallization layer pattern (M1), comprising a plurality of islands (corresponding to the plurality—4×4 array in this representative example—of isles in the icell) of patterned fine-pitch interdigitated base and emitter metallization fingers, formed on master cell or icell 100 prior to the backplane attachment or lamination to the epitaxially grown (e.g., on porous silicon on template) or crystalline wafer-based semiconductor substrate. This design corresponds to the icell with a 4×4 array of square-shaped isles shown in FIG. 2. FIG. 9B is an expanded backside view of a solar cell isle from FIG. 9A with its patterned M1 metallization layer forming the fine-pitch busbarless interdigitated base and emitter metallization fingers (for instance, for the back junction/back-contact or IBC icell or master cell). Consistent with the icell embodiment as described previously with reference to FIG. 2, partially-processed master cell or icell 100 (processed through the first layer or level of patterned metal M1) is defined by cell peripheral boundary 106 and, in this representative embodiment, comprises 4×4=16 uniform (equal isle areas) square-shaped isles I₁₁ through I₄₄ to be subsequently defined (after the backplane attachment or lamination to the solar cell backside) by formation of the partitioning trench isolation borders, shown as borders 104 projected towards this backside view from frontside of the solar cell where the partitioning trenches will be formed. Note that the partitioning trenches will be formed from the sunnyside of the semiconductor substrate on the opposite side of the backplane. In FIG. 9A and FIG. 9B, the isle-partitioning borders 104 also define the M1 metallization islands (plurality of islands of interdigitated base and emitter metallization fingers formed by patterned M1) for the isles forming the icell (array of 4×4 isles in this embodiment). The 4×4 islands of interdigitated M1 fingers may be physically separated (i.e., the interdigitated fingers do not cross or violate the partitioning borders 104) and electrically isolated from each other. The entire plurality of patterned M1 islands (4×4 array of M1 islands in this embodiment, comprising a relatively high conductivity and inexpensive metal capable of making good ohmic contacts to both n-type and p-type silicon, such as aluminum) are formed concurrently on the backside of the solar cell by a suitable process such as screen printing of a suitable paste (aluminum or aluminum-silicon alloy paste) or PVD and post-PVD patterning (by pulsed laser ablation patterning or patterned etching). The isles or sub-cells or mini-cells, are monolithically formed (from the same initially continuous semiconductor layer) trench partitioned and isolated islands of a semiconductor layer (for example, an epitaxially grown silicon layer or a silicon layer from a starting crystalline silicon wafer)) on a shared continuous or continuous backplane layer/sheet (backplane not shown here but will be attached or laminated to the solar cell backside comprising the backside passivation and patterned on-cell M1 layers). The plurality of islands (4×4=16 in this embodiment) of patterned M1 interdigitated metallization fingers 102 are formed on the solar cell backside corresponding to and consistent with the icell pattern of trench-partitioned semiconductor isles on the solar cell frontside, with each island of interdigitated base and emitter metal fingers corresponding to the M1 metallization for each isle. The interdigitated base and emitter metal fingers on each M1 islands are shown without cell busbars on the M1 pattern (shown as alternating emitter M1 metal fingers 110 and base M1 metal fingers 112 formed on solar cell substrate backside 108, prior to the backplane attachment)—thus, there are no on-cell busbars. As shown in FIG. 9A and FIG. 9B, the patterned interdigitated M1 metallization fingers for each M1 island (corresponding to each trench-partitioned isle for the resulting icell) are physically and electrically isolated from the patterned interdigitated M1 metallization fingers of the other neighboring islands. Mostly but not necessarily, the electrical interconnections among various trench-partitioned isles of an icell are made through the second patterned metallization layer M2 after completion of the backplane attachment to the partially-processed solar cell backside and towards the end of the back-end processing of the solar cell. Some embodiments may utilize the patterned M1 layer to also interconnect the adjacent or neighboring trench-partitioned isles, for instance, in electrical parallel and/or series connections. In some instances, if applicable and desired, M1 metallization layer may be formed on the solar cell substrate backside 108, such as in the case of solar cell being made from an epitaxially grown silicon substrate, while the partially-processed epitaxial solar cell is still attached to its supporting crystalline silicon template structure on the cell sunnyside. This was described earlier in conjunction with the epitaxial silicon solar cell fabrication process flows.

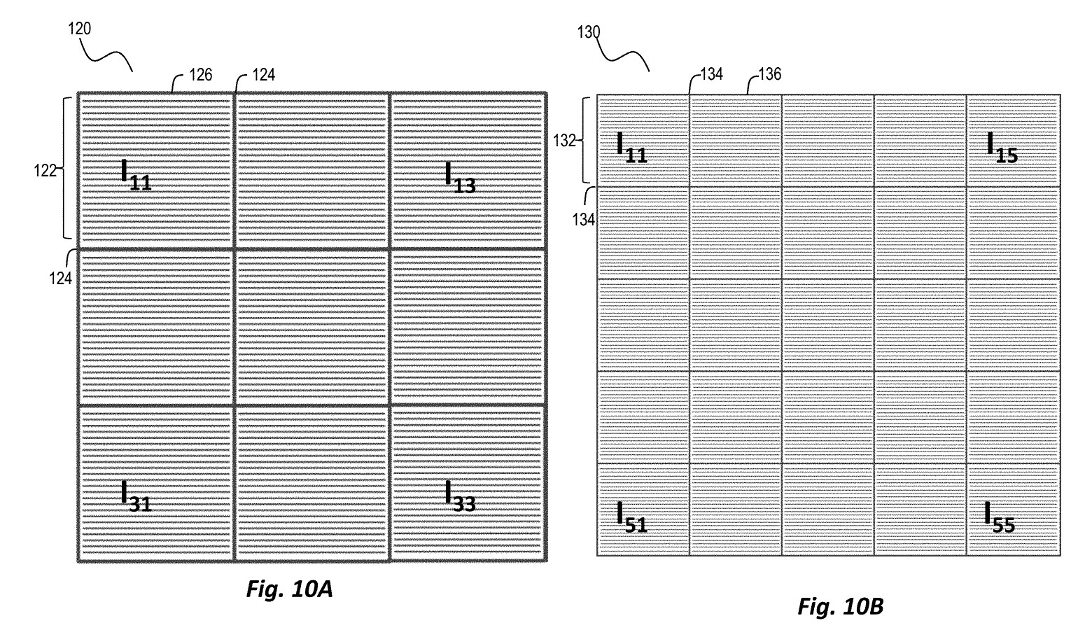

FIG. 10A is a schematic diagram showing a backside plan view of a busbarless first metallization layer pattern (M1) formed on master cell or icell with 3×3 square-shaped isles (this icell M1 pattern rear view corresponds to the frontside view shown in FIG. 6A for an icell with the same 3×3 square-shaped isles arrangement). FIG. 10B is a schematic diagram showing a backside plan view of a busbarless first metallization layer pattern (M1) formed on master cell or icell with 5×5 square-shaped isles (this icell M1 pattern rear view corresponds to the frontside view shown in FIG. 6B for an icell with the same 5×5 square-shaped isles arrangement).

FIGS. 10A and 10B are a schematic diagrams showing a backside plan views of a busbarless first metallization layer pattern (M1), comprising a plurality of M1 metal pattern islands (corresponding to the 3×3=9 array in FIG. 10A and 5×5=25 array in FIG. 10B in these representative examples—of isles in the icell) of patterned fine-pitch interdigitated base and emitter metallization fingers, formed on master cell or icell 120 in FIG. 10A and 130 in FIG. 10B prior to the backplane attachment or lamination to the epitaxially grown (on template) or crystalline wafer-based semiconductor substrate. These designs correspond to the icells with a 3×3 array of isles shown in FIG. 6A and the icells with a 5×5 array of isles shown in FIG. 6B). In FIG. 10A, consistent with the icell embodiment as described previously with reference to FIG. 6A, partially-processed master cell or icell 120 (processed through the first layer or level of patterned metal M1) is defined by cell peripheral boundary 126 and, in this representative embodiment, comprises 3×3=9 uniform (equal isle areas) square-shaped isles I₁₁ through I₃₃ to be subsequently defined (after the backplane attachment or lamination to the solar cell backside) by formation of the partitioning trench isolation borders, shown as borders 124 projected towards this backside view from the frontside of the solar cell where the partitioning trenches will be formed through the semiconductor layer. Note that the partitioning trenches will be formed from the sunnyside of the semiconductor substrate on the opposite side of the backplane. In FIG. 10A, the partitioning borders 124 also define the M1 metallization islands (plurality of islands of interdigitated base and emitter metallization fingers) for the isles forming the icell (3×3 isles in this embodiment). The 3×3 islands of interdigitated M1 fingers may be physically separated (i.e., the interdigitated fingers do not cross or violate the partitioning borders 124) and electrically isolated from each other. The entire plurality of patterned M1 islands (3×3 array of M1 islands in this embodiment, comprising a relatively high conductivity and inexpensive metal capable of making good ohmic contacts to both n-type and p-type silicon, such as aluminum) are formed concurrently on the backside of the solar cell by a suitable process such as screen printing of a suitable paste (such as a paste comprising aluminum or aluminum-silicon alloy) or PVD and post-PVD patterning (by pulsed laser ablation patterning or patterned etching). The isles or sub-cells or mini-cells, are monolithically formed (from the same initially continuous semiconductor layer) trench partitioned and isolated islands of a semiconductor layer (for example, an epitaxially grown silicon layer or a silicon layer from a starting crystalline silicon wafer) on a shared continuous or continuous backplane layer/sheet (backplane not shown here but will be attached or laminated to the solar cell backside comprising the backside passivation and patterned on-cell M1 layers). The plurality of islands (3×3=9 in this embodiment) of patterned M1 interdigitated metallization fingers 122 are formed on the solar cell backside corresponding to and consistent with the icell pattern of trench-partitioned semiconductor isles on the solar cell frontside, with each island of interdigitated base and emitter metal fingers corresponding to the metallization region for each isle. The interdigitated base and emitter metal fingers on each M1 islands are shown without cell busbars on the M1 pattern (shown as alternating emitter and base M1 metal lines 122 formed on solar cell substrate backside, prior to the backplane attachment)—thus, there is no on-cell busbar. As shown in FIG. 10A, the patterned interdigitated M1 metallization fingers for each M1 island (corresponding to each trench-partitioned isle for the resulting icell) are physically and electrically isolated from the patterned interdigitated M1 metallization fingers of the other neighboring islands. In some instances the electrical interconnections among various trench-partitioned isles of an icell are made through the second patterned metallization layer M2 after completion of the backplane attachment to the solar cell backside and towards the end of the back-end processing of the solar cell. Some embodiments may utilize the patterned M1 layer to also interconnect some adjacent or neighboring trench-partitioned isles, for instance, in electrical parallel and/or connections. In some instances, if applicable and desired, M1 metallization layer may be formed on the solar cell substrate backside, such as in the case of solar cell being made from an epitaxially grown silicon substrate, while the partially-processed epitaxial solar cell is still attached to its supporting crystalline silicon template structure on the cell sunnyside. This was described earlier in conjunction with the epitaxial silicon solar cell fabrication process flows.

In FIG. 10B, consistent with the icell embodiment as described previously with reference to FIG. 6B, partially-processed master cell or icell 130 (processed through the first layer or level of patterned metal M1) is defined by cell peripheral boundary 136 and, in this representative embodiment, comprises 5×5=25 uniform (equal isle areas) square-shaped isles I₁₁ through I₅₅ to be subsequently defined (after the backplane attachment or lamination to the solar cell backside) by formation of the partitioning trench isolation borders, shown as borders 134 projected towards this backside view from the frontside of the solar cell where the partitioning trenches will be formed. Note that the partitioning trenches will be formed from the sunnyside of the semiconductor substrate on the opposite side of the backplane. In FIG. 10B, the partitioning borders 134 also define the M1 metallization islands (plurality of islands of interdigitated base and emitter metallization fingers) for the isles forming the icell (5×5=25 isles in this embodiment). The 5×5=25 islands of interdigitated M1 fingers may be physically separated (i.e., the interdigitated fingers do not cross or violate the partitioning borders 134) and electrically isolated from each other. The entire plurality of patterned M1 islands (5×5=25 array of M1 islands in this embodiment, comprising a relatively high conductivity and inexpensive metal capable of making good ohmic contacts to both n-type and p-type silicon, such as aluminum) are formed concurrently on the backside of the solar cell by a suitable process such as screen printing of a suitable paste (such as comprising aluminum or aluminum-silicon alloy) or PVD and post-PVD patterning (by pulsed laser ablation patterning or patterned etching). The isles or sub-cells or mini-cells, are monolithically formed (from the same initially continuous semiconductor layer) trench partitioned and isolated islands of a semiconductor layer (for example, an epitaxially grown silicon layer or a silicon layer from a starting crystalline silicon wafer) on a shared continuous or continuous backplane layer/sheet (backplane not shown here but will be attached or laminated to the solar cell backside comprising the backside passivation and patterned on-cell M1 layers). The plurality of islands (5×5=25 in this embodiment) of patterned M1 interdigitated metallization fingers 132 are formed on the solar cell backside corresponding to and consistent with the icell pattern of trench-partitioned semiconductor isles on the solar cell frontside, with each island of interdigitated base and emitter metal fingers corresponding to the M1 metallization region for each isle. The interdigitated base and emitter metal fingers on each M1 islands are shown without cell busbars on the M1 pattern (shown as alternating emitter and base M1 metal lines 132 formed on solar cell substrate backside, prior to the backplane attachment)—thus, there are no on-cell busbars (to prevent or minimize electrical shading losses). As shown in FIG. 10B, the patterned interdigitated M1 metallization fingers for each M1 island (corresponding to each trench-partitioned isle for the resulting icell) are physically and electrically isolated from the patterned interdigitated M1 metallization fingers of the other neighboring islands. The electrical interconnections among various trench-partitioned isles of an icell may be made through the second patterned metallization layer M2 after completion of the backplane attachment to the solar cell backside and towards the end of the back-end processing of the solar cell. Some embodiments may utilize the patterned M1 layer to also interconnect the adjacent or neighboring trench-partitioned isles, for instance, in electrical parallel connection. In some instances, if applicable and desired, M1 metallization layer may be formed on the solar cell substrate backside, such as in the case of solar cell being made from an epitaxially grown silicon substrate, while the partially-processed epitaxial solar cell is still attached to its supporting crystalline silicon template structure on the cell sunnyside. This was described earlier in conjunction with the epitaxial silicon solar cell fabrication process flows.

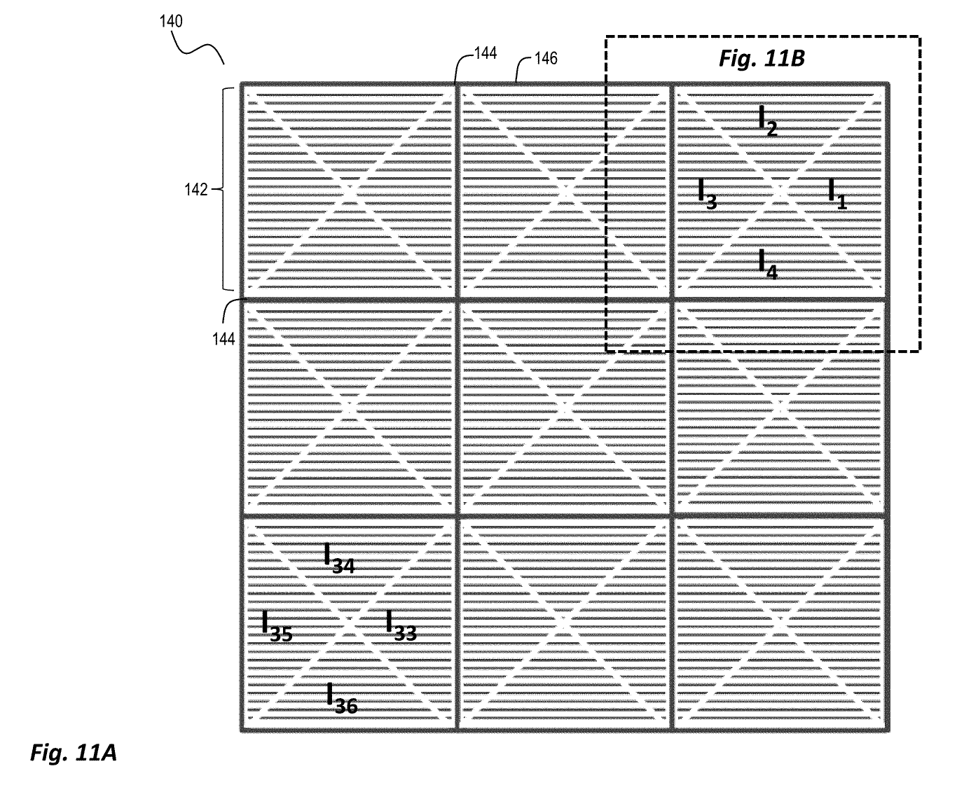

FIG. 11A is a schematic diagram showing a backside plan view of a busbarless first metallization layer pattern (M1) formed on master cell or icell with 4×3×3=36 triangular-shaped isles (this icell M1 pattern rear view corresponds to the frontside view shown in FIG. 7D for an icell with the same 4×3×3=36 triangular-shaped isles arrangement). FIG. 11B is an expanded view of a section of the schematic diagram of FIG. 11A, showing the expanded backside plan view of a group of triangular isles of FIG. 11A (e.g., the isles designated by I1, I2, I3, I4), indicating their triangular-shaped island of busbarless first metallization layer pattern (M1) interdigitated base and emitter metal fingers, electrically isolated from each other and the interdigitated base and emitter M1 fingers of the other isles in the icell.

FIG. 11A is a schematic diagram showing a backside plan views of a busbarless first metallization layer pattern (M1), comprising a plurality of islands (corresponding to the plurality—4×3×3=36 array of triangular isles in the icell in this representative example) of patterned fine-pitch interdigitated base and emitter metallization fingers, formed on master cell or icell 140 prior to the backplane attachment or lamination to the epitaxially grown (on template) or crystalline wafer-based semiconductor substrate. This design corresponds to the icell with 4×3×3 array of isles shown in FIG. 7D. FIG. 11B is an expanded backside view of a solar cell isle from FIG. 11A with its patterned M1 metallization layer forming the fine-pitch busbarless interdigitated base and emitter metallization fingers (for the back junction/back-contact or IBC solar cell). Consistent with the icell embodiment as described previously with reference to FIG. 7D, partially-processed master cell or icell 140 (processed through the first layer or level of patterned metal M1) is defined by master cell or icell peripheral boundary 146 and, in this representative embodiment, comprises 4×3×3=36 uniform (equal isle areas) triangular-shaped isles I₁ through I₃₆ to be subsequently defined (after the backplane attachment or lamination to the solar cell backside) by formation of the partitioning trench isolation borders through the semiconductor layer, shown as various border lines 144 and 154 (shown as dark axial—horizontal and vertical—lines, and white diagonal border lines, separating the triangular islands of interdigitated M1 metal fingers) projected towards this backside view from the frontside of the solar cell semiconductor substrate where the partitioning trenches will be formed. Note that the partitioning trenches will be formed from the sunnyside of the semiconductor substrate on the opposite side of the backplane. In FIG. 11A and FIG. 11B, the horizontal and vertical (also called axial herein) partitioning borders 144 and triangular pattern partitioning diagonal or angled borders 154 (shown as horizontal and vertical or axial dark lines as well as diagonal white lines—dark lines and white lines simply distinguish between the axial X and Y direction isle-partitioning borders vs. diagonal direction isle-partitioning borders) also define the M1 metallization islands (plurality of triangular-shaped islands of interdigitated base and emitter metallization fingers) for the triangular isles forming the icell (4×3×3=36 isles in this embodiment). The 4×3×3=36 islands of interdigitated M1 fingers may be physically separated (i.e., the interdigitated fingers do not cross the partitioning borders 144 and 154) and electrically isolated from each other. The entire plurality of patterned M1 islands (4×3×3=36 array of M1 islands in this embodiment, comprising a relatively high conductivity and inexpensive metal capable of making good ohmic contacts to both n-type and p-type silicon, such as aluminum) are formed concurrently on the backside of the solar cell by a suitable process such as screen printing of a suitable paste (such as a paste comprising aluminum or aluminum-silicon alloy) or PVD and post-PVD patterning (by pulsed laser ablation patterning or patterned etching). The isles or sub-cells or mini-cells, are monolithically formed (from the same initially continuous semiconductor layer) trench partitioned and isolated islands of a semiconductor layer (for example, an epitaxially grown silicon layer on porous silicon on template or a silicon layer from a starting crystalline silicon wafer)) on a shared continuous or continuous backplane layer/sheet (backplane not shown here but will be attached or laminated to the solar cell backside comprising the backside passivation and patterned on-cell M1 layers). The plurality of islands (4×3×3=36 in this embodiment) of patterned M1 interdigitated metallization fingers 142 are formed on the solar cell backside corresponding to and consistent with the icell pattern of trench-partitioned semiconductor isles on the solar cell frontside, with each island of interdigitated base and emitter metal fingers corresponding to the M1 metallization for each isle. The interdigitated base and emitter metal fingers on each M1 islands are shown without cell busbars on the M1 pattern (shown as alternating emitter M1 fingers 150 and base M1 fingers 152 formed on solar cell substrate backside 148, prior to the backplane attachment)—thus, there are no on-cell busbars (in order to avoid or eliminate electrical shading losses). As shown in FIG. 11A and FIG. 11B, the patterned interdigitated M1 metallization fingers for each triangular-shaped M1 island (corresponding to each trench-partitioned triangular-shaped isle for the resulting icell) are physically and electrically isolated from the patterned interdigitated M1 metallization fingers of the other neighboring islands. The electrical interconnections among various trench-partitioned isles of an icell are made through the second patterned metallization layer M2 after completion of the backplane attachment to the solar cell backside and towards the end of the back-end processing of the solar cell. Some embodiments may utilize the patterned M1 layer to also interconnect the adjacent or neighboring trench-partitioned isles, for instance, in electrical parallel and/or series connections. In some instances, if applicable and desired, M1 metallization layer may be formed on the solar cell substrate backside, such as in the case of solar cell being made from an epitaxially grown silicon substrate, while the partially-processed epitaxial solar cell is still attached to its supporting crystalline silicon template structure on the cell sunnyside. This was described earlier in conjunction with the epitaxial silicon solar cell fabrication process flows. In an icell embodiment with a plurality of triangular isles such as that shown in FIGS. 11 A and B, a set of four triangular isles forming a square (for example isle group I₁ through I₄ forming a square and isle group I₃₀ through I₃₆ forming another square) may be electrically connected in parallel using second patterned metallization layer M2 (which is not shown here) and the entire set of square regions (3×3 square regions in this embodiment, with each square region comprising 4 triangular isles) may then be electrically connected in series (e.g., 3×3=9 square regions to be connected in electrical series), or if desired, in a hybrid parallel-series arrangement. Thus, while the number of triangular isles is 4×3×3=36, the number of subgroups (S) connected in series (for a series-connected arrangement of groups of 4 triangular isles) is 3×3=9—in other words 9 square-shaped subgroups of 4 triangles, such as I1, I2, I3, and I4 forming a square (P=4 or 4 triangular isles confined within a square connected in electrical parallel by M2 and the 9 square regions each comprising 4 parallel-connected triangular isles, all connected in electrical series).

Representative M2 Metallization Embodiments

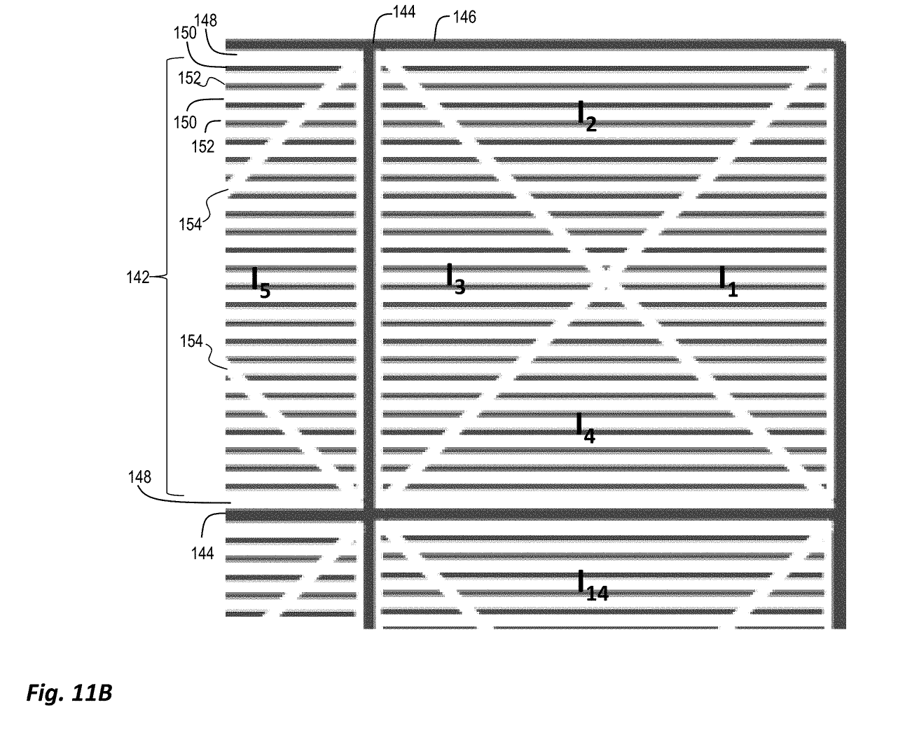

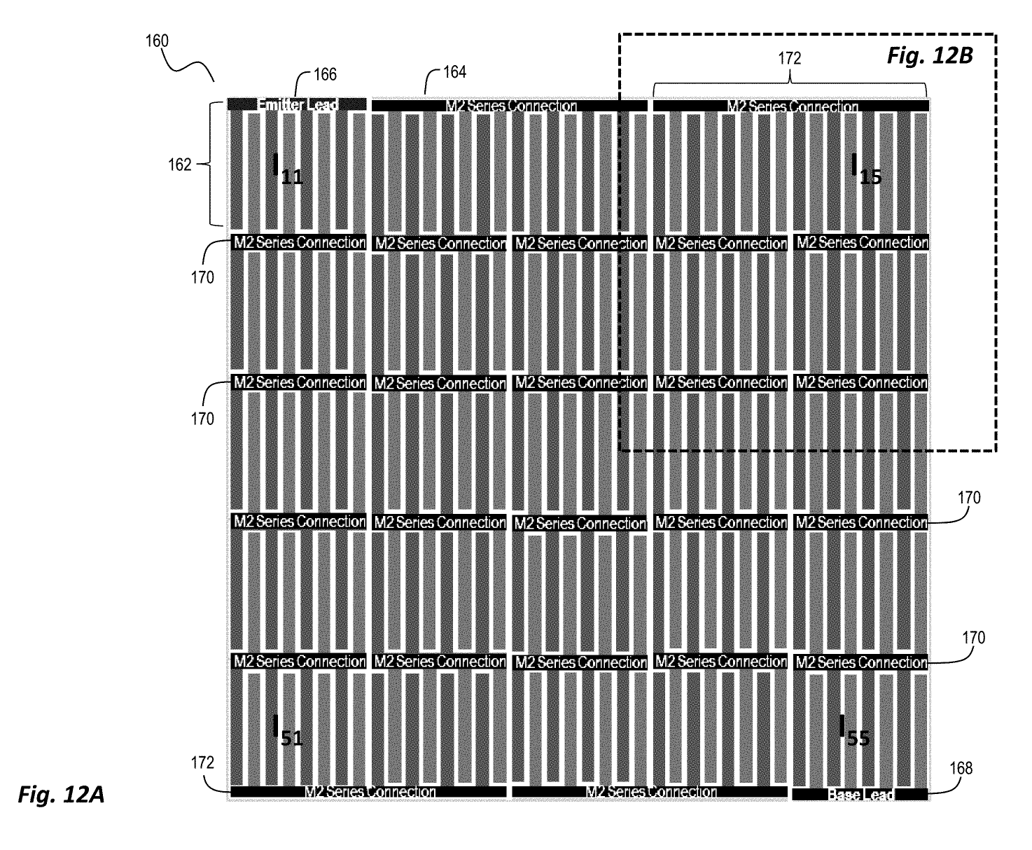

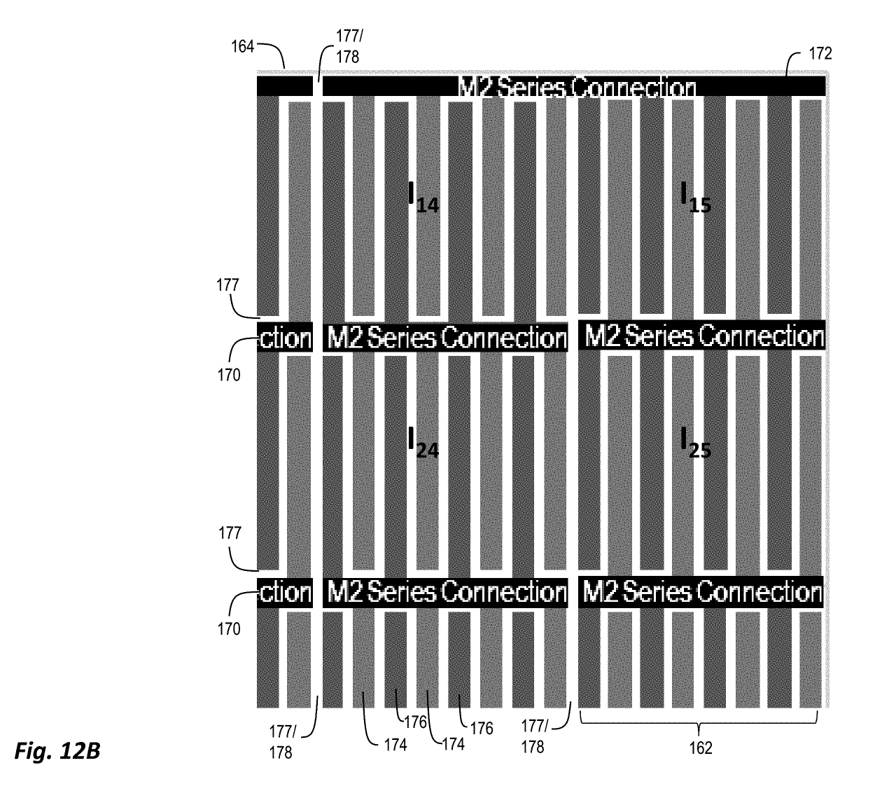

FIG. 12A is a schematic diagram showing a backside plan view of a second and final metallization layer pattern (M2) formed on master cell or icell backside for an icell with an array of 5×5 square-shaped isles (this M2 pattern applies to the solar cell design shown in FIG. 6B on which M1 is formed as shown in FIG. 10B). The M2 pattern shown here provides an arrangement to interconnect the array of 5×5=25 isles in electrical series in the icell. Patterned M2 layer is shown with substantially rectangular fingers (number of M2 fingers<<number of M1 fingers). FIG. 12B is an expanded view of a section of M2 structure in the schematic diagram of FIG. 12A showing the expanded backside plan view of the M2 pattern for a few of the series-connected isles within one quadrant region of FIG. 11A (e.g., including the M2 pattern for the isles designated by I14, I15, I24, I25, indicating the interdigitated base and emitter M2 metal fingers.

FIG. 12A is a schematic diagram showing a backside plan view of a second metallization layer pattern (M2) formed on master cell or icell 160 (similar to the solar cell shown in FIG. 6B comprising a 5×5=25 array of square-shaped isles, on which patterned M1 is as shown in FIG. 10B). FIG. 12B is an expanded view of the M2 metallization layer pattern in a few of the isles within a quadrant of the solar cell of FIG. 12A. In FIGS. 12A and B, and as described previously with reference to FIGS. 6B and 10B, master cell or icell 160 is defined by solar cell peripheral boundary 164 and comprises 5×5=25 uniform square shaped isles I₁ through I₅₅ defined by semiconductor-layer-partitioning trench isolation borders. Patterned M2 metallization layer 162 is formed on the continuous backplane layer 177 attached or laminated to the backside of the solar cell after formation of the patterned M1 layer. The patterned M1 and M2 layers are separated from each other by the backplane layer 177 and interconnected together through the conductive via plugs as described earlier. Patterned M2 metallization layer 162 shown in FIGS. 12A and B comprises substantially rectangular interdigitated emitter and base metal fingers which connect to the underlying patterned M1 layer through a plurality of conductive via plugs (formed by the M2 metallization process through the laser-drilled via holes through the backplane layer). As shown, the patterned M2 interdigitated rectangular fingers (M2 emitter fingers 176 and M2 base fingers 174) are may be patterned such that they are substantially perpendicular or orthogonal to the underlying patterned M1 interdigitated base and emitter fingers, hence, allowing for substantially smaller number of M2 base and emitter fingers as compared to the number of M1 base and emitter fingers. The isles in each column comprising a group of 5 isles in this embodiment (the master cell or icell comprising a 5×5 array of mini-cells or isles) are connected in electrical series by M2 series connections 170 (base M2 metal of each isle connected to the emitter M2 metal of its adjacent isle and emitter M2 metal of each isle connected to the base M2 metal of its adjacent isle in the same column and when transitioning from the end of one column to the beginning of its adjacent column; the base M2 busbar of one corner isle and the emitter M2 busbar of another diagonally opposite isle corner isle serve as the icell base and emitter busbars for icell to icell interconnections either through extensions of M2 in monolithic module embodiments or through tabbing/stringing/and/or soldering of the solar cells together when not using Monolithic Module embodiment). In order to complete the patterned M2 electrical series interconnections of array of 5×5 isles arranged in 5 columns, the isle columns are electrically interconnected using the patterned M2 layer, specifically by lateral M2 layer jumpers or lateral connectors 172 positioned, alternatively, at the top and bottom of the isle columns—thus, the 5×5=25 isles in this icell are all interconnected in electrical series using the patterned M2 layer, with the series connections starting with the top left corner isle in icell 160 of FIG. 12A and continuing down the first column of isles, then connecting the first leftmost column in series to the second column using a bottom M2 jumper or lateral connector 172, with the series connections continuing up the second column of isles, then connecting the second column in series to the third column using a top M2 jumper or lateral connector 172, with the series connections continuing down the third column of isles, then connecting the third column in series to the fourth column using a bottom M2 jumper or lateral connector 172, with the series connections continuing up the fourth column of isles, then connecting the fourth column in series to the fifth column using a top M2 jumper or lateral connector 172, and finally with the series connections continuing down the fifth column of isles. In this icell with an array of 5×5 series-connected isles (all isles interconnection and final icell metallization by the patterned M2 layer), emitter lead or busbar 166 (emitter terminal) for isle I₁₁ (top left corner isle) and base lead or busbar 168 (base terminal) for isle I₅₅ (bottom right corner isle) serve as the main busbars of the icell 160. As shown, the adjacent columns of patterned M2 layer corresponding to the adjacent columns of isles (5 isles per column in this embodiment) are separated by M2 column electrical isolation gap regions 178 (i.e., no M2 metal in these isolation regions), exposing backplane layer 177. The M2 column electrical isolation gap regions 178 are formed concurrently along with formation of all the M2-level patterned base and emitter fingers as well as emitter lead or busbar 166 (emitter terminal) and base lead or busbar 168 (base terminal) as part of monolithically-fabricated patterned M2 metallization layer. M2 series connections 170 between adjacent isles in columns electrically connect the M2 base fingers 174 from isle I₁₁ to the M2 emitter fingers 176 of isle I₂₁. The M2 base fingers 174 of isle I₂₁ are electrically connected to the M2 emitter fingers 176 of isle I₃₁ and so on vertically to isle I₅₁, hence, completing the electrical series connections of the isles in the first column. M2 series connection lateral jumper 172 electrically connects the M2 base fingers 174 of isle I₅₁ (in column 1) to M2 emitter fingers 176 of isle I₅₂ (in column 2).

Each mini-cell or isle may be connected in series to at least one of the other isles in the array, with all the isles in the array of 5×5 isles connected in electrical series, such as that shown in FIG. 12A, which is herein referred to as an all-series connection. However, parallel and hybrid parallel-series mini-cell connection patterns may also be used, depending on the applications and requirements.

As shown in FIG. 12A, each isle (or each sub-group of M1 parallel connected isles) has a corresponding M2 unit cell design of interdigitated rectangular fingers formed on and orthogonal to the underlying interdigitated M1 finger unit cell for that isle—I₁₁ in FIG. 6B corresponding to I₁₁ in FIG. 10B corresponding to I₁₁ in FIG. 12A. In some instances, it may be desired to pattern the M2 fingers parallel to the underlying interdigitated M2 fingers.

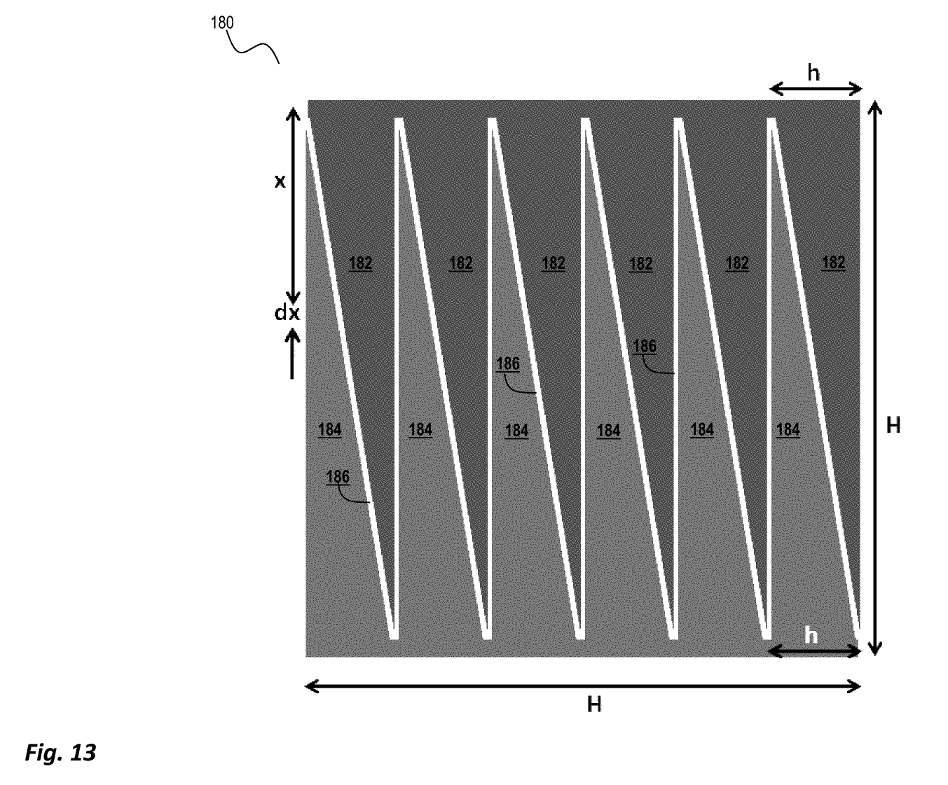

Additionally and alternatively, the metal fingers comprising the M2 unit cell design for icells may be tapered, for instance, triangular or trapezoidal shaped, as shown in FIG. 13. FIG. 13 is a schematic diagram showing a backside plan view of a second metallization layer pattern (M2) unit cell having a plurality of interdigitated tapered/right-angle triangular base and emitter fingers. This example of an M2 unit cell design, located over each series-connected square-shaped isle or sub-group of M1-parallel-connected isles, shows F=6 pairs of base and emitter M2 metal fingers per isle or sub-group of M1-parallel-connected isles.

FIG. 13 is a schematic diagram showing a backside plan view of a second metallization layer pattern (M2) unit cell 180 having, for instance, six pairs of tapered/right-angle triangular fingers—M2 tapered base fingers 184 (all attached to M2 base busbar) and M2 tapered emitter fingers 182 (all attached to M2 emitter busbar) separated by electrical isolation gaps 186 formed during M2 patterning. The word tapered is used herein to describe M2 fingers which are wider at the isle busbar connection and narrower as the fingers extend from the busbar towards the other end of isle. In some instances, a tapered M2 finger design may reduce ohmic losses and reduce M2 layer thickness requirements by about 30% as compared to rectangular M2 fingers—thus allowing for a thinner M2 layer for given allowable metallization ohmic losses. Tapered base and emitter M2 fingers (tapered away from corresponding isle M2 busbar) may be shaped as nearly triangular (right-angle, equilateral, or other desired triangular shape) or nearly trapezoidal. Example dimensional considerations for designing a square shaped M2 unit cell with tapered fingers for a master cell or icell with side dimension of L (corresponding to square-shaped icell area of about L×L) and N×N=S isles (S isles connected in electrical series by the patterned M2 metallization layer), and F pairs of M2 fingers per isle (or per sub-group of M1-parallel-connected isles): L=H×N; H=F×h; Isle Area=H²; F=Number of M2 Base and Emitter Finger Pairs (F=6 in FIG. 13)—wherein: H is the side dimension of the M2 pattern per series-connected isle (or isle subgroup), h is the base width of the triangular M2 fingers, and F is the number of pairs of base and emitter M2 fingers per isle (or isle subgroup). The area of each series-connected isle (or subgroup of isles) is H².

FIG. 13 is a diagram showing a backside view of a second metallization unit cell layer pattern (M2) formed on master cell isle 180 (concurrently and monolithically along with the patterned M2 for all the other isles in the icell), having triangular-tapered interdigitated base fingers 184 and emitter fingers 182 defined and electrically isolated by isolation metallization electrical isolation gap 186 (formed as part of patterned M2 formation). The M2 metallization pattern shown in FIG. 13 may be positioned for example orthogonal or perpendicular to the patterned M1 fingers, on each individual isle (such as each isle connected in series with the other isles in the icell) or on a sub-group of M1-parallel-connected isles. Tapered fingers may further reduce M2 thickness requirements (typically by about 30% with respect to rectangular fingers) and allow for a thinner M2 metallization layer (due to the reduced electrical sheet conductance requirements).

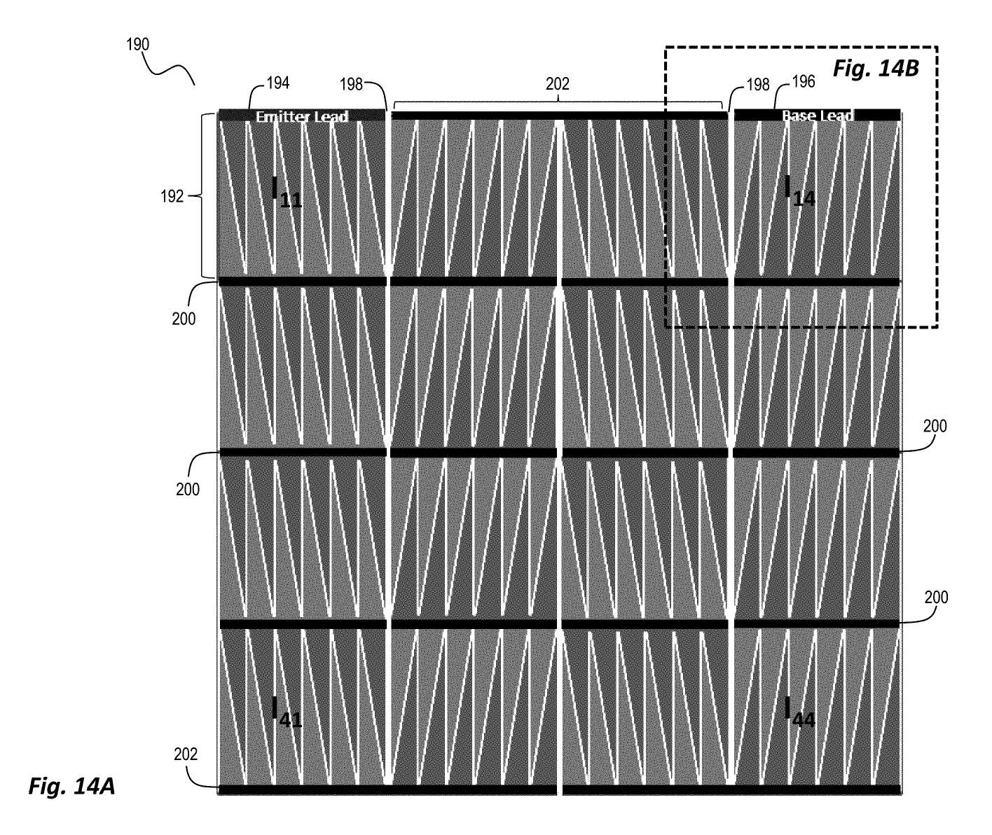

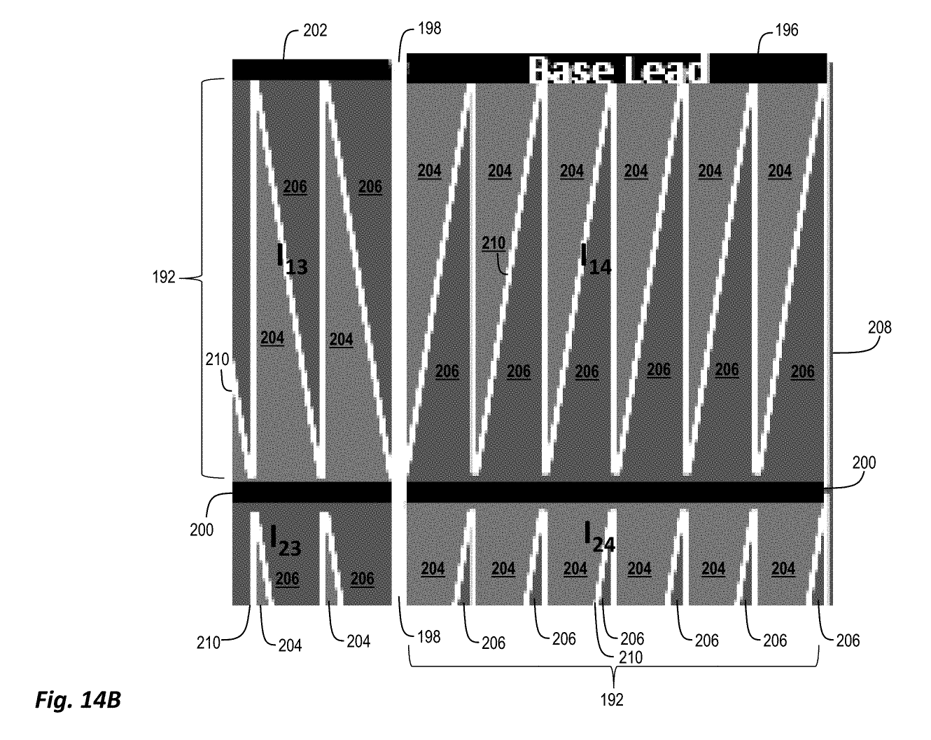

FIG. 14A is a schematic diagram showing a backside plan view of a second metallization layer pattern (M2) formed on the backside of an icell (similar to the cell shown in FIG. 2 on which patterned M1 is formed as shown in FIG. 9A). This shows an icell M2 pattern to make electrical series connections of the 4×4=16 array of square-shaped isles. Patterned M2 fingers use triangular base and emitter metal fingers (number of M2 fingers is less than the number of M1 fingers per isle). In some instances M2 fingers may be orthogonal or perpendicular to the M1 fingers. M2 fingers can be much wider and coarser pitch than M1 fingers.

FIG. 14B is a schematic diagram showing an expanded backside plan view of a portion of the solar cell from FIG. 14A, with a patterned M2 metallization layer, specifically showing full view of isle I14 along with partial views of isles I13, I23, and I24.

FIG. 14A is a diagram showing a backside plan view of an second metallization layer pattern (M2) formed on master cell or icell 190 (similar to the cell shown in FIG. 2 on which patterned M1 is formed as shown in FIG. 9A). FIG. 14B is an expanded schematic plan view of a portion of the solar cell from FIG. 14A, with a patterned M2 metallization layer, specifically showing full view of isle I₁₄ along with partial views of isles I₁₃, I₂₃, and I₂₄. In FIGS. 14A and B, and as described previously with reference to FIGS. 2 and 9A, master cell or icell 190 is defined by a cell peripheral boundary 208 and comprises 4×4=16 uniform (equal area) square shaped isles I₁₁ through I₄₄ defined by partitioning trench isolation borders. Patterned M2 unit cell metallization layer 192 is formed on the backplane layer attached to the solar cell backside comprising the patterned M1 layer, and on the backside of each isle in the icell, as tapered (e.g., triangular shaped as shown) interdigitated emitter and base metal fingers which are electrically interconnected to the underlying M1 layer through a plurality of conductive via plugs. As shown, the patterned M2 interdigitated triangular fingers (M2 emitter fingers 206 and M2 base fingers 204 which are electrically isolated in the patterned M2 layer by isolation gaps 210) are patterned substantially orthogonal or perpendicular to the underlying M1 interdigitated fingers allowing for substantially fewer M2 fingers as compared to the number of M1 fingers for each isle. Each isle in a column (the master cell comprising a 4×4=16 array of mini-cells as shown in FIG. 14A) connected in series by M2 series connections 200 and isle columns are interconnected by M2 lateral jumpers 202 positioned, alternatively, at the top and bottom of the isle columns—thus is the array of 4×4=16 isles are connected in electrical series from emitter lead 194 (emitter terminal or busbar for icell) to base lead 196 (base terminal or busbar for icell). As shown, each isle column is separated by M2 column isolation regions 198, also formed as part of the patterned M2 formation process. M2 series connections 200 electrically connect the M2 base fingers 204 from isle I₁₁ to the M2 emitter fingers 206 of isle I₂₁. The M2 base fingers 204 of isle I₂₁ are electrically connected to the M2 emitter fingers 206 of isle I₃₁ and so on vertically to isle I₄₁. M2 series connection lateral jumper 202 electrically connects the M2 base fingers 204 of isle I₄₁ (in column 1) to M2 emitter fingers 206 of isle I₄₂ (in column 2).

FIG. 15A is a schematic diagram showing a backside plan view of a second metallization layer pattern (M2) formed on master cell with 3×3=9 series-connected isles or sub-groups of M1-parallel-connected isles (similar to the cell shown in FIG. 6A on which patterned M1 is formed as shown in FIG. 10A). Patterned M2 fingers use triangular base and emitter metal fingers (number of M2 fingers is less than the number of M1 fingers per isle). In some instances, M2 fingers may be orthogonal or perpendicular to the M1 fingers. M2 fingers can be much wider and coarser pitch than M1 fingers.

FIG. 15A is a diagram showing a backside plan view of a second metallization layer pattern (M2) formed on master cell or icell 220 (similar to the cell shown in FIG. 6A on which patterned M1 is formed as shown in FIG. 10A). The M2 pattern shown may be formed for 3×3=9 series-connected isles (or sub-groups of M1-parallel-connected isles) on a master cell providing increased voltage and decreased current as compared to a prior art single isle master cell (such as that shown in FIG. 1). In other words, the M2 metallization pattern may scale up the solar cell voltage (Vₘₚ and V_{oc}) by a factor of nine and scale down the solar cell current (Iₘₚ and I_{sc}) by a factor of nine as compared to a prior art single isle master cell. In FIG. 15A, and as described previously with reference to FIGS. 6A and 10A, icell or master cell 220 is defined by a cell peripheral boundary 238 and comprises 3×3=9 uniform (equal area) square shaped isles I₁₁ through I₃₃ defined by partitioning trench isolation borders. Patterned M2 unit cell metallization layer 222 is formed on the continuous electrically insulating backplane attached to the solar cell backside after formation of the patterned M1 layer, on the backside of each isle as tapered (e.g., triangular shaped) interdigitated emitter and base M2 metal fingers which are electrically connected to the underlying patterned M1 layer fingers through a plurality of conductive via plugs formed through the backplane. As shown, the patterned M2 interdigitated triangular fingers (M2 emitter fingers 232 and M2 base fingers 234 which are electrically isolated by isolation gaps formed during the patterned M2 formation process) are patterned substantially orthogonal or perpendicular to the underlying patterned M1 interdigitated fingers allowing for substantially fewer M2 fingers as compared to the number of M1 fingers for each isle. Each isle in a column (the master cell comprising a 3×3=9 array of mini-cells or isles in this embodiment) connected in series by M2 series connections 230 and isle columns are connected by lateral jumpers 228 positioned, alternatively, at the top and bottom of the isle columns—thus each isle is connected in series from emitter lead or busbar 224 (emitter terminal) to base lead or busbar 226 (base terminal). As shown, each isle column is separated by M2 column isolation regions 228 formed during the patterned M2 formation process. M2 series connections 230 electrically connect the M2 base fingers 234 from isle I₁₁ to the M2 emitter fingers 232 of isle I₂₁. The M2 base fingers 234 of isle I₂₁ are electrically connected to the M2 emitter fingers 232 of isle I₃₁. M2 series connection lateral jumper 228 electrically connects the M2 base fingers 234 of isle I₃₁ (in column 1) to M2 emitter fingers 232 of isle I₃₂ (in column 2).

FIG. 15B is a schematic diagram showing a backside plan view of a second metallization layer pattern (M2) formed on master cell with 5×5=25 series-connected isles or sub-groups of M1-parallel-connected isles (similar to the cell shown in FIG. 6B on which patterned M1 is formed as shown in FIG. 10B). Patterned M2 fingers use triangular base and emitter metal fingers (number of M2 fingers is less than the number of M1 fingers per isle). In some instances M2 fingers may be orthogonal or perpendicular to the M1 fingers. M2 fingers can be much wider and coarser pitch than M1 fingers

FIG. 15B is a diagram showing a backside plan view of an second metallization layer pattern (M2) deposited on icell or master cell 240 (similar to the cell shown in FIG. 6B on which M1 is deposited as shown in FIG. 10B). The M2 pattern shown may be formed for 5×5=25 series connected isles on a master cell providing increased solar cell voltage and decreased solar cell current as compared to a prior art isle master cell. In other words, the M2 metallization pattern may scale up the voltage (Vₘₚ and V_{oc}) by a factor of 25 and scale down the current (Iₘₚ and I_{sc}) by a factor of 25 as compared to a prior art single isle master cell. In FIG. 15B, and as described previously with reference to FIGS. 6B and 10B, icell ore master cell 240 is defined by a cell peripheral boundary 258 and comprises 25 uniform square shaped isles I₁₁ through I₅₅ defined by trench isolation borders. Patterned M2 unit cell metallization layer 242 is formed on the electrically insulating continuous backplane attached to the solar cell backside after formation of the patterned M1 layer, on the backside of each isle as tapered (triangular shaped) interdigitated emitter and base metal fingers which are electrically interconnected to the underlying M1 layer through a plurality of conductive via plugs through the backplane layer. As shown, the M2 interdigitated triangular fingers (M2 emitter fingers 252 and M2 base fingers 254 which are electrically isolated by isolation gaps) are patterned substantially orthogonal or perpendicular to the underlying patterned M1 interdigitated fingers allowing for substantially fewer M2 fingers as compared to the number of M1 fingers. Each isle in a column (the master cell comprising a 5×5=25 array of mini-cells in this embodiment) connected in series by M2 series connections 250 and isle columns are connected by lateral jumpers 248 positioned, alternatively, at the top and bottom of the isle columns—thus each isle is connected in series from emitter lead or busbar 244 (emitter terminal) to base lead or busbar 246 (base terminal). As shown, each isle column is separated by M2 column isolation regions 256. M2 series connections 250 electrically connect the M2 base fingers 254 from isle I₁₁ to the M2 emitter fingers 252 of isle I₂₁. The M2 base fingers 254 of isle I₂₁ are electrically connected to the M2 emitter fingers 252 of isle I₁₁ and so on vertically to isle I₅₁. M2 series connection lateral jumper 248 electrically connects the M2 base fingers 254 of isle I₅₁ (in column 1) to M2 emitter fingers 252 of isle I₅₂ (in column 2).

The M1 and M2 unit cell patterns disclosed herein may be designed for square or pseudo-square shaped isles, triangular isles, or various other geometric shaped isles and any combination thereof. In other words, the isle design and interconnection pattern may dictate patterned M1 and M2 designs.

The required electrical conductivity for M2 (or the overall thickness of patterned M2 metal for a given M2 material such as Al or Cu) is less for a master cell having S isles (or S subgroups of isles) connected in electrical series (or hybrid-parallel-series) as compared to a master cell comprising a single isle because of the reduced cell current and increased cell voltage of an icell with a current and voltage scaling factor of S. Generally, the larger the value of S—in other words the number of series connected sub-cells or isles—the smaller the M2 thickness requirement as cell current is reduced and cell voltage increased by a factor of S (number of series connected isles or sub-groups of isles in the icell). For example, copper M2 layer thickness for an IBC solar cell may be decreased from the thickness range of about 20 to over 80 microns for a non-tiled solar cell (for instance, 156 mm×156 mm IBC solar cells) such as that shown in FIG. 1 to less than approximately 20 microns, and in some instances less than 10 microns to as low as about 1 micron to 5 microns, for tiled master cell with series-connected isles (hence, scaling up the voltage and scaling down the current for the icell by the factor S).

The monolithically tiled solar cell or icell structures and fabrication methods disclosed herein provide for substantially reduced metallization sheet conductance and thickness requirements which in turn can reduce metal consumption, process cost, fabrication process equipment cost, and corresponding capital expenditures. Further hazardous waste byproducts from particular cell fabrication processes, such as that produced during metal plating (for example copper plating), may be reduced or eliminated due to reduced and relaxed metallization sheet conductance and thickness requirements (hence, the capability to eliminate dependency on thick metal plating, by replacing it with a much simpler and lower cost metallization process such as evaporation, plasma sputtering, and/or screen printing. A thinner and simpler M2 metallization pattern may reduce solar cell semiconductor layer microcracks and improve the overall solar cell and module manufacturing yields—for example due to substantially reduced tensilary/mechanical stresses of the thinner patterned M2 metallization and elimination of dependency on metal plating processing (such as copper plating) and associated handling, edge sealing, and plating electrical contacting requirements. For applications requiring flexible or bendable solar cells and PV modules, the thinner M2 metallization layer enabled by the icell innovative aspects also enable improved flexibility and bendability of the solar cells and flexible, lightweight PV modules without increasing the risk of solar cell microcracks or breakage. Copper plating process used to form the relatively thick (e.g., about 30 to 80 microns) copper metallization for the prior art interdigitated back-contact (IBC) solar cells may degrade the manufacturing yield due to the intrusive nature of copper plating process (requiring one-sided plating, preventing exposure of the IBC solar cell frontside to the plating chemistry) and risk of mechanical breakage of the cells due to handling as well as clamping/sealing and declamping/unsealing of the solar cells during and after the plating process. For example, copper plating processing of solar cells with pre-existing microcracks may plate copper along the silicon microcracks causing hard shunts or soft shunts, resulting in yield or performance degradation. In one embodiment, the elimination of copper plating processing due to substantially reduced M2 sheet conductance (or M2 metal thickness) requirements eliminates the need for special M1 designs allowing for the patterned M2 layer to be recessed or offset from the edge of the solar cell to accommodate edge-sealed copper plating—in other words the laxed M2 sheet conductance requirements of the isled master cells or icells enable replacing thick copper plating process with a dry non-plating process to form the patterned M2 layer, hence eliminating the need for clamping or sealing of the frontside of the cells to eliminate exposure to plating processing. Therefore, the underlying patterned M1 fingers may be extended nearly end-to-end between the edges or partitioning borders of the isles. Further, eliminating the dependency on copper plating metallization allows for all-dry cell metallization processing (for instance, using screen printing or PVD)—thus substantially reducing cell fabrication complexity.

And in some metallization embodiments when using a metallization material other than copper (e.g., aluminum), projected long-term field reliability of the solar cells and PV modules may be improved since in solar cells using copper metallization, copper seeping to sensitive solar cell surface areas (even though not causing soft or hard solar cell shunts) may cause long-term reliability issues due to copper diffusion into the semiconductor substrate and degradation of minority carrier lifetime (and efficiency).

Thinner solar cell metallization enabled by the icell reduces solar cell bow and mechanical stress, for example on backplane-laminated solar cells disclosed herein, as compared to known solar cells using relatively thick (typically in the range of about 30 to 80 microns for IBC solar cells) plated metal, often plated copper. The reduction of M2 metal thickness in a dual level metallization structure (in one example from at least 30 to 80 microns to less than approximately 5 microns) results in enhanced solar cell and PV module flexibility/pliability without crack generation and without PV module performance degradation as a result of PV module flexing or bending. Additionally, reduction of M2 metal thickness and mass substantially reduces or eliminates mechanical stresses, such as patterned metallization stresses on the sensitive solar cell semiconductor absorber—thus, minimizing microcrack generation and yield degradation during subsequent solar cell and module processing, such as during test and sort, module lamination (which may use lamination pressure and heat), and field operation of the installed PV modules. For example, patterned M2 may be made of a relatively inexpensive, high-conductivity metal such as copper (bulk resistivity 1.68 μΩ·cm) or aluminum (bulk resistivity 2.82 μΩ·cm). For example, copper has a linear CTE of about 17 ppm/° C. and crystalline silicon has a linear CTE of approximately 2.7 ppm/°. Thus, there is an approximate CTE difference of 14 ppm/° C. between copper and crystalline silicon, and a 140° C. module lamination process would cause a dimensional mismatch of 0.25 mm or 250 μm for a 156 mm×156 mm solar cell (in other words thick plated copper expands about 250 microns more from side to side as compared to silicon) resulting in very large tensile stress on silicon during the module lamination process. Monolithic mini-cells or isles having a patterned thin M2 metallization pattern in accordance with the disclosed subject matter (for example with a layer thickness less than approximately 10 microns, and in some instances less than 5 microns) substantially reduces or eliminates this mode of crack generation and propagation and resulting yield degradation.

If desired, in order to eliminate the need for plating processing, such a copper plating process (as well as the cost, added process complexity, thermal/mechanical stresses, and potential fabrication yield losses associated with metal plating process), the number of series-connected sub-cells or isles (S) may be chosen such that the required low-resistivity or high-conductivity metal (for example inexpensive high-conductivity metals such as copper and/or aluminum, although another high-conductivity metal such as silver may also be used) thickness is sufficiently small in order to use a relatively low-cost metal deposition process, such as plasma sputtering or evaporation (Physical-Vapor Deposition or PVD processes), particularly in instances where the M2 thickness (such as the copper or aluminum thickness) is reduced to less than about 10 microns and in some instances less than approximately 5 microns. Alternatively, another inexpensive metallization process such as screen printing may be used instead of copper plating.

Further, in one embodiment, M2 may be patterned to be substantially orthogonal or perpendicular to M1 and the number of M2 fingers (such as tapered fingers) may be much less than the number of M1 fingers, for example by a factor in the range of about 5 to 50. And in some instances, M2 fingers designed in tapered finger shapes such as triangular or trapezoidal shapes, as compared to rectangular shaped fingers, will further reduce the M2 metal thickness requirement (typically by about 30%).

Partitioning the main/master cell into an array of isles or sub-cells (such as an array of N×N square or pseudo-square shaped or K triangular-shaped or a combination thereof) and interconnecting those isles in electrical series or a hybrid combination of electrical parallel and electrical series reduces the overall master cell current for each isle or mini-cell—for example by a factor of N×N=N² if all the square-shaped isles are connected in electrical series, or by a factor of K if all the triangular-shaped isles are connected in series. And while the main/master cell or icell has a maximum-power (mp) current of Iₘₚ, and a maximum-power voltage of Vₘₚ, each series-connected isle (or sub-groups of isles connected in parallel and then in series) will have a maximum-power current of Iₘₚ/N² (assuming N² isles connected in series) and a maximum-power voltage of Vₘₚ (no change in voltage for the isle). Designing the first and second metallization layer patterns, M1 and M2 respectively, such that the isles on a shared continuous or continuous backplane are connected in electrical series results in a main/master cell or icell with a maximum-power current of Iₘₚ/N² and a maximum power voltage of N²×Vₘₚ or a cell (icell) maximum power of Pₘₚ=Iₘₚ×Vₘₚ (the same maximum power as a master cell without mini-cell partitioning).

Thus, a monolithically isled master cell or icell architecture reduces ohmic losses due to reduced solar cell current and allows for thinner solar cell metallization structure generally and a much thinner M2 layer if applicable or desired. Further, reduced current and increased voltage of the master cell or icell allows for relatively inexpensive, high-efficiency, maximum-power-point-tracking (MPPT) power optimizer electronics to be directly embedded into the PV module and/or integrated on the solar cell backplane.

Assume a main/master cell or icell with S square-shaped or pseudo-square shaped pattern of isles (where S is an integer and assume S=N×N) or P triangular isles (where P is an integer, for example 2 or 4) with each adjacent set of P trench-isolated triangular isles forming a square-shaped sub-group of isles. Each adjacent set of P triangular isles forming a square-shaped sub-group may be connected in electrical parallel and the set of S sub-groups are connected in electrical series. The resulting main cell will have a maximum-power current of Iₘₚ/S and a maximum power voltage of S×Vₘₚ. In practice, the reduced current and increased voltage of the isles may also allow for a relatively inexpensive, high-efficiency, maximum-power-point-tracking (MPPT) power optimizer electronics to be directly embedded into the PV module and/or integrated on the solar cell backplane. Moreover, the innovative aspects of an icell also enable distributed shade management based on implementation of inexpensive bypass diodes (e.g. pn junction diodes or Schottky diodes) into the module, for instance, one bypass diode embedded with each solar cell prior to the final PV module lamination. In a metallization embodiment, the M1 metallization layer may be a busbarless, fine-pitch (base-to-base pitch in the range of approximately about 200 μm to 2 mm, and more specifically in the range of about 500 μm to 1,500 μm) interdigitated Al and/or Al/Si metal finger pattern (formed by screen printing or PVD and post-PVD patterning) contained within each isle. For each isle, the M1 fingers may be slightly recessed from the partitioning trench isolation edges (for example recessed or offset from the isle trench isolation edges by approximately 50 μm to 100's μm). In other words, the M1 fingers for each isle in the master cell are electrically isolated and physically separated from each other (the M1 pattern corresponding to a particular isle may be referred to herein as an M1 unit cell).

The electrical interconnection configuration of the isles (all series, hybrid parallel-series, or all parallel) may be defined by the M2 pattern design wherein M1 serves as an on-cell contact metallization for all of the master cell isles and M2 provides high-conductivity metallization and electrical interconnection of the isles within the icell or master cell.

An M2 design (for example an M2 pattern using rectangular or tapered interdigitated M2 base and emitter fingers) may provide all-series, hybrid parallel-series, or all-parallel electrical interconnections of the isles in the icell. In some instances, as noted above, M2 designs which provide all-series or hybrid parallel-series electrical connections of the isles may be used to scale up the main/master cell voltage and scale down the main/master cell current (for instance, by a factor of S, S being the number of series connected isles or sub-groups of isles). Increasing cell voltage while decreasing cell current relaxes/decreases metallization conductivity requirements and allows for thinner metallization and lower metal sheet conductance, thus reducing or mitigating process costs, process complexity, fab equipment and facilities costs (e.g., because of elimination of the need for copper plating for cell metallization), cracks, reliability concerns, and overall yield loss associated with relatively thick metallization processing such as relatively thick metallization formed using copper plating.

Moreover, the enhanced-voltage/reduced-current main/master solar cell or icell provides for the integration of a relatively inexpensive, high-performance, high-efficiency maximum-power-point-tracking (MPPT) power optimizer electronics embedded within each module and associated with each icell and/or each isle, —thus providing enhanced power and energy harvest capability across a master cell having shaded, partially shaded, and unshaded isles. Similarly, each icell or even each isle within each icell may have its own inexpensive bypass diode (pn junction diode or Schottky barrier diode) in order to provide distributed shade management capability for enhanced solar cell protection and power harvest under shading and partial shading conditions. An all-parallel electrical connection of isles provided by an all-parallel M2 pattern, as compared to all-series or hybrid parallel-series connection, also provides some of the numerous advantages of a monolithically isled solar cell as described above, particularly the increased flexibility and bendability of the resulting icells and PV modules.

For example, in the case of using PVD aluminum for M2 (such as a sub-5 μm thick M2 layer providing all-series or hybrid parallel-series connections in an icell), a metal stack may be PVD Al (main metal) capped with a relatively thin layer of Ni or NiV (e.g., formed by plasma sputtering), optionally followed by Sn (e.g., formed by plasma sputtering) to provide M2 solderability. The aluminum layer may be deposited using an electron-beam or thermal evaporation process.

Assume there are S square-shaped isles connected in electrical series. Each “isle” to be connected in electrical series may comprise a subgroup of smaller isles, such as triangular isles, connected in electrical parallel. For an N×N array of square-shaped isles connected in series: S=N×N=N².

Further, assume the M2 finger pattern is substantially orthogonal or perpendicular to M1 pattern—this allows the number of M2 fingers to be substantially smaller than the number of M1 fingers (by about a factor of 5× to about 50×). For instance, a 156 mm×156 mm cell (without tiling or isles) with a base-to-base M1 metal pitch of 750 microns may have about 416 M1 fingers and approximately 8 to 40 M2 orthogonal fingers.

Similarly, a large factor reduction in the M1 to M2 finger ratio may apply to the M2 metal finger count for each isle sub-cell (the M2 pattern corresponding to a particular isle may be referred to herein as an M2 unit cell). For instance, for an S=3×3 isle master cell design, each isle may have about 140 M1 fingers (running over a distance of about 52 mm in each isle) and an M2 finger count of 12 (for example with the M2 base and emitter metal fingers having combined width or pitch of about 6.5 mm, much larger than the M1 pitch of about 750 microns). And, in some instances the M2 layer may provide a relatively large cell coverage ratio (close to 100%)—in one instance the deposited M2 layer (for example deposited by PVD) is patterned using pulsed nanoseconds laser ablation creating a finger-to-finger isolation gap less than approximately 100 μm thick.

Guidelines for M2 Thickness in a Dual Level Metallization Structure for a Given Metal—Aluminum or Copper.

Assume, for master cell area=L×L=L², Iₘₚ is the master cell maximum-power-point (MPP) current (base or emitter current) extracted from the entire M1 layer under the STC conditions. At the maximum-power-point operation of the solar cell, the entire current extracted from cell contact metallization level M1 and flowing through conductive M2-M1 via plugs is Iₘₚ for base and Iₘₚ for emitter (2Iₘₚ without current direction consideration).

Also, assume Pₘₚ and Vₘₚ are the maximum-power-point (MPP) power and voltage of the cell, respectively. Then: Pₘₚ=Vₘₚ×Iₘₚ; the total electrical cell current per unit area extracted from M1 (including both base and emitter currents, irrespective of flow direction)=2Iₘₚ/L², as half of the cell area produces Iₘₚ base current and half of the cell area produces Iₘₚ emitter current; and MPP power of each isle (or sub-cell) connected in series=Pₘₚ/S, where S is the number of series-connected isles or sub-groups of isles (for example: S=N×N=N²).

Now, in a triangular M2 finger embodiment, assume I_{f} is the current collected by each individual M2 triangular finger from the underlying M1 fingers for the triangular area covered by the M2 finger, then: I_{f}=Iₘₚ/(F·S) where F is the number of pairs of M2 triangular fingers per isle; in a base or emitter triangular finger on a series-connected isle, the finger current as a function of x may be expressed as I(x)=Integral from 0 to x of {[2Iₘₚ/L²]·[(x/H)·h]}·dx where H=L/N (for S=N×N) and h=H/F=L/(N·F); thus, I(x)=Integral from 0 to x of {[2Iₘₚ/L²]·[(x/F]}·dx=Integral from 0 to x of {[2Iₘₚ/(FL²)]·x·dx}; thus, I(x)=[2Iₘₚ/(FL²)]·(½)x²=[Iₘₚ/(FL²)]·x²; and the total current per finger may be expressed as I_{f}=[Iₘₚ/(FL²)]·H²=[Iₘₚ/(FL²)]·(L/N)²=[Iₘₚ/(FN²)=Iₘₚ/(F·S).

Further, assuming M2 resistivity ρ, thickness t, and M2 sheet resistance Rₛ=ρ/t, the power loss per M2 Finger per isle P_{lf} (in other words power loss per M2 finger per M2 unit cell) may be expressed as: P_{lf}=Integral from 0 to H of {{(ρ·dx)/[(t·x·h)/H]}·[Iₘₚ/(FL²)]²·x⁴}; thus, P_{lf}=[(ρ·H)/(t·h)]·[Iₘₚ/(FL²)]²·(¼)·H⁴=[(ρ·H)/(t·h)]·[Iₘₚ/(FL²)]²·(¼)·(L/N)⁴; and as h=H/F and H/h=F, then P_{lf}=(ρ·F/t)·[Iₘₚ/(FL²)]²·(¼)·(L/N)⁴; thus, power loss per finger P_{lf}=(ρ/t)·F·Iₘₚ²·(1/F²L⁴)·(¼)·L⁴·(1/N⁴)=(ρ/t)·Iₘₚ²·[1/(4·F·N⁴)]; as there are 2F fingers per isle, the total M2 power loss per isle (P_{M2isle}) at the MPP condition may be expressed as P_{M2isle}=(ρ/t)·Iₘₚ²·[1/(4·F·N⁴)]·2·F=(ρ/t)·Iₘₚ²·[1/(2N⁴)]; as may be a total of N×N=N² isles, total M2 power loss at MPP may be expressed as P_{M2loss}=(ρ/t)·Iₘₚ²·[1/(2N⁴)]·N²=(ρ/t)·Iₘₚ²·[1/(2N²)]; thus, P_{M2loss}=(ρ/t)·Iₘₚ²·[1/(2N²)].

Now, as an example assuming approximately 22.5% mean solar cell efficiency Pₘₚ=5.50 Wp, and assume Vₘₚ=0.59 V, Iₘₚ=9.3. M2 metal layer thickness requirements for aluminum and copper—assuming a total maximum M2 allowable relative ohmic loss factor k of 0.01, 0.005, or 0.0025 (as a fraction of Pₘₚ for the cell), Power Loss Factor=k=(P_{M2loss}/Pₘₚ), K (in allowable maximum M2 loss)=(ρ/t)·(Iₘₚ²/Pₘₚ) [1/(2·N²)]—the required M2 metal thickness based on an allowable k at t may be expressed as t=(ρ/k)·(Iₘₚ²/Pₘₚ) [1/(2·N²)] where k is the maximum allowable loss as a fraction of Pₘₚ.

Table 1 below tabulates the calculated required M2 thickness for copper or aluminum M2 metallization for various allowable loss factors (k) and various N value master cell embodiments having series-connected N×N array of isles (S=N×N) with the N value between 1 (for example cell with a single isle—i.e., no partitioning trenches) up to 6 (for example for S=36 series connected isles) based on the expressions defined above and assuming the following: ρ=1.68 μΩ·cm for copper metallization, ρ=2.82 μΩ·cm for aluminum metallization, Pₘₚ=5.5 W, Iₘₚ=9.3 A, and allowable loss factors k of 0.01, 0.005, or 0.0025.

TABLE 1

| | t (um) for | t (um) for | t (um) for | t (um) for | t (um) for | t (um) for |
|---|---|---|---|---|---|---|
| N | k = 0.01, Cu | k = 0.005, Cu | k = 0.0025, Cu | k = 0.01, Al | k = 0.005, Al | k = 0.0025, Al |
| 1 | 13.21 | 26.42 | 52.84 | 22.17 | 44.35 | 88.69 |
| 2 | 3.30 | 6.60 | 13.21 | 5.54 | 11.09 | 22.17 |
| 3 | 1.47 | 2.94 | 5.87 | 2.46 | 4.93 | 9.85 |
| 4 | 0.83 | 1.65 | 3.30 | 1.39 | 2.77 | 5.54 |
| 5 | 0.53 | 1.06 | 2.11 | 0.89 | 1.77 | 3.55 |
| 6 | 0.37 | 0.73 | 1.47 | 0.62 | 1.23 | 2.46 |

Thus, patterned M2 metal layer thickness (for instance, when formed using PVD such as evaporation or sputtering) may be limited to less than approximately 5 μm, and in some instances M2 PVD metal layer thickness limited to less than approximately 3 μm, providing numerous economical (for example, reduced PVD material cost and processing simplification) as well as fabrication advantages.

In some instances, electron-beam evaporation or thermal evaporation or DC Magnetron Plasma Sputtering (a Physical-Vapor Deposition or PVD process) may be used to deposit a high-quality M2 metal layer with near-bulk material resistivity (for example with metal resistivity close to the bulk resistivity values of 1.68 μΩ·cm for copper or 2.82 μΩ·cm for aluminum) using high-throughput, in-line, evaporation and/or plasma sputtering tools commercially available for high-productivity solar PV applications. For example, an in-line evaporation and/or DC magnetron plasma sputtering (PVD) tool for aluminum M2 sputter deposition may have the following stations: (i) Argon plasma sputter etch to clean laser-drilled through-backplane vias, for low M2-M1 via plug contact resistance and for improved metal adhesion to the backplane; (ii) electron-beam evaporation or thermal evaporation or DC magnetron sputtering of pure aluminum, M2 layer thickness may be based on loss factor design rules, for instance, 3 to 5 microns of aluminum; (iii) DC magnetron sputtering of a thin, for example a layer thickness in the range of approximately 0.05 μm to 0.25 μm, of NiV or Ni capping layer; and (iv) DC magnetron sputtering of Sn, a Sn alloy, or alternative suitable solder material, with a layer thickness of approximately 0.5 μm to several μm.

Alternatively, an in-line DC magnetron plasma sputtering (PVD) tool for copper M2 sputter deposition may have the following stations: (i) Argon plasma sputter etch to clean M1 contact areas exposed through laser-drilled backplane via holes, for low M2-M1 via plug contact resistance and improved M2 adhesion to the backplane; (ii) DC magnetron sputtering of a thin, for example a layer thickness in the range approximately 0.05 μm to 0.25 μm, of NiV or Ni as a diffusion barrier and adhesion layer; (iii) DC magnetron sputtering of pure copper, copper thickness may be based on loss factor design rules; and (iv) DC magnetron sputtering of Sn, a Sn alloy, or alternative suitable solder material, with a layer thickness of approximately 0.5 μm to several μm.

In some embodiments, N may be chosen in order to meet particular design criteria for a given desired loss factor k and corresponding maximum allowable M2 thickness value. And by keeping the M2 copper or aluminum thickness less than about 5 μm, M2 may be easily patterned using pulsed laser ablation.

And while DC magnetron plasma sputtering of aluminum or copper, as well as any applicable barrier and/or capping layers, followed by laser ablation patterning may be used to form the M2 metal layer, alternative M2 metal layer formation methods include, but are not limited to: PVD aluminum or copper (as well as any applicable barrier and/or capping layers) followed by wet patterning (screen print mask, wet etch metal/strip mask); screen print high-conductivity, low-temperature-cure metal paste such as high-conductivity silver paste, copper paste, aluminum paste, etc.

Using aluminum as compared to copper for M2 may allow the cell fabrication line and the resulting cell to be free of copper and in some instances cell fabrication using all dry processing. Thus, improving risk mitigation in cell fabrication (due to inherent complications involved in copper processing such as with copper plating) and for the cell modules in the field as the long-term reliability concerns of copper contamination and lifetime degradation are eliminated. Moreover, the M2-M1 contact (the metallization in the via holes, or via plugs) may be an aluminum-to-aluminum contact thus eliminating the need for a diffusion barrier layer between M2 and M1. Further, an M2 Sn/NiV/Al stack or another suitable metal stack comprising aluminum as the main M2 conductor metal may allow for pulsed laser ablation patterning, thus providing all-dry cell backend metallization process and increasing cell yield.

In some embodiments, a monolithic isled master cell or icell may integrate monolithically-integrated bypass switch (MIBS) with each icell and/or with each isle in the icell to provide high-performance lightweight, thin-format, flexible, high-efficiency (e.g., greater than 20%) solar modules with distributed shade management—for example a pn junction diode, such as a rim pn junction diode, formed around the periphery of each isle. Alternatively, the MIBS device may be a metal-contact Schottky diode, such as a rim Schottky diode formed around the periphery of each isle made of, for example, an aluminum or aluminum-silicon alloy Schottky contact on n-type silicon. The pn junction MIBS diode pattern may be one of many possible pattern designs. For instance, in one MIBS diode pattern the rim diode p+ emitter region is a continuous closed-loop band sandwiched between (or surrounded by) the n-type base regions.

While standard rigid glass modules (for instance, using copper-plated cells and discrete shade management components) may be used to reduce module manufacturing costs for isled solar cells (icells), further weight and cost reductions may be achieved by incorporating MIBS, eliminating copper plating and the discrete bypass diode components. MIBS integration benefits for a monolithic isled master cell include materials cost reductions combined with substantial manufacturing risk mitigation and higher manufacturing yield due to process simplification (no plating, much reduced cracks) and enhanced overall projected reliability (for example by eliminating the discrete components from cells). Thus, a monolithic isled MIBS integrated master cell module may reduce the weight, reduce the volume/size (and thickness), and increase power density (W/kg) of the module by significant factors—further reducing installed system Balance of System (BOS) costs.

A monolithic isled MIBS integrated master cell module may provide some or all of the following advantages: distributed MIBS shade management without external components; a relatively small average module weight per unit area, for instance, on the order of approximately 1.2 kg/m² (˜0.25 lb/ft²), which may be at least 10× lighter than the standard rigid c-Si modules; module power density of approximately 155 W/kg (˜70 W/lb), which is at least 10× higher than the standard rigid c-Si modules; high-efficiency (greater than 20%) lightweight flexible modules for various applications; module shipping weight and volume (per MW shipped) reductions by approximately 10× and 40×, respectively; reduced overall BOS cost, enabling a lower installed PV system cost compared to installed PV system costs using standard rigid c-Si modules; and reduced BOS and miscellaneous costs relating to shipping and handling, labor, mounting hardware, and wiring costs.

MIBS formation may be integrated and performed concurrent with partitioning trench isolation formation processing. If a rim diode design is utilized, the monolithically integrated bypass switch (MIBS) rim may also provide the additional benefit of mitigating or eliminating the generation and/or propagation of micro-cracks in the solar cell during and/or after fabrication of the solar cells.

A full-periphery through-silicon partitioning trench separating and isolating the rim bypass diode from the isles may have, for example, an isolation width in the range of a few microns up to about 100 microns depending on the laser beam diameter (or capability of the trenching process if using a process other than laser trenching) and semiconductor layer thickness. A typical trench isolation width formed by pulsed nanoseconds (ns) laser scribing may be around 20 to 50 microns although the trench isolation width may be smaller. While pulsed laser ablation or scribing is an effective and proven method to form the trench isolation regions, it should be noted that other non-mechanical and mechanical scribing techniques may also be used instead of laser scribing to form the trench isolation regions for all trench formation processing. Alternative non-laser methods include plasma scribing, ultrasonic or acoustic drilling/scribing, water jet drilling/scribing, or other mechanical scribing methods.

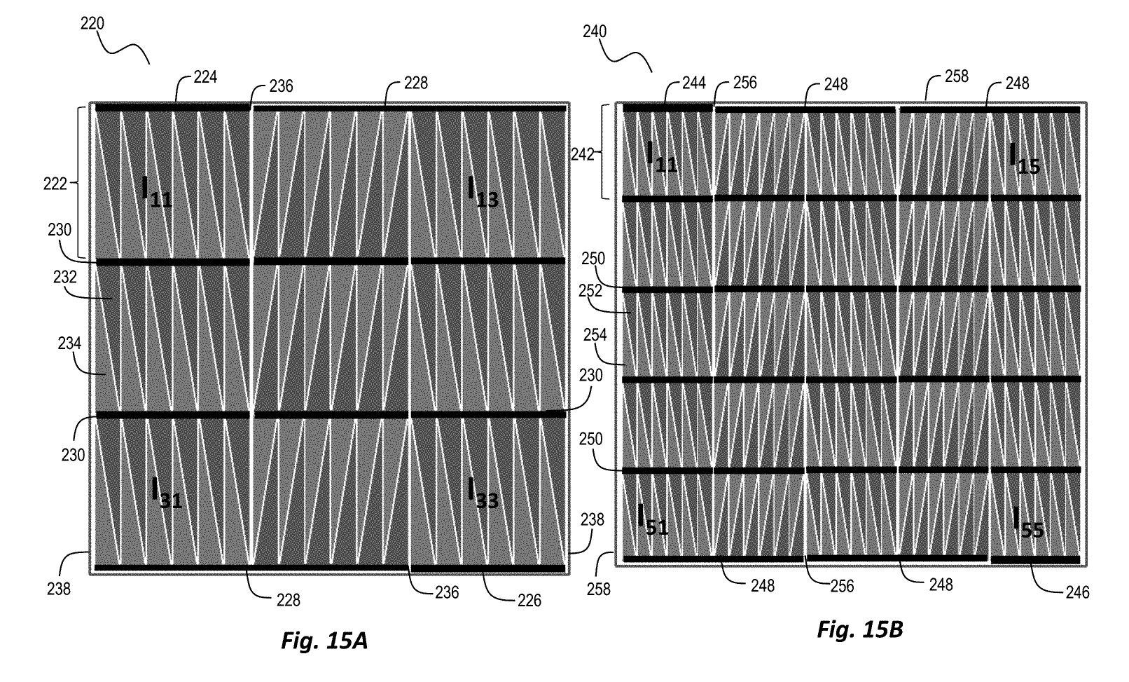

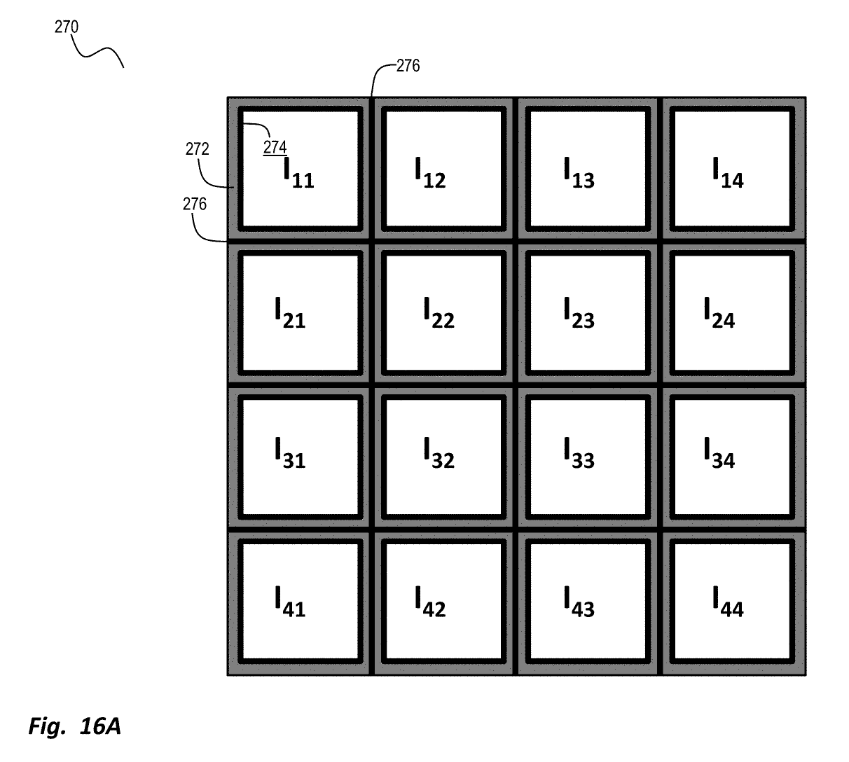

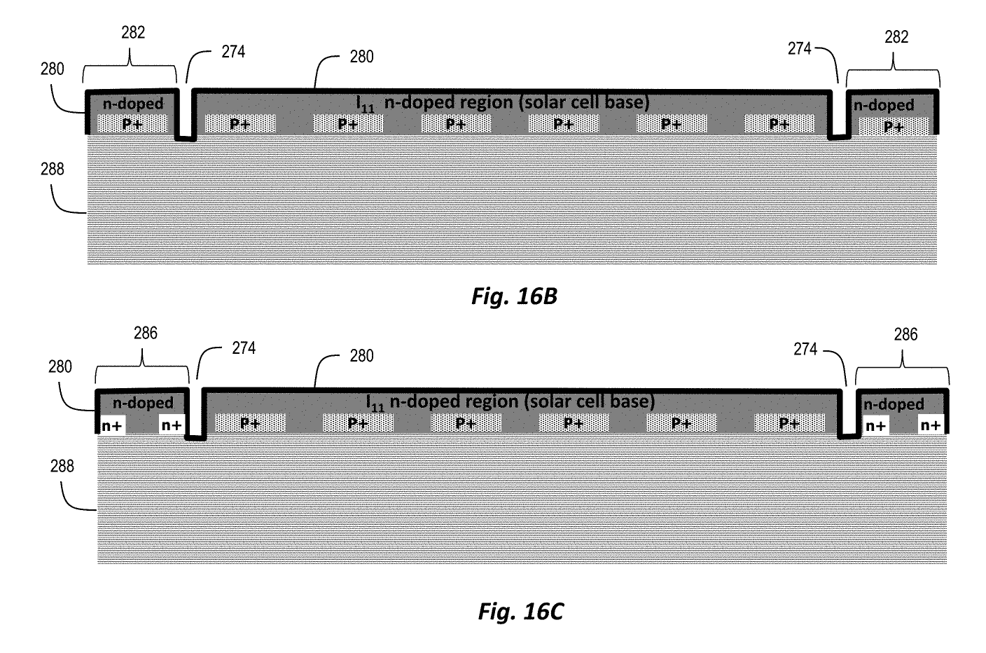

FIG. 16A is a schematic diagram showing a sunnyside view of isled master cell with a plurality of isles (example shows 4×4 isles) and monolithically-integrated bypass switch or MIBS devices integrated with the isles. This is an embodiment of MIBS using full-periphery bypass diodes isolated from the solar cells using full-periphery isolation trenches for an icell sharing a continuous backplane.

FIG. 16A is a schematic diagram showing a sunnyside plan view of isled MIBS (Monolithically Integrated Bypass Switch) master cell 270 (icell embodiment shown with 4×4 array of square-shaped isles) with a plurality of full-periphery closed loop MIBS bypass diodes, for example MIBS bypass diode 272 electrically isolated from isle I₁₁ by isle partitioning isolation trench 274. Each isle (I₁₁ through I₄₄) isolated by full-periphery partitioning trenches (either formed by laser ablation/scribing or scribed by another suitable technique as described above), such as cell isolation trenches 276, to form an icell with a 4×4 array of isles (a solar cell comprising a plurality of mini-cells or isles) sharing a shared continuous backplane and formed from a common originally continuous and subsequently partitioned solar cell semiconductor substrate.

FIG. 16A shows the sunnyside view of the MIBS-enabled solar cell (icell) with mini-cells or isles and full-periphery closed-loop rim diodes (either pn junction diodes or Schottky barrier diodes). Each mini-cell isle I₁₁ through I₄₄ has a corresponding full periphery isolation trench (276) and full-periphery MIBS rim diode (such as MIBS bypass diode 272 and periphery isolation trench 274 for cell I₁₁)—thus each mini cell or isle has a corresponding MIBS rim diode, or in other words there is one MIBS rim diode per isle or mini cell. The isles or mini-cells may be electrically connected in series through the cell metallization pattern design although other connections such as parallel or a hybrid combination of series and parallel are also possible.

As a representative example, FIG. 16A shows a 4×4 array of equally sized and shaped mini-cells and each mini-cell having a corresponding full-periphery closed-loop rim diode. In general, this architecture may use N×N array of mini-cells and corresponding full-periphery closed-loop rim diodes with N being an integer equal to or greater than two to form mini-cell array. And while FIG. 16 shows a symmetrical N×N mini-cell array for a full-square-shaped solar cell, the mini-cell or isle array design may have an asymmetrical array of N×M mini-cells. The mini-cells or isles may be square-shaped (when N=M for a square-shaped master cell) or rectangular (when N is not equal to M and/or the master cell is rectangular instead of square shaped), or various other geometrical shapes.

Further, the mini-cells of a master cell (again, a master cell refers to an array of mini-cells or isles sharing a common continuous backplane and all originating from the same original solar cell semiconductor substrate subsequently partitioned into the plurality of mini-cell or isle regions by partitioning trenches) may optionally have substantially equal areas although this is not required. The semiconductor layers for the array of isles or mini-cells are electrically isolated from each other using partitioning trench isolation formed by a suitable scribing technique such as laser scribing or plasma scribing. Moreover, each mini-cell or isle semiconductor substrate is partitioned and isolated from its corresponding full-periphery closed-loop MIBS diode semiconductor substrate using trench isolation. All the trench isolation regions on the master cell may be formed during the same manufacturing process step, for example using a single laser-scribe process step during the cell fabrication process flow.

FIGS. 16B and 16C are cross-sectional diagrams detailing MIBS rim or full-periphery diode solar cell embodiments of the back-contact/back-junction solar cell for one isle (or unit cell such as I₁₁ in FIG. 16A) on a shared continuous backplane 288 after completion of manufacturing processes to form a MIBS-enabled back-contact/back-junction isled master cell such as that shown in FIG. 16A, including frontside passivation and ARC coating on the textured surface of the solar cell (and MIBS device) shown as passivation/ARC coating layer 280 in the solar cell in the MIBS device. The solar cell isle and MIBS structural details such as the patterned M1 and M2 metallization layers are not shown here. FIG. 16B shows a MIBS implementation using a pn junction peripheral rim diode bypass switch. Trench-isolated MIBS rim pn junction diode region 282 (isolated from isle I₁₁ by corresponding isolation trench 274) comprises an n-doped (e.g., phosphorus doped) region and a p+ doped (e.g., heavily boron doped) region and is used as a pn junction diode bypass switch. MIBS rim pn junction diode region 282 may be a full peripheral rim diode, for example with a width in the range of about 200 to 600 microns (smaller or larger dimensions are also possible as described earlier). The MIBS rim diode and solar cell relative dimensions are not shown to scale. In one fabrication embodiment, FIG. 16B shows a backplane-laminated (or backplane-attached) MIBS-enabled solar cell after completion of manufacturing processes for a MIBS-enabled back-contact/back-junction (IBC) solar cell comprising completion of back-contact/back-junction cell processing through patterned first-level metallization or M1 (for example made of screen printed or PVD aluminum or aluminum-silicon alloy or another suitable metal comprising nickel, etc.), backplane lamination, epitaxial silicon lift-off release and separation from a crystalline silicon reusable template (if using an epitaxial silicon lift-off process to form the substrate—this process not applicable when using a starting crystalline silicon wafer), formation of trench isolation regions (e.g., by pulsed laser scribing or cutting) to define the MIBS rim diode border, optional silicon etch, texture and post-texture clean, passivation & ARC deposition (e.g., by PECVD or a combination of ALD and PECVD), and fabrication of the final patterned second-level metal or M2 (along with the conductive via plugs) on the backplane.

As can be seen in FIG. 16B, the process used to form the p+ emitter regions (field emitter regions and/or heavily doped emitter contact regions) of the solar cell may also be used to form p+ junction doping for the MIBS pn junction formation. The patterned M1 metal (not shown), for example made of aluminum or an aluminum alloy such as aluminum with some silicon addition, not only provides the contact metallization or the first-level metallization for the solar cell but also creates metallization contacts (to both the p+ region and the n-type substrate region through n+ doped contact windows) for the MIBS pn junction diode. The n-doped silicon region of the MIBS pn junction diode is formed from the same n-type silicon substrate which also serves as the base region of the solar cell (e.g., from the n-type silicon wafer when using starting n-type crystalline silicon wafers without epitaxy, or from in-situ-doped n-type crystalline silicon layer formed by epitaxial deposition when using epitaxial silicon lift-off processing to form the solar cell and MIBS substrate)—the substrate bulk region doping may also be referred to as the background doping of the substrate. The patterned M1 and M2 metallization structures complete the required monolithic solar cell and MIBS pn junction diode electrical interconnections and also ensure the MIBS diode terminals are properly interconnected to the respective solar cell base and emitter terminals to provide cell-level integrated shade management and continual solar cell protection against shading. As can be seen in FIG. 16B, the sidewall edges and the top surface of the MIBS pn junction diode are also passivated using the same passivation layer(s) and processes used to passivate the sunny-side and edges of the solar cell, passivation/ARC coating layer(s) 280. FIG. 16A does not show some details of the solar cell and MIBS structure such as the patterned M1 and M2 metallization, rear side passivation layer, M1 contact holes, M1-M2 via holes through the backplane, and the n+ doped contact windows for n-type substrate M1 connections in the MIBS device structures.

FIG. 16C shows a MIBS implementation using a peripheral Schottky rim diode bypass switch. Isolated Schottky rim diode bypass switch region 286 (isolated from isle I₁₁ by corresponding isolation trench 274) comprises an n-doped region and an inner and outer n+ region and is used as a Schottky diode bypass switch. Schottky rim diode bypass switch region 286 may be a full peripheral rim diode with a width in the range of 200 to 600 microns (this dimension may be chosen to be larger or smaller than this range).

In one fabrication embodiment, FIG. 16C shows a backplane-laminated or backplane-attached MIBS-enabled solar cell after completion of manufacturing processes for the MIBS-enabled back-contact/back-junction isled master cell comprising completion of the back-contact/back-junction cell processing through a patterned first-level metallization or M1 (for example made of a suitable conductor which can serve as both an effective ohmic contact on heavily doped silicon as well as an effective Schottky barrier contact on lightly doped silicon, such as aluminum or aluminum-silicon alloy), backplane lamination, epitaxial silicon lift-off release and separation from a crystalline silicon reusable template when using an epitaxial lift off silicon substrate (this process not applicable or required when using starting crystalline silicon wafers instead of epitaxial lift off substrates), formation of the trench isolation (e.g., by pulsed laser scribing or cutting) to define MIBS rim Schottky diode border, optional silicon thinning etch, texture and post-texture clean, formation of passivation and ARC (e.g., by PECVD or a combination of PECVD with another process such as ALD), and fabrication of a final patterned second-level metal or M2 on the backplane (in conjunction with the conductive M1-M2 via plugs).

As can be seen in FIG. 16C, the n-type silicon substrate also used as the base region of the solar cell (for instance formed through in-situ-doped epitaxial deposition when using epitaxial lift off processing, or from a starting n-type crystalline silicon wafer when not using epitaxial lift off processing) is also used as the n-type silicon substrate region for the MIBS Schottky diode. The M1 metal (not shown), for example made of aluminum or a suitable aluminum alloy such as aluminum with some silicon addition, not only makes the M1 ohmic contact metallization for the solar cell (for both base region through n+ doped contact openings and emitter contact region through p+ doped contact openings of the solar cell), but also creates the metallization contacts for the MIBS Schottky diode (both the non-ohmic Schottky barrier contact on the lightly doped n-type silicon substrate region and the ohmic contact to n-type silicon through heavily doped n+ doped regions). The lightly doped n-type silicon substrate region of the MIBS diode is from the same n-type substrate used for the solar cell and serving as its base region (e.g., the n-type substrate may be formed by in-situ-doped n-type epitaxial silicon deposition when using epitaxial silicon lift-off processing, or from a starting n-type crystalline silicon wafer when not using epitaxial silicon lift off processing). The heavily doped n+ diffusion doping of the n-type silicon region for the MIBS Schottky diode ohmic contacts to the n-type silicon substrate may be formed at the same time and using the same process also used for producing the heavily doped n+ doped base contact regions for the solar cell (in preparation for the subsequent patterned M1 metallization). The combination of patterned M1 and M2 metallization structures complete the solar cell and MIBS Schottky diode electrical interconnections and ensure the MIBS diode terminals are properly connected to the solar cell terminals to provide cell-level integrated shade management and solar cell protection. As can be seen FIG. 16C, the sidewall edges and the top surface of the MIBS Schottky diode are also passivated using the same passivation and ARC layer(s) and process(es) used to form the passivation and ARC layer(s) on the sunny-side and edges of the solar cell—note passivation/ARC coating layer(s) 280. Again, FIG. 16C does not show some structural details of the solar cell structure including but not limited to the patterned M1 and M2 metallization layers.

The monolithically isled solar cells, and optionally MIBS embodiments, disclosed herein employ trench isolation in conjunction with a shared backplane substrate to establish partitioning and electrical isolation between the semiconductor substrate regions (isles) and also optionally for the MIBS device and adjacent isles or solar cell region. One method to create the trench isolation regions is pulsed (such as pulsed nanoseconds) laser scribing. Below is a summary of key considerations and laser attributes for using a laser scribing process to form the trench isolation regions which partition and electrically isolate substrate region(s).

Pulsed laser scribing for trench isolation formation may use a pulsed nanoseconds (ns) laser source at a suitable wavelength (e.g., green, or infrared or another suitable wavelength to ablate the semiconductor layer with relatively good selectivity to cut through the semiconductor substrate layer with respect to the backplane material) commonly used and proven for scribing and cutting through silicon. The laser source may have a flat-top (also known as top-hat) or a non-flat-top (e.g., Gaussian) laser beam profile. It's possible to use a pulsed laser source wavelength which is highly absorptive in silicon but can partially or fully transmit through the backplane (hence, cut through the semiconductor layer without substantially removing the backplane material after the through-semiconductor layer laser cutting is complete and the beam reaches the backplane sheet). For instance, we may use a pulsed nanoseconds IR or green laser beam which may effectively cut through the silicon substrate layer and partially transmit through the backplane material (hence, removing little to negligible amount of backplane material during the trench isolation cut).

The pulsed laser beam diameter and other properties of the pulsed nanoseconds laser source may be chosen such that the isolation scribe width is in the range of a few microns up to 10's of microns as a width much larger than about 100 microns would be rather excessive and result in unnecessary waste of precious silicon substrate area and some reduction of the total-area efficiency of the solar cells and modules. Thus, it is beneficial to minimize the trench isolation areas as compared to the highly desirable solar cell area. In practice, pulsed nanoseconds laser cutting can produce trench isolation regions with width in the desirable range of about 20 microns up to about 60 microns. For instance, for a 156 mm×156 mm solar cell, a trench isolation width of 30 microns corresponds to an area ratio of 0.077% for the trench isolation area as a fraction of the cell area. This represents a rather negligible area compared to the solar cell area, in other words, this small ratio provides negligible waste of solar cell area and ensures negligible loss of total-area solar cell and module efficiency.

Pulsed nanoseconds (ns) laser scribing or cutting to form trench isolation may be performed immediately after the backplane lamination process when using starting crystalline silicon wafers to fabricate the solar cells (and in the case of solar cells using epitaxial silicon lift-off processing, after completion of the backplane lamination process and subsequent lift-off release of the laminated cell from the reusable template and after or before pulsed laser trimming of the solar cell) in a back-contact/back-junction solar cell fabrication process as described herein. In the case of solar cells fabricated using epitaxial silicon lift-off processing, the trench isolation scribing or cutting process may optionally use the same pulsed laser tool and source used for pre-release scribing of the epitaxial silicon layer to define the lift-off release boundary and/or used for post-release trimming of the laminated solar cell. Thus, no additional laser process tool may be needed in order to form the trench isolation regions.

Pulsed nanoseconds (ns) laser scribing to form trench isolation may also be used to partition the isles and define the fully isolated MIBS rim diode region outside an isolated solar cell island surrounded by and defined by the rim. Alternatively, the pulsed ns laser scribing process may form other designs of the MIBS diode, such as in a multiple MIBS diode island design as well as and many other possible MIBS pattern designs.

Pulsed laser scribing may be used to cut through the thin (such as sub-200 microns and more particularly sub-100 microns) silicon substrate layer (from the sunny side) and substantially stop on the backplane material sheet. If desired and/or required, a simple real-time in-situ laser scribe process end-pointing, such as using reflectance monitoring, may be used for process control and endpointing to minimize trenching or material removal in the backplane sheet while enabling complete through-semiconductor-layer laser cut.

The sidewalls of the solar cell and the MIBS rim diode regions may be subsequently wet etched (for instance, as part of the solar cell sunny-side wet etch/texture process), post-texture cleaned, and passivated (by deposition of the passivation and ARC layer) during the remaining solar cell fabrication process steps.

The MIBS diode may be a pn junction diode used as the MIBS bypass device or shade management switch. A pn junction MIBS diode fabrication process to produce a MIBS-enabled solar cell of may have the following, among others, attributes and benefits:
In some solar cell processing designs, there may be essentially no change (or minimal change) to the main solar cell fabrication process flow to implement MIBS (for example a back-junction/back-contact crystalline silicon solar cell fabrication using either crystalline silicon starting wafers or epitaxial silicon and porous silicon/lift-off processing in conjunction with a reusable crystalline silicon template, and an electrically insulating backplane). Thus, there may be essentially no added processing cost to implement MIBS along with the solar cells (icells) disclosed herein.
In a back-contact/back-junction epitaxial silicon lift-off cell process, following the completion of the on-template cell processing involving most of the back-contact, back-junction cell process steps, the following processes may be performed (provided as an example of various possible process flows): (i) backplane lamination to the solar cell backside; (ii) pre-release trench scribe (for example using a pulsed nanoseconds laser scribe tool or alternatively using another scribing tool such as plasma scribe) of the thin epitaxial silicon substrate to define the epitaxial silicon lift-off release boundary; (iii) mechanical lift-off release of the backplane-supported cell and its detachment from the reusable crystalline silicon template; (iv) laser trim (for example using a pulsed nanoseconds laser source) of the backplane-laminated cell for precision trim and to establish the final desired dimensions for the solar cell in conjunction with its associated MIBS; (v) pulsed nanoseconds laser scribing (or plasma scribing or another suitable scribing technique) on the sunny-side of the solar cell to form the trench isolation region(s) and to define the inner solar cell island(s) and the peripheral rim diode(s) regions, this step providing the isles and corresponding MIBS regions; (vi) and, subsequent cell processing such as sunny-side texture and post-texture clean followed by additional cell process steps such as PECVD sunny-side passivation and anti-reflection coating (ARC) layer deposition and final cell metallization including patterned second level metallization if applicable. When using starting crystalline silicon wafer instead of epitaxial silicon lift-off processing, the process flow is fairly similar to the flow described above, except that there is no reusable template, porous silicon, epitaxial silicon, or release process. In the process flow described above for the solar cells made using epitaxial silicon lift-off processing, the trench isolation scribing process and tool may be essentially the same as the process and tool used for pre-release trench scribe and/or the post-release precision trim of the backplane-laminated solar cell and MIBS substrate.
The laser scribed trench isolation process may be performed (for example using a pulsed nanoseconds laser source) to create complete through-semiconductor trench(es) within the semiconductor layer through the entire thickness of the crystalline silicon layer and substantially stopping at the backplane—thus forming the electrically isolated n-type silicon rim region for the MIBS diode and the n-type silicon island region for solar cell assuming an n-type base and p+ emitter solar cell (a common doping type for a back-contact/back-junction IBC solar cell).

In an all-series-connected cell, an M2 cell metallization design which results in sufficiently low or negligible ohmic losses should be used due to the current flow on lateral M2 connectors between the adjacent series-connected columns. Lateral M2 jumpers or connectors (which may be formed in conjunction with the patterned M2 layer) are used to interconnect the adjacent columns of icell in electrical series.

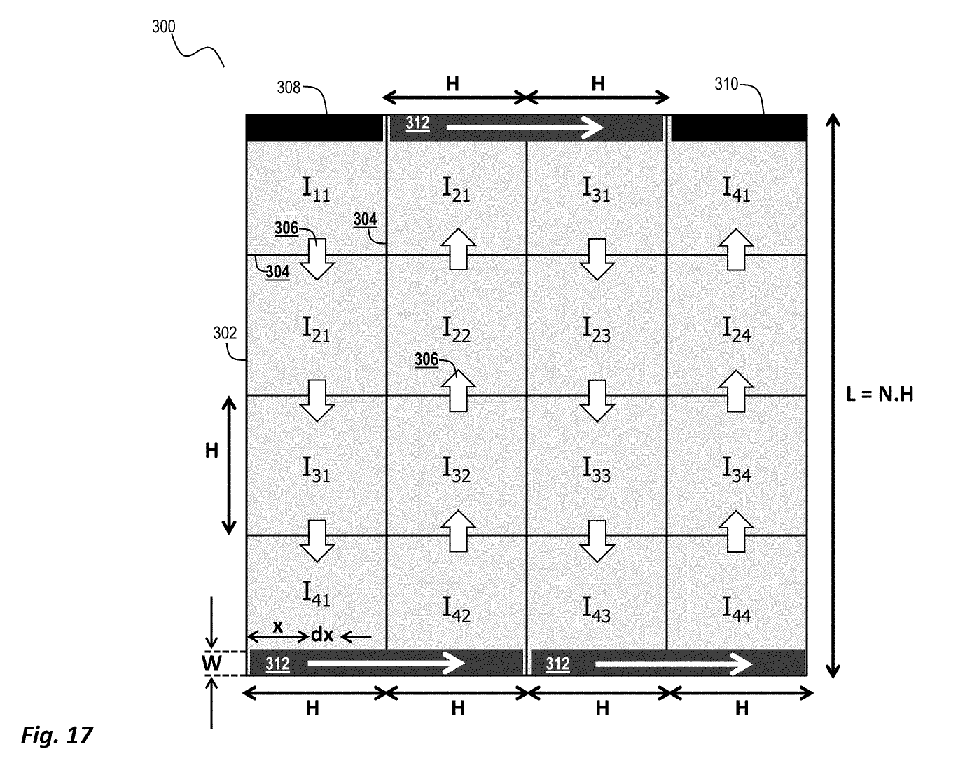

As shown in FIG. 17, all-series-connected icell or master cell 300 has an N×N array (N rows and N columns, shown as 4×4 in this representative example) of electrical series-connected isles I₁₁ through I₄₄ (isles defined by outer cell boundary 302 and electrical isolation trenches 304) from emitter busbar 308 to base busbar 310, each isle in a column electrically connected by M2 series connections 306 (simply shown as arrows) and each column in series electrically connected by lateral M2 jumpers 312. Master cell 300 has N columns (in this embodiment N=4) and N−1 lateral M2 jumpers 312 (N−1=3) each with a length of 2H and width of W. A lateral M2 jumper half-segment has a length of H (with H being the side dimension of each square-shaped isle) and width of W. M2 metallization pattern is not shown in FIG. 17; however an M2 unit cell such as that shown in FIG. 13 may correspond to each isle (I₁₁ through I₄₄).

Assuming an M2 metal layer thickness oft and a resistivity of ρ (or a sheet resistance of ρ/t). And assuming the master square cell has a side dimension of L=N·H, an area of L², a maximum power of Pₘₚ, and a non-isled (non-tiled) maximum-power-point (MPP) current of Iₘₚ (in other words the MPP for a single isle cell—for an isled master cell with all-series-connected isles, the MPP current is scaled down by N²). And assuming for an isled master cell having N×N series-connected isles, assume Pₛ is the ohmic power loss per half-segment of a lateral M2 jumper, and Pₗ is the total ohmic power loss for all the lateral M2 jumper segments, thus Pₗ=2(N−1)·Pₛ. The inter-columnar current flow ohmic losses in an all-series connected N×N master cell may be calculated as follows: Pₛ=Integral from 0 to H of {[(ρ·dx)·(W·t)]·[(Iₘₚ/N²)·(x/H)]²}; thus Pₛ=[ρ/(W·t)]·[Iₘₚ/(N²·H)]²·{Integral from 0 to H of [x²·dx]}; thus Pₛ=[ρ/(W·t)]·[Iₘₚ/(N²·H)]²·(H³/3)=(⅓)·[(ρ·H)/(W·t)]·(Iₘₚ/N²)²; since Pₗ=2(N−1)·Pₛ then Pₗ=[2(N−1)/3]·[(ρ·H)/(W·t)]·(Iₘₚ/N²)²; and since H=L/N then Pₗ=[2(N−1)/3]·[(ρ·L)/(N·W·t)]·(Iₘₚ/N²)²; thus Pₗ=[2(N−1)/(3·N⁵)]·[(ρ·L)/(W·t)]·Iₘₚ². The total lateral M2 jumper power loss factor (ratio) is defined as kⱼ=Pₗ/Pₘₚ.

Now, assuming a solar cell having approximately 22.5% mean cell efficiency and Pₘₚ=5.50 Wp and assuming Vₘₚ=0.59 V, Iₘₚ=9.3 A, M2 metal thickness requirements for aluminum and copper may be calculated as describe herein assuming an allowable maximum total lateral M2 jumper power loss factor (ratio) of 0.01, 0.005, or 0.0025 (as a fraction of Pₘₚ for the cell). Power Loss Factor=kⱼ=(Pₗ/Pₘₚ) and Kⱼ (in allowable maximum M2 loss)=[2(N−1)/(3·N⁵)]·[(ρ·L)/(W·t)]·(Iₘₚ²/Pₘₚ).

Thus, required lateral M2 jumper width W and/or the M2 metal thickness t based on an allowable kⱼ may be expressed as W·t=[2(N−1)/(3·N⁵)]·(ρ·L)·(Iₘₚ²/Pₘₚ)/kⱼ where kⱼ is the maximum allowable total lateral M2 jumper ohmic loss as a fraction of Pₘₚ.

Tables 2 through 7 below show calculated M2 lateral jumper W·t and W values for aluminum with bulk resistivity of ρ=2.82 μΩ·cm (Tables 2 through 4) and copper with bulk resistivity of ρ=1.68 μΩ·cm (Tables 5 through 7) for various allowable loss factors (kⱼ) and the N value between 3 and 5, and L=156 mm.

TABLE 2
Calculated W.t Values (in cm²) With Aluminum M2 Metallization.

| N and kⱼ Values | N = 3 | N = 4 | N = 5 |
|---|---|---|---|
| kⱼ = 0.0025 | 1.52E−03 cm² | 5.40E−04 cm² | 2.36E−04 cm² |
| kⱼ = 0.0050 | 7.59E−04 cm² | 2.70E−04 cm² | 1.18E−04 cm² |
| kⱼ = 0.0100 | 3.80E−04 cm² | 1.35E−04 cm² | 5.90E−05 cm² |

TABLE 3
Calculated W Values (in cm) With Aluminum M2
Metallization and t = 3 μm Al.

| N and kⱼ Values | N = 3 | N = 4 | N = 5 |
|---|---|---|---|
| kⱼ = 0.0025 | 5.061 cm | 1.802 cm | 0.787 cm |
| kⱼ = 0.0050 | 2.531 cm | 0.901 cm | 0.394 cm |
| kⱼ = 0.0100 | 1.265 cm | 0.450 cm | 0.197 cm |

TABLE 4
Calculated W Values (in cm) With Aluminum M2
Metallization and t = 5 μm Al.

| N and kⱼ Values | N = 3 | N = 4 | N = 5 |
|---|---|---|---|
| kⱼ = 0.0025 | 3.037 cm | 1.081 cm | 0.472 cm |
| kⱼ = 0.0050 | 1.518 cm | 0.540 cm | 0.236 cm |
| kⱼ = 0.0100 | 0.759 cm | 0.270 cm | 0.118 cm |

TABLE 5
Calculated W.t Values (in cm²) With Copper M2 Metallization.

| N and kⱼ Values | N = 3 | N = 4 | N = 5 |
|---|---|---|---|
| kⱼ = 0.0025 | 9.05E−04 cm² | 3.22E−04 cm² | 1.41E−04 cm² |
| kⱼ = 0.0050 | 4.52E−04 cm² | 1.61E−04 cm² | 7.03E−05 cm² |
| kⱼ = 0.0100 | 2.26E−04 cm² | 8.05E−05 cm² | 3.52E−05 cm² |

TABLE 6
Calculated W Values (in cm) With Copper M2
Metallization and t = 3 μm Cu..

| N and kⱼ Values | N = 3 | N = 4 | N = 5 |
|---|---|---|---|
| kⱼ = 0.0025 | 3.015 cm | 1.073 cm | 0.469 cm |
| kⱼ = 0.0050 | 1.508 cm | 0.537 cm | 0.234 cm |
| kⱼ = 0.0100 | 0.754 cm | 0.268 cm | 0.117 cm |

TABLE 7
Calculated W Values (in cm) With Copper M2
Metallization and t = 5 μm Cu.

| N and kⱼ Values | N = 3 | N = 4 | N = 5 |
|---|---|---|---|
| kⱼ = 0.0025 | 1.809 cm | 0.644 cm | 0.281 cm |
| kⱼ = 0.0050 | 0.905 cm | 0.322 cm | 0.141 cm |
| kⱼ = 0.0100 | 0.452 cm | 0.161 cm | 0.070 cm |

Based on the exemplary calculations above, the following regarding ohmic losses of M2 lateral jumpers between adjacent isle columns may be concluded:
Practical and optimum M2 designs with sufficient lateral M2 jumper width can be provided in order to limit the total lateral M2 jumper ohmic power loss to less than about 1% (or as low as less than 0.5%) relative, without a need for soldering external copper ribbon tabs on the lateral M2 jumpers between the isle columns;
For a given M2 metal thickness, the total lateral M2 jumper ohmic power loss is reduced for higher values of N and/or lower resistivity metal;
For either aluminum or copper M2 metallization in an isled cell design with N=4, the M2 jumper width may be limited to less than 1 cm for M2 metal thickness of either 3 μm or 5 μm (or any width approximately in this range) while maintaining the maximum total lateral M2 jumper power loss to no more than about 0.50% relative ohmic losses—corresponding to approximately 0.1% absolute cell efficiency loss due to the M2 jumpers; and
The ability to limit the maximum lateral M2 jumper ohmic losses to well below 1% relative while using an M2 metal (aluminum or copper) thickness of no more than 5 μm, or 3 μm, with lateral jumper width of less than 1 cm provides for the formation of high-performance, low-loss M2 metallization without a need for externally soldered copper ribbon tabs on the lateral M2 jumpers. Thus enabling the production of low-cost, reliable isled cells without a need for excessively large value of N. In other words N=4 is sufficient (in an N×N=4×4 icell design) and in some instances N=5 may be more advantageous since it provides even lower losses.

As noted, isles (designed in any shape) may be electrically connected in an all-series, an all-parallel, or a hybrid series-parallel M2 interconnection design. The M2 interconnection pattern should maintain the benefits of substantially reduced R·I² ohmic losses in the cell, module, and system due to the scaled up the voltage and scaled down the current of the master cell.

The following exemplary embodiments are provided to illustrate high cell efficiency (for example approximately 22% cell efficiency) interconnection designs for an evaporated aluminum M2 pattern having a layer thickness of less than approximately 5 μm compatible with both full-square and pseudo-square substrate formats. Specifically, designs describing a master cell having a 4×4 array of monolithic trench isolated isles having a hybrid parallel-series isle connection design and having an all-series isle connection design with a master cell voltage of approximately close to 5 V and a current of approximately close to 1 A are provided.

It is important to note that although the isle designs are described generally as square shaped, the isles may be formed in any geometric shape in accordance with the disclosed subject matter. And in most instances, it is desirable to eliminate area-related current mismatches between the series-connected isles—in other words, to design and pattern the array of isles symmetrically to maintain equivalent area between isles or subgroups of isles connected in parallel.

Further, the M2 interconnection designs disclosed herein provide relatively optimum-range current-voltage parametrics for integration of inexpensive, embedded, high-performance distributed MPPT power optimizer and/or shade management electronics components assuming a master cell maximum-power voltage (Vₘₚ) in the range of approximately ˜5 V to 10 V and a master cell maximum-power current (Iₘₚ) in the range of approximately ˜0.5 A to 1 A.

Additionally, the M2 interconnections provided herein are capable of supporting various installed PV arrays, such as 600 VDC and 1,000 VDC PV systems for maximum system-level efficiency in residential and commercial rooftop as well as ground-mount utility-scale applications.

The following parametric assumptions are provided for a master cell or icell having an efficiency of approximately 22% with a 4×4 array of isles connected in parallel (referred to herein as all-parallel): Cell Power=5.35 Wp (assumes full-square 156 mm×156 mm master cell); V_{oc}=685 mV, and Vₘₚ=575 mV, then Vₘₚ/V_{oc}=0.84 or 84%; I_{oc}=9.90 A, and Iₘₚ=9.30 A, then Vₘₚ/V_{oc}=0.94 or 94%; and Fill Factor=(Vₘₚ×Iₘₚ/V_{oc}×I_{oc})=0.79 or 79%.

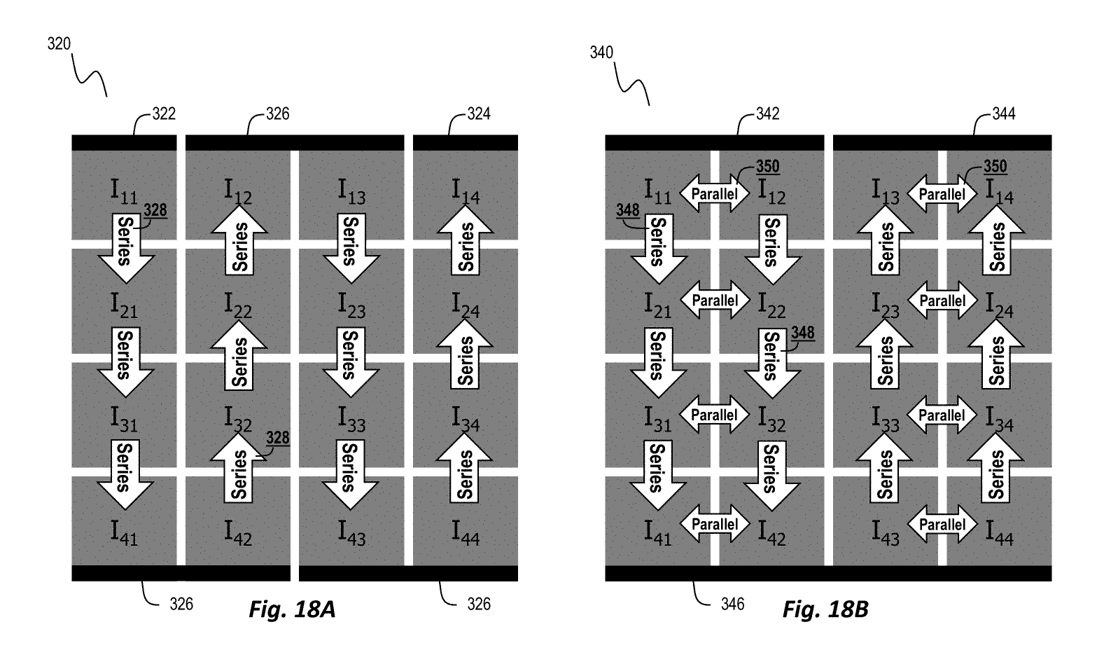

In an all-series 4×4 master cell (assuming a full-square 156 mm×156 mm master cell) referred to herein as a 1×16S (1 by 16 Series) design, an example of which is shown in FIG. 18A, the following may be assumed: V_{oc}=685 mV×16=10.96 V and I_{oc}=9.90 A/16=0.619 A; Vₘₚ=575 mV×16=9.20 V, and Iₘₚ=9.30 A/16=0.581 A. Further, for a 60-cell module using the 1×16 all-series master cell design, module parametrics may be assumed to be: Module V_{oc}=10.96 V×60=657.6 V and Module Vₘₚ=9.20 V×60=552.0 V; and I_{oc}=0.619 A, and Iₘₚ=0.581 A.

In a hybrid parallel-series (HPS) 4×4 master cell with 8 series pairs of isles (assuming full-square 156 mm×156 mm master cell)—referred to herein as a 2×8HPS (2 by 8 Hybrid Parallel Series) design, an example of which is shown in FIG. 18B, the following may be assumed: V_{oc}=685 mV×8=5.48 V and I_{oc}=9.90 A/8=1.238 A; Vₘₚ=575 mV×8=4.60 V, and Iₘₚ=9.30 A/8=1.163 A. Further, for a 60-cell module using the 2×8 hybrid master cell design, module parametrics may be assumed to be: Module V_{oc}=5.48 V×60=328.8 V, and Module Vₘₚ=4.60 V×60=276.0 V; and I_{oc}=1.238 A, and Iₘₚ=1.163 A.

FIGS. 18A, 18B, and 18C are schematic diagrams for a full square master cell or icell showing an all-series (1×16) master cell configuration (4×4 array of isles) referred to herein as a 1×16S design (FIG. 18A), a hybrid parallel-series (2×8) master cell or icell configuration (4×4 array of isles) referred to herein as a 2×8HPS design (FIG. 18B), and a hybrid parallel-series (8×8) master cell or icell configuration (8×8 array of isles) referred to herein as a 8×8HPS design (FIG. 18C).

As shown in FIG. 18A, all-series master cell or icell configuration 1×16S 320 has an 4×4 array of electrical series-connected isles I₁₁ through I₄₄ from emitter busbar 322 to base busbar 324, each isle in a column electrically connected by M2 series connections 328 and each column in series electrically connected by lateral M2 jumpers 326.

As shown in FIG. 18B, hybrid parallel-series master cell configuration 2×8HPS 340 has a 4×4 array of electrical series and parallel connected isles I₁₁ through I₄₄ from emitter busbar 342 to base busbar 344, adjacent isles in a column connected in parallel by M2 parallel connections 350 and each isle in a column electrically connected by M2 series connections 348 and combined parallel connected adjacent isles electrically connected in series by lateral M2 jumpers 346. In some applications, the 2×8HPS design of FIG. 18B may be particularly suitable for a master cell having a thin silicon absorber layer (for example having a thickness in the range of about a few microns up to 100 microns).

As shown in FIG. 18C, hybrid parallel-series master cell configuration 8×8HPS 352 has an 8×8 array of electrical series and parallel connected isles I₁₁ through I₈₈ from emitter busbar 354 to base busbar 356, adjacent isles in a column connected in parallel by M2 parallel connections and isles in a column electrically connected by M2 series connections and combined parallel connected adjacent isles electrically connected in series by lateral M2 jumper 358. In some applications, the 8×8HPS design of FIG. 18C may be particularly suitable for a master cell having a somewhat thicker silicon absorber layer (for example having a silicon thickness in the range of about 50 to 150 microns). This is due to the fact that this 8×8HPS design provides a higher degree of flexibility/bendability and hence can be suitable for a wide range of silicon thicknesses (even accommodating thicker silicon for flexible crack-free solar cells). The 2×8HPS solar cell of FIG. 18B and 8×8HPS solar cell of FIG. 18C provide the same current and voltage scaling factor of 8.

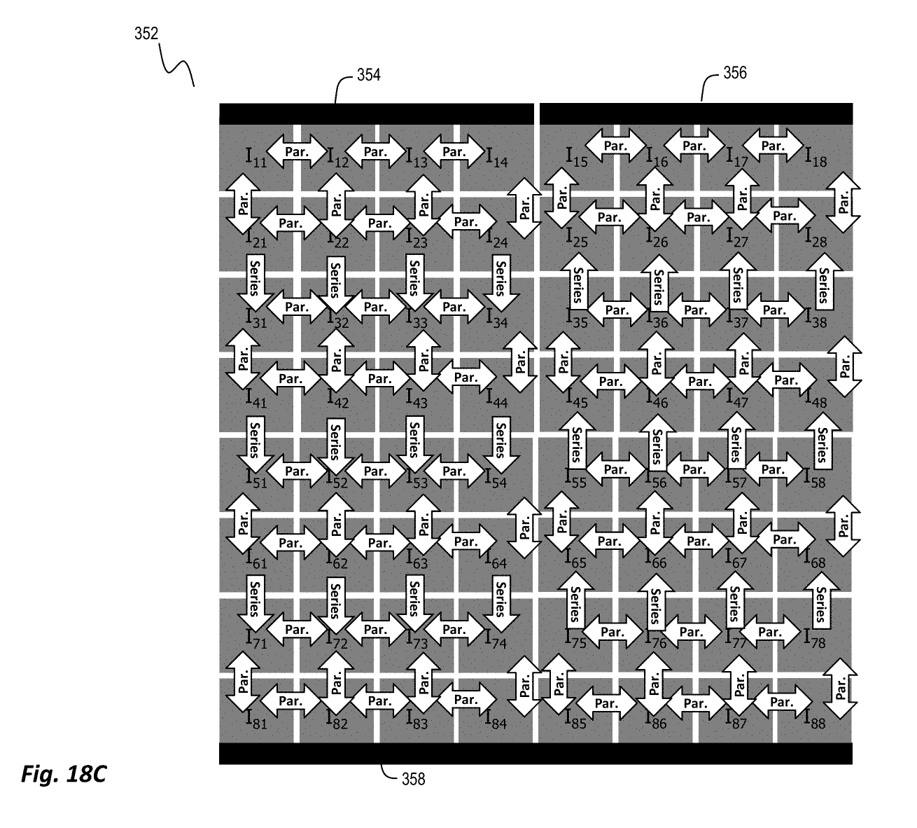

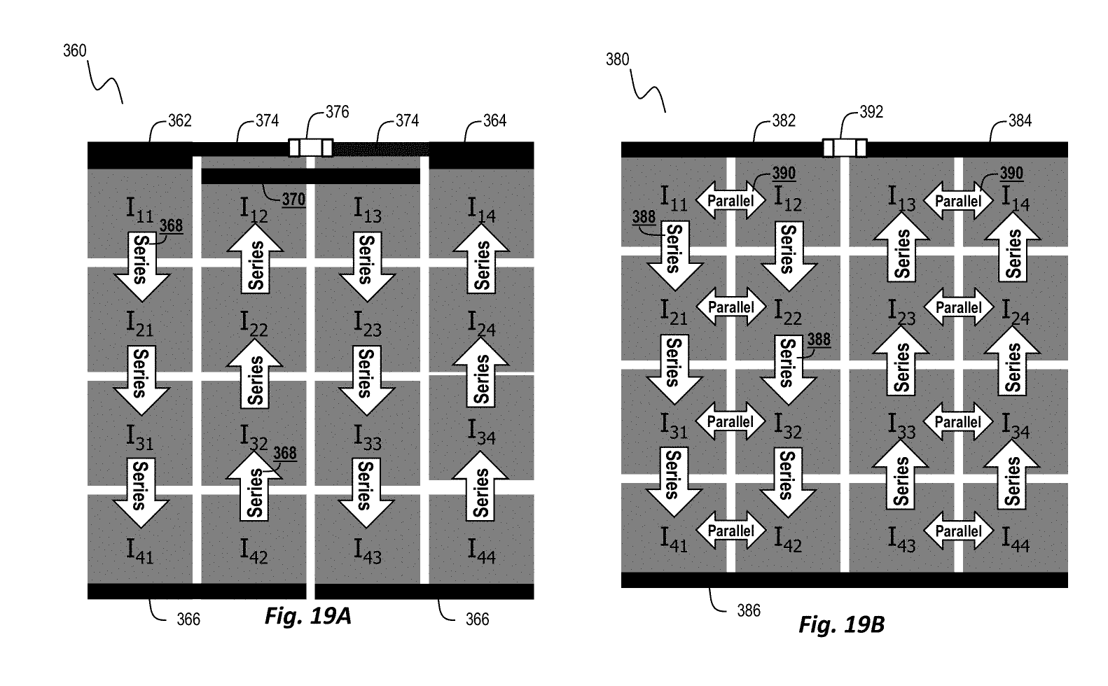

FIGS. 19A, 19B, and 19C are diagrams showing example placement/position of a relatively small shade management bypass switch (e.g., either a pn junction diode or a Schottky barrier diode) on the M2 interconnection designs of the master cells shown in FIGS. 18A, 18B, and 18C, respectively.

As shown in FIG. 19A, all-series master cell configuration 1×16S 360 has a 4×4 array of electrical series-connected isles I₁₁ through I₄₄ from emitter busbar 362 to base busbar 364, each isle in a column electrically connected by M2 series connections 368 and each column in series electrically connected by lateral M2 jumpers 366. Lateral M2 jumper 370 has been offset from the master cell peripheral edge for direct placement and connection of a relatively small-package bypass switch 376 to emitter busbar 362 and base busbar 364. Busbar extensions 374 connect emitter busbar 362 and base busbar 364 to bypass switch 376.

As shown in FIG. 19B, hybrid parallel-series master cell configuration 2×8HPS 380 has a 4×4 array of electrical series and parallel connected isles I₁₁ through I₄₄ from emitter busbar 382 to base busbar 384, adjacent isles in a column connected in parallel by M2 parallel connections 390 and each isle in a column electrically connected by M2 series connections 388 and combined parallel connected adjacent isles electrically connected in series by lateral M2 jumpers 386. Bypass switch 392 is positioned between and directly connected to emitter busbar 382 and base busbar 384.

As shown in FIG. 19C, hybrid parallel-series master cell configuration 8×8HPS 394 has an 8×8 array of electrical series and parallel connected isles I₁₁ through I₈₈ from emitter busbar 395 to base busbar 396, adjacent isles in a column connected in parallel by M2 parallel connections and isles in a column electrically connected by M2 series connections and combined parallel connected adjacent isles electrically connected in series by lateral M2 jumper 397. Bypass switch 398 is positioned between and directly connected to emitter busbar 395 and base busbar 396.

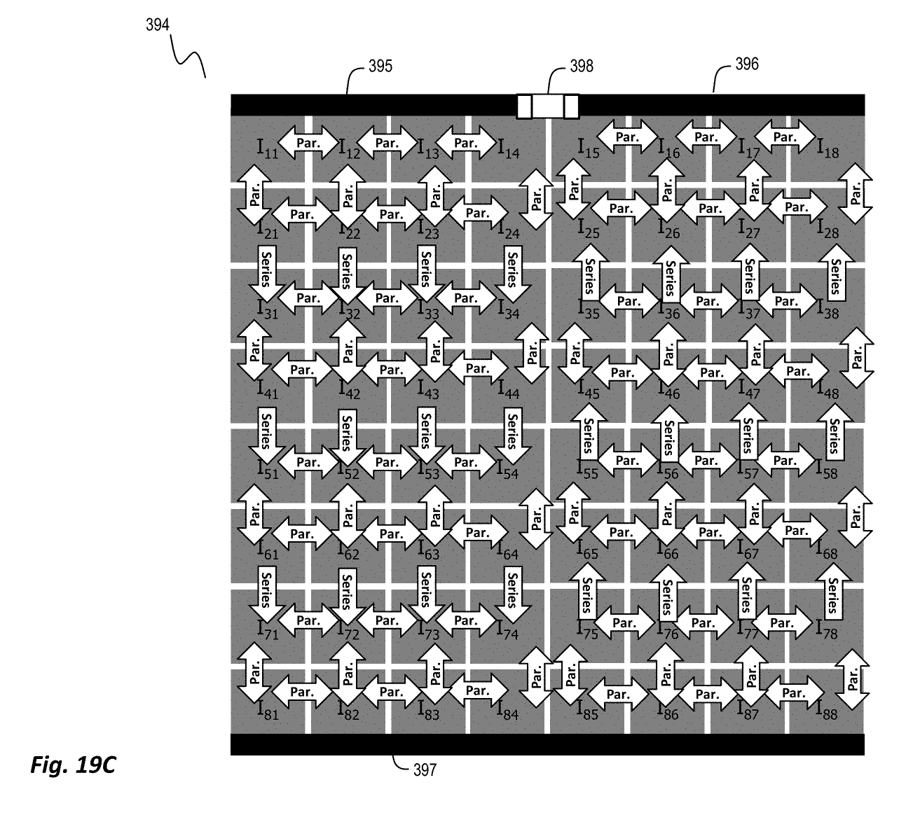

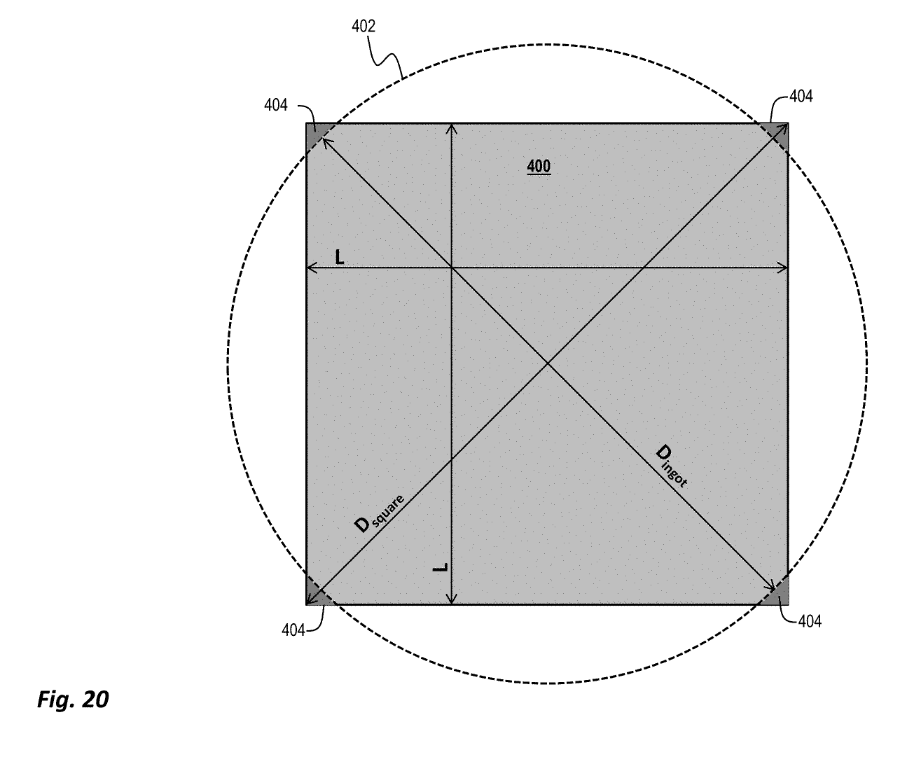

In practice, monocrystalline semiconductor wafers (particularly CZ and FZ monocrystalline silicon wafers) are often fabricated from a cylindrical ingot and most often commercially available in a circular shape. To maximize semiconductor material usage and minimize waste, a master cell may be formed as a pseudo-square solar cell—as shown in FIG. 20. FIG. 20 is a schematic diagram showing a top view of a pseudo-square shaped master cell substrate fabricated from a cylindrical ingot (shown by cylindrical ingot periphery).

Thus, to maintain symmetry and equivalently sized (equal series-connected isle areas) series connected isles or sub-groups of isles, isles within a pseudo-square shaped master cell may be individually designed in various shapes and configurations.

FIG. 20 is a diagram showing a top view of a pseudo-square shaped master cell substrate 400 fabricated from a cylindrical ingot (shown by cylindrical ingot periphery 402). Excluded corners 404 have area a′ per corner and have been removed/excluded from the pseudo-square master cell substrate design in order to minimize the ingot waste while providing a nearly (but not full) square wafer for solar cell fabrication.

In practice and used as exemplary design dimensions herein, pseudo-square master cell substrate 400 may have dimensions of 156 mm by 156 mm (L=156 mm) with a diagonal dimension of 220 mm (D_{square}=220 mm) formed from a cylindrical ingot having a final polished ingot diameter of 200 mm (D_{ingot}=200 mm). Assuming the dimensions described above, a full-square substrate will have an area (A_{sq})=L²=156 mm×156 mm=243.36 cm². And a pseudo-square substrate will have an area (A_{psq})=A_{sq}−4a′ where a′≈(D_{square}−D_{ingot})²/4, then a′≈(220 mm−200 mm)²/4≈1 cm² and A_{psq}≈243.36−4×1 cm²=239.36 cm². Thus when L=156 mm, standard pseudo-square wafers have a cell area of 239.36 cm² as compared to standard 156 mm×156 mm square wafers having cell area of 243.36 cm²—resulting in approximately 1.64% less area (4/243.36).

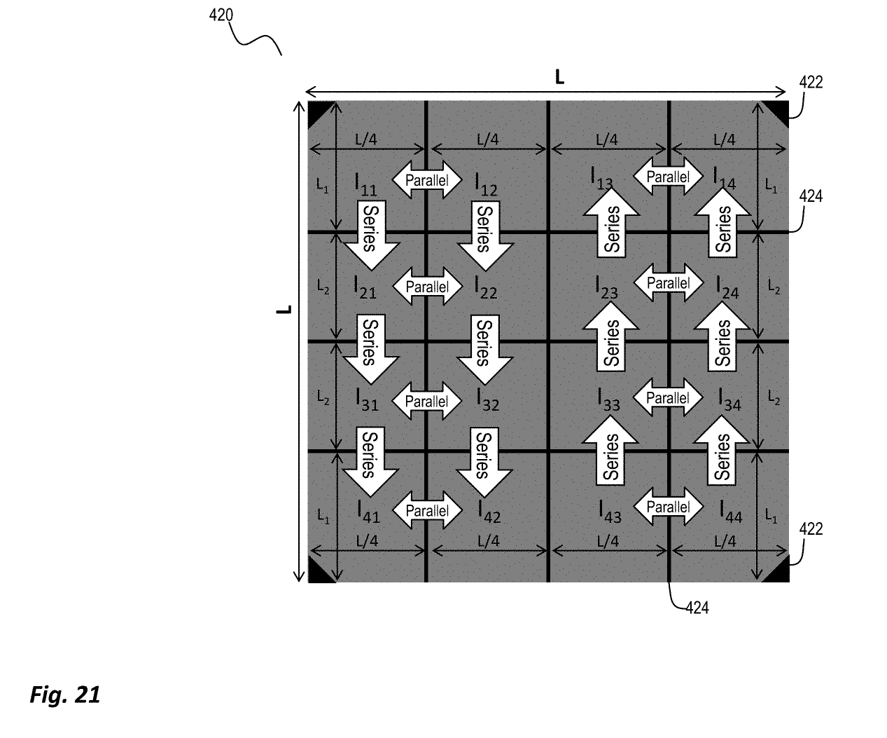

FIG. 21 is a diagram of a hybrid parallel-series pseudo-square master cell configuration 2×8HPS 420 having a 4×4 array of electrical series and parallel connected isles I₁₁ through I₄₄ (isles defined by isolation trenches 424) from emitter busbar to base busbar similar to the cell shown in FIG. 18B (emitter busbar, base busbar, and lateral M2 jumpers not shown in FIG. 21). Similar to the pseudo-square master cell shown in FIG. 20, pseudo-square master cell 420 has a side length L (for instance, 156 mm for a 156 mm×156 mm pseudo-square icell) and is missing corners 422 each having area a′.

The following dimensions are provided as an exemplary to fully balance the master cell current of pseudo-square master cell configuration 2×8HPS 420; however, as noted previously the isle design principles disclosed herein may be applicable to various cell shapes and dimensions. As shown master cell 420 is horizontally and vertically symmetrical (resulting in eight pairs of parallel connected isles) and the dimensional expressions following are for one quadrant (for example I₁₁, I₂₁, I₁₂, and I₂₂). Each set of isles connected in series may be designed or sized to have an equivalent area (and a corresponding equivalent voltage and current)—in other words the area of I₁₁+I₁₂=I₂₁+I₂₂.

For L=156 mm, L₁ and L₂ may then be calculated as follows, resulting in a fully current-balanced master cell: [(L/4)·L₁−a′]+(L/4)·L₁=2·(L/4)·L₂ and L₁+L₂=L/2. Thus for L=15.6 cm (or L/4=3.9 cm) and a′=1 cm^{2:} 3.9 L₁−1+3.9 L₁=2×3.9 L₂ and L₁+L₂=15.6/2. Then L₁−L₂=0.1282 cm and L₁+L₂=7.8 cm. Resulting in L₁=3.964 cm and L₂=3.836 cm.

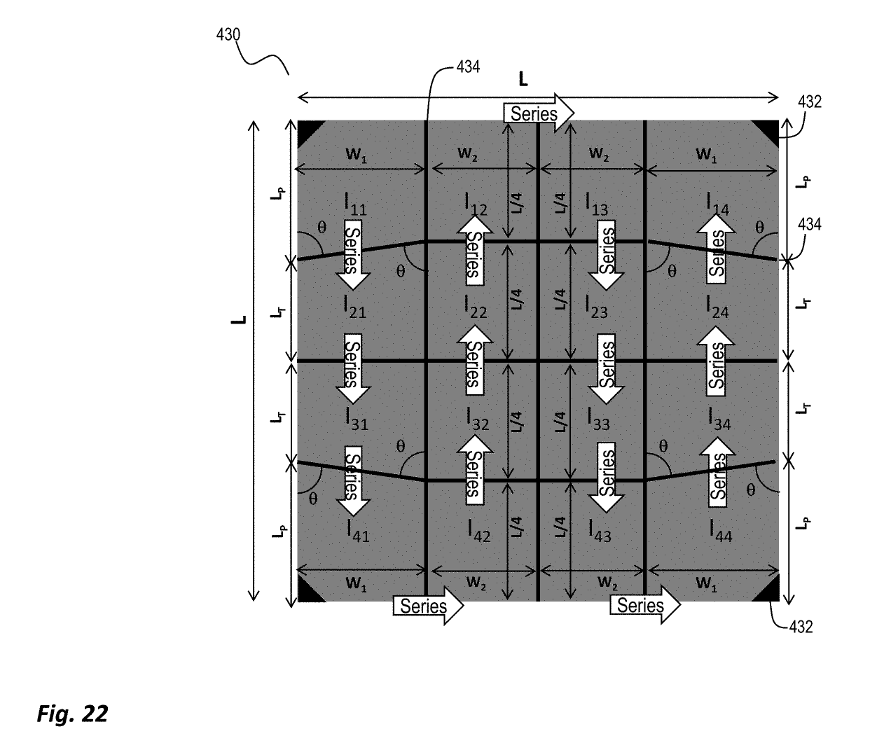

FIG. 22 is a diagram of an all-series pseudo-square master cell configuration 1×16S 430 having a 4×4 array of electrical series connected isles I₁₁ through I₄₄ (isles defined by isolation trenches 434) from emitter busbar to base busbar similar to the cell shown in FIG. 18A (emitter busbar, base busbar, and lateral M2 jumpers not shown in FIG. 22). Similar to the pseudo-square master cell shown in FIG. 20, pseudo-square master cell 420 has a side length L (for example 156 mm for a 156 mm 156 mm pseudo square solar cell) and is missing corners 422 each having area a′.

The following dimensions are provided as an exemplary to fully balance the master cell current of pseudo-square master cell configuration 1×16S 430 having a side length L (156 mm) with continuous isolation trenches defining each isle—in other words the guideline described provided for equal area isles. In some instances, continuous isolation trenches (trench isolation lines formed continuous with common intersection points) may be desired to maximize master cell flexibility for processing simplicity during scribing and to minimize crack generation and propagation. As shown in FIG. 22, all trench isolation line intersections have right angles, except for those specified otherwise.

In the isle design of FIG. 22, isles in the second and third columns (I₁₂, I₂₂, I₃₂, I₄₂, I₁₃, I₂₃, I₃₃, I₄₃) are rectangular, each having an area (L/4)·W₂. Isles in the first and fourth columns are non-rectangular: isles I₂₁, I₃₁, I₂₄, and I₃₄ are trapezoidal; and corner isles I₁₁, I₄₁, I₁₄, and I₄₄ are polygons. The three vertical scribe lines (isolation trenches) and the central horizontal scribe line (isolation trench) are straight lines running from edge to edge of the master cell. The two outside horizontal scribe lines (isolation trenches)—in other words the top and bottom scribe lines—are straight and horizontal between the two middle columns (columns 2 and 3) and sloped by angle θ as the lines extend to the first and fourth columns. Thus, master cell 430 is horizontally and vertically symmetrical (resulting in 16 connected isles each having an equivalent area and four symmetrical quadrants). The dimensional expressions following are for one quadrant (for example I₁₁, I₂₁, I₁₂, and I₂₂). Each set of isles connected in series is designed to have an equivalent area (and a corresponding equivalent voltage and current)—in other words the area of I₁₁=I₂₂=I₂₁=I₂₂.

For a master cell side dimension L (156 mm) the isle dimensions of master cell 430, may be calculated as follows: the area of isle I₁₂ (same rectangular shape and area as isles I₂₂, I₃₂, I₄₂, I₁₃, I₂₃, I₃₃, I₄₃)=A_{rectangle}=W₂·(L/4); the area of isle I₁₁ (same polygonal shape and area as Isles I₄₁, I₁₄, I₄₄)=A_{corner}=W₁·(L/4)+[W₁²/tan(θ)]/2−a′; the area of isle I₂₁ (same trapezoidal shape and area as isles I₃₁, I₂₄, I₃₄)=A_{trapezoid}=W₁·(L/4)−[W₁²/tan(θ)]/2. And A_{rectangle}=A_{corner}=A_{trapezoid}=(L²−4·a′)/16, thus W₂·(L/4)=W₁·(L/4)+[W₁²/tan(θ)]/2−a′=W₁·(L/4)−[W₁²/tan(θ)]/2=(L²−4·a′)/16=(15.6 cm×15.6 cm−4.0 cm²)/16=14.96 cm². Each isle has an area of 14.96 cm².

Then W₂·(L/4)=14.96 cm², W₂·L=59.84 cm², W₂=59.84/15.6 cm, thus W₂=3.836 cm. And W₁·(L/4)+[W₁²/tan(θ)]/2−a=14.96 cm2, W1·L+2[W₁²/tan(θ)]=63.84 cm², W₁·(L/4)−[W₁²/tan(θ)]/2=14.96 cm2, and W1·L−2[W₁²/tan(θ)]=59.84 cm². Therefore: 2W₁·L=63.84+59.84 cm²=123.68 cm², W₁=123.68/(2×15.6) cm, thus W₁=3.964 cm. And 4[W₁²/tan(θ)]=63.84−59.84 cm², 4[3.964²/tan(θ)]=4.00 cm², tan(θ)=15.7133, thus θ=86.36°. And L_{T}=L/4−W₁/tan(θ)=15.6/4-3.964/15.7133, L_{T}=3.9−0.252 cm, thus L_{T}=3.648 cm.

Thus, in the exemplary embodiment providing dimensions and angles for current matching in the 1×16S all-series 4×4 pseudo-square substrate master cell of FIG. 22: each isle area=14.96 cm², Polygonal Isles (4 Corners): Isles I₁₁, I₄₁, I₁₄, and I₄₄; Trapezoidal Isles (4): Isles I₂₁, I₃₁, I₂₄, and I₃₄; Rectangular Isles (8 Middle): I₁₂, I₂₂, I₃₂, I₄₂, I₁₃, I₂₃, I₃₃, I₄₃; L/4=39.00 mm; W₂=38.36 mm; W₁=39.64 mm; L_{T}=36.48 mm; Lₚ=41.52 mm; and θ=86.36°.

Monolithically Isled Master Cell Interconnections in PV Modules.

The isled master cells disclosed herein may be connected in electrical series, parallel, or hybrid parallel-series arrangements in PV modules. These interconnections may be performed using Monolithic Module embodiments described earlier (for example when a plurality of icells are attached to a continuous backplane layer and all the icell to icell electrical interconnections are performed using the patterned M2 layer). Master cell interconnection design choice in the module (series, hybrid parallel—series, or even parallel) may be based on the master cell maximum-power-point (MPP) current and voltage (Iₘₚ and Vₘₚ), the number of master cells in the module, as well as the desired MPP current and voltage of the module. Often, standard crystalline Si modules are made of 60 cells arranged in 6 columns, with 10 cells in each column (6×10) although other module configurations including 6×12=72 cells may be used based on the requirements for module power, module format, safety, BOS (e.g., wiring) cost, etc.

One exemplary module configuration embodiment for master cell interconnects (assuming N is at least 3) in a module of 6×10 (or more) master cells is a hybrid parallel-series configuration. Depending on the specific application and market, master cell interconnections may be optimized using a hybrid parallel-series design to provide the desired maximum module MPP current or the desired maximum module MPP current. And while an all-parallel configuration is possible, in some instances an all-parallel configuration may result in an excessively large module current resulting in significant ohmic losses. Further, while an all-series configuration is possible, in some instances an all-series configuration may result in an excessively high (for example larger than several hundred volts) module voltage (module Vₘₚ) which may cause safety concerns and/or may demand higher wiring costs due to the dielectric insulation requirements.

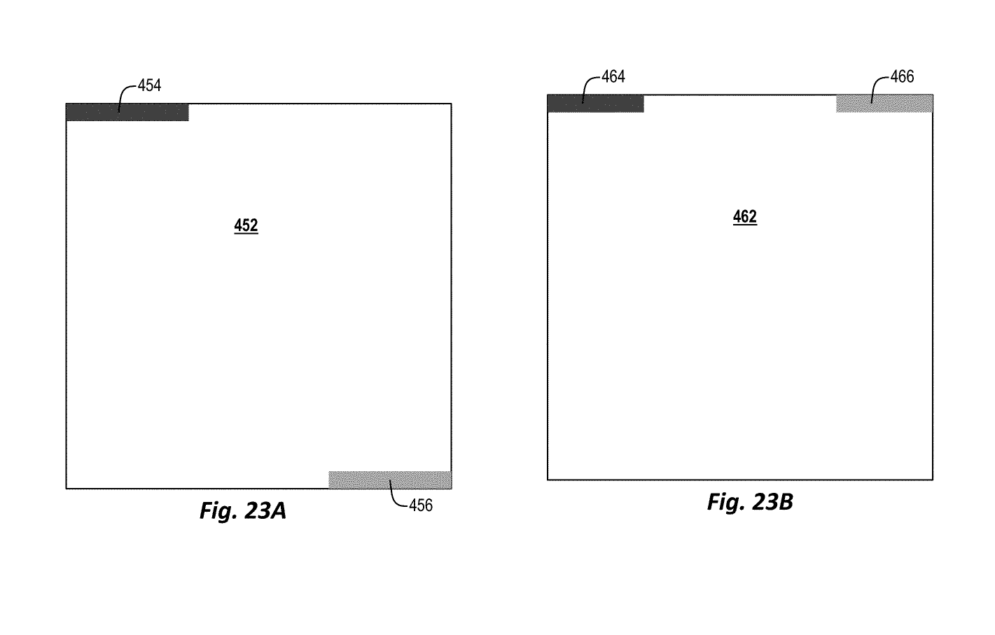

FIGS. 23A and 23B are diagrams showing a master cell or icell overview highlighting the position of the emitter and base busbars as dependent on the number of isles (odd or even number of isles), as well as M2 interconnection design. Both master cell 452 in FIG. 23A and master cell 462 in FIG. 23B have an array of S=N×N isles (or N×N subgroups of parallel-connected isles)—individual isles not shown. In master cell 452 N is an odd integer and in master cell 462 N is an even integer. As can be seen in FIG. 23A, master cell 452, when N is an odd integer and the isles (or subgroup of parallel-connected isles) are connected in electrical series, the master cell emitter and base busbars are positioned opposite the cell diagonal in two opposite quadrants—shown as emitter busbar 454 and base busbar 456 in FIG. 23A (for example see the master cells shown in FIGS. 15A and 15B). In master cell 462 N is an even integer and the isles (or subgroup of parallel-connected isles) are connected in electrical series, the master cell emitter and base busbars are positioned on the two opposite corners on the same side of the square cell—shown as emitter busbar 464 and base busbar 466 in FIG. 23B (for example see the master cells shown in FIG. 14A).

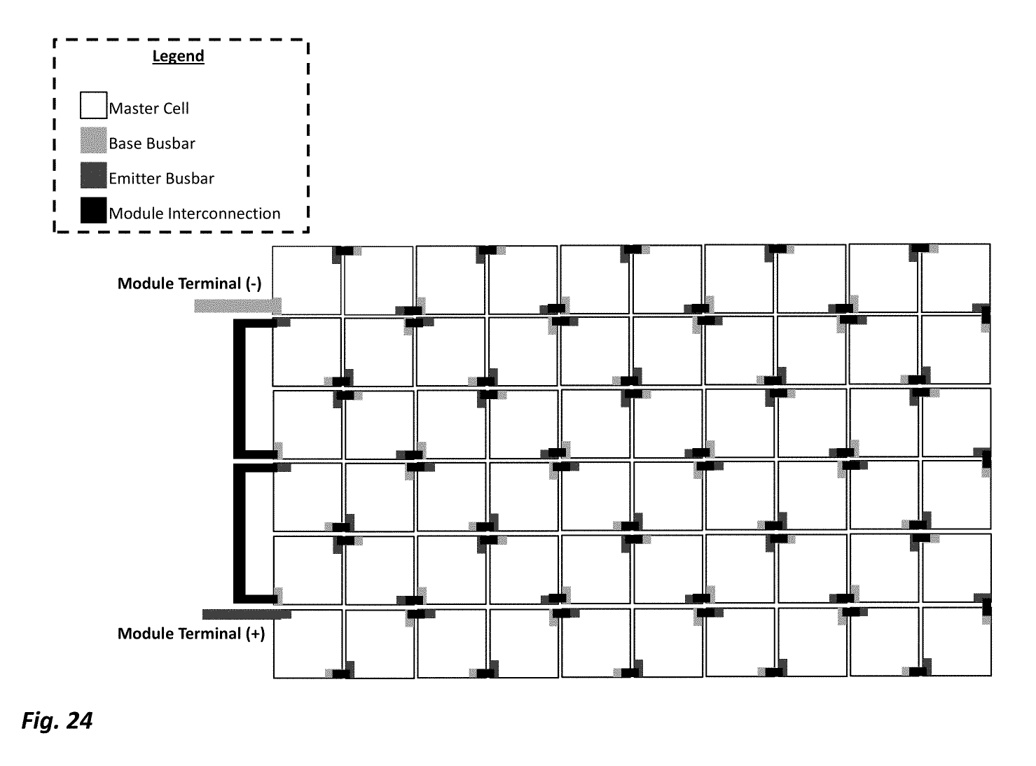

FIGS. 24 through 27 are diagrams depicting various 60 cell module connection designs for master cells designs having both an even and odd number of series connected isles (or subgroups of parallel-connected isles), such as those shown in of FIGS. 23A (N is odd) and 23B (N is even). The diagrams of FIGS. 24 through 27 are top module views (showing the frontside of the master cell) showing emitter busbars and base busbars for each master cell although the busbars are actually positioned on the backsides of the master cells. In other words, the emitter and base busbars and module interconnections are shown as visible through the master cell frontside to emphasize various cell-to-cell interconnection designs. Each of these representative modules may be made as a monolithic module by attaching or laminating a plurality of icells (e.g., 60 icells in a 6×10 arrangement as shown in these embodiments) to a continuous backplane sheet after completion of the solar cell backside processing through the patterned M1 layer and then performing the remaining post-backplane-lamination back-end solar cell processing on the continuous multi-cell backplane substrate through completion of the patterned M2 layer on the large continuous backplane sheet comprising the plurality of icells. This approach will result in interconnections of the icells to one another according to a desired electrical interconnection arrangement (all series or hybrid parallel-series) using the monolithic patterned M2 metallization layer. This results in a monolithic module, eliminating the need for tabbing and/or stringing and/or soldering of the solar cells to each other for module assembly (since patterned M2 already completes the cell-to-cell interconnections based on the monolithic module embodiment). Of course, each of these representative modules may also be made without the monolithic module embodiments disclosed herein by conventional tabbing and/or stringing and/or soldering of the solar cells to each other for module assembly.

FIG. 24 is an example of a module interconnection design (which is made using the patterned M2 layer if using monolithic module embodiments disclosed herein) for master cells or icells with emitter and base busbars positioned on opposite diagonal corners of the master cell (i.e., N is an odd number) and all icells connected in electrical series (all-series). Module voltage and current for 60 master cells connected in electrical series as shown in FIG. 24 may be calculated as follows: module voltage=60× master cell voltage. Thus, for N=4 and S=16: master cell voltage Vₘₚ≈16×0.59≈9.4 V; module Vₘₚ=60×9.4=564 V; and module Iₘₚ≈9.3 A/16≈0.58 A.

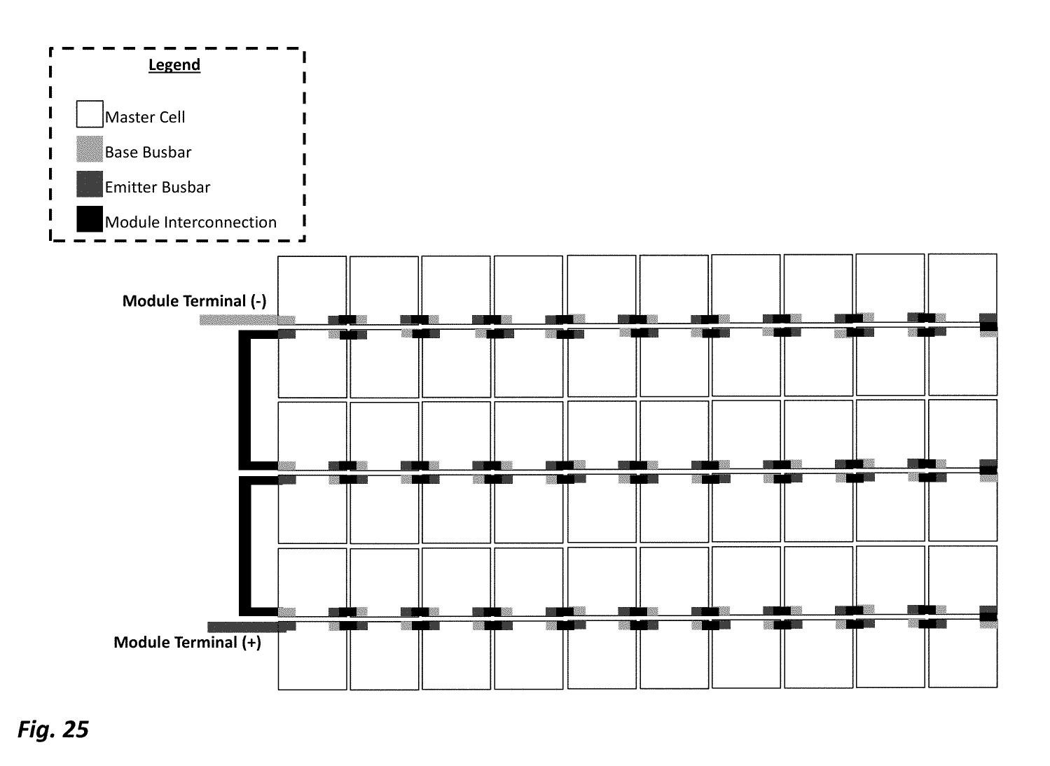

FIG. 25 is an example of a module interconnection design (which is made using the patterned M2 layer if using monolithic module embodiments disclosed herein) for master cells with emitter and base busbars positioned on corners on the same side of the master cell (N is an even number) and all cells connected in electrical series (all-series). For N=4 and S=16, module voltage and current may be calculated as described for FIG. 24.

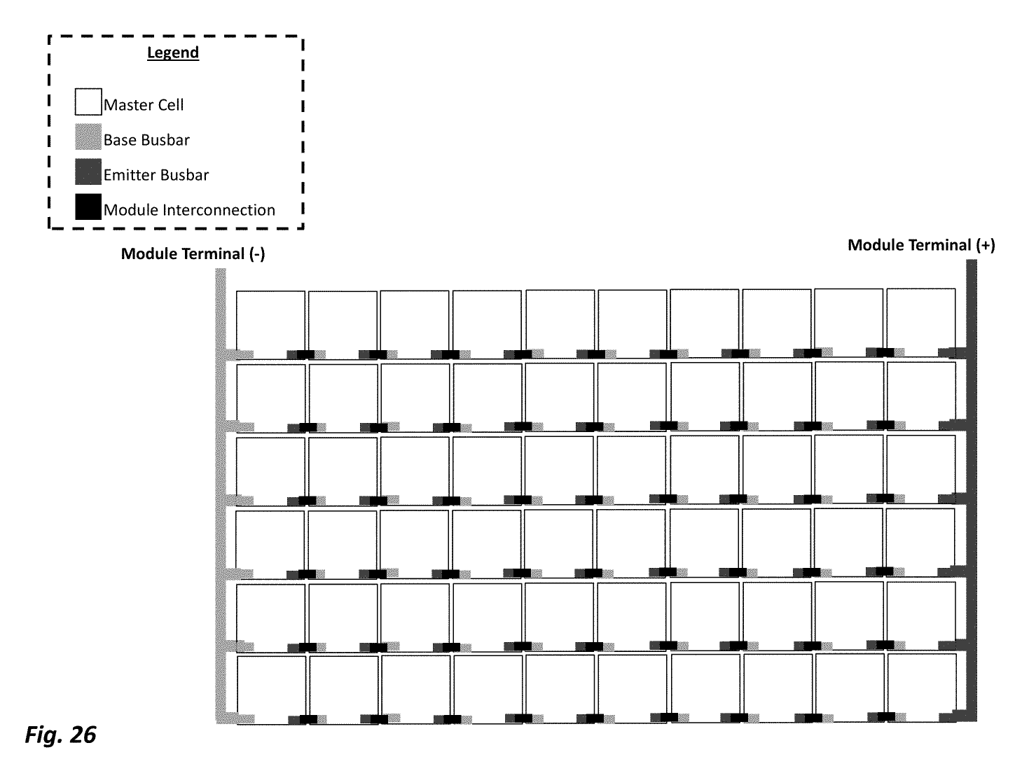

FIG. 26 is an example of a module interconnection design (which is made using the patterned M2 layer if using monolithic module embodiments disclosed herein) for master cells with emitter and base busbars positioned on corners on the same side of the master cell (N is an even number) and the cells connected in electrical hybrid parallel-series. In this embodiment each master cell in a row of 10 master cells is connected in series and the 6 rows of 10 master cells are connected in parallel. In the hybrid parallel-series module interconnection embodiment shown in FIG. 26: module voltage=10× master cell voltage. Thus, for N=4 and S=16: master cell voltage Vₘₚ≈16×0.59≈9.4 V and module voltage Vₘₚ=10×9.4=94 V.

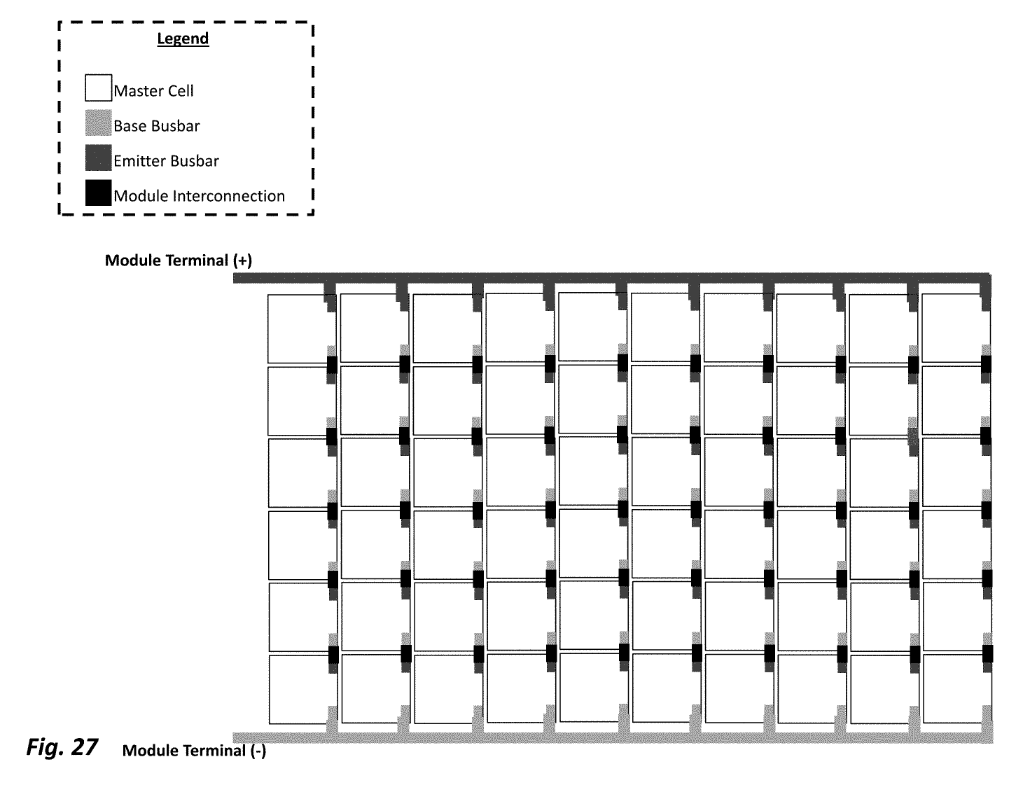

FIG. 27 is an alternative example of a module interconnection design (which is made using the patterned M2 layer if using monolithic module embodiments disclosed herein) for master cells with emitter and base busbars positioned on corners on the same side of the master cell (N is even number) and the cells connected in electrical hybrid parallel-series. In this embodiment each master cell in a column of 6 master cells is connected in series and the 10 columns of 6 master cells are connected in parallel. In the hybrid parallel-series module interconnection embodiment shown in FIG. 27: module voltage=6× master cell voltage. Thus, for N=4 and S=16: master cell voltage Vₘₚ≈16×0.59≈9.4 V; module voltage Vₘₚ=6×9.4=56.4 V; and module current Iₘₚ≈(9.3 A/16)×10≈5.81 A.

In some instances, the monolithically isled architecture disclosed herein may integrate an embedded module-level or a cell-level DC-to-DC (or DC-to-AC) power optimizer which may be mounted directly on the master cell backplane prior to final module lamination or embedded within the module laminate. The MPPT Power optimizer may be a high-conversion-efficiency (for example greater than 97% efficiency) monolithic or hybrid chip (possibly including some discrete components comprising at least an inductor and a capacitor) which converts cell DC output to either DC or AC output at a specified voltage or constant current (range). For example, a cell-level MPPT power optimizer chip may be used to produce AC cells while performing maximum-power-point tracking (MPPT), by converting master cell DC voltage and current (Vₘₚ and Iₘₚ) to AC voltage and current.

And if the master cells in a module are connected in all-series, the cell-level embedded MPPT may be set to produce a pre-specified fixed output current in each master cell under all illumination conditions while performing the MPPT power optimization function. This may ensure that all the master cells connected in series are current-matched. Similarly, if the master cells in the module are connected in a hybrid parallel-series arrangement, the cell-level embedded MPPT may be set to produce a pre-specified fixed output current in each master cell to provide a pre-specified parallel-string voltage under all illumination conditions while performing the MPPT power optimization function (and providing a pre-specified string voltage). This may ensure that all master cells or icells connected in series in each series string are current-matched while the parallel strings are also voltage matched.

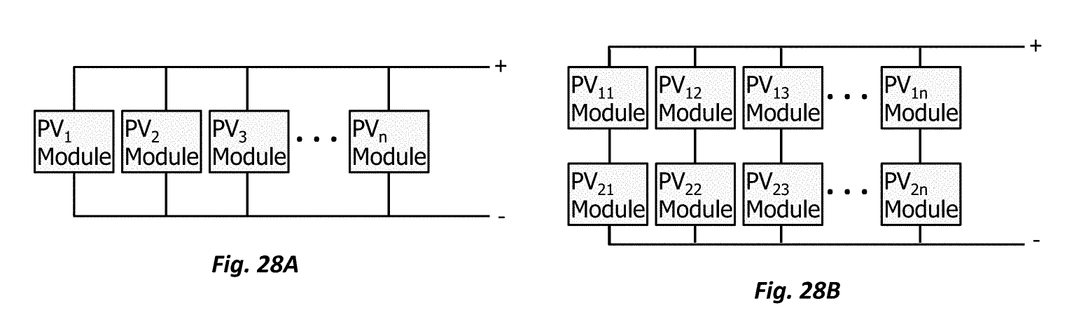

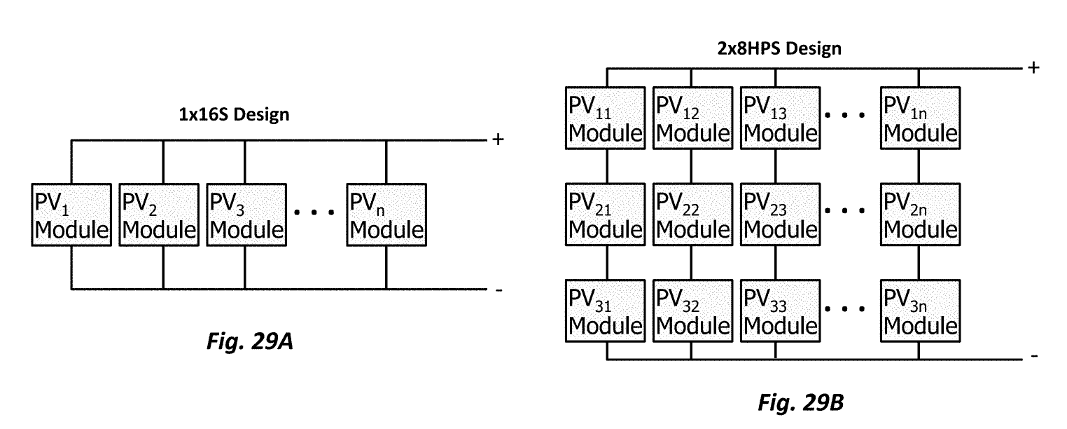

FIGS. 28A and 28B are diagrams showing some representative examples of module interconnections embodiments for a 600 VDC PV system. FIG. 28A shows example of module interconnections for a 1×16S (all-series) module design (60-cell modules) where V_{oc}=657.6 V and Vₘₚ=552.0 V and FIG. 28B shows module interconnection embodiments for a 2×8HPS (hybrid parallel-series) design (60-cell modules) where V_{oc}=657.6 V and Vₘₚ=552.0 V. FIGS. 29A and 29B are schematic diagrams showing module interconnections for a 1000 VDC PV system. FIG. 29A shows module interconnections for a 1×16S (all-series) design (60-cell modules) where V_{oc}=657.6 V and Vₘₚ=552.0 V and FIG. 28B shows module interconnections for a 2×8HPS (hybrid parallel-series) design (60-cell modules) where V_{oc}=986.4 V and Vₘₚ=828.0 V. Thus, Vₒₛ and Vₘₚ are increased in 2×8HPS design for a 1000 VDV PV system as compared to a 2×8HPS design for a 600 VDV PV system or a 1×16S design for 600 or 1000 VDV PV systems.

Thus, in some specific embodiments, a 2×8 Hybrid Parallel-Series (2×8HPS) interconnection design may be chosen for the following advantages:
Enable the use of pseudo-square crystalline silicon wafers to fabricate icells while maintaining important advantages of an all-series master cell (for example such as master cell flexibility due to straight bidirectional trench isolation scribe lines and an M2 metal layer with a thickness less than approximately 5 μm if applicable);
Current match/balance in pseudo-square crystalline silicon wafers, for example achieved by using L₁=3.964 cm, L₂=3.836 cm as shown (for 156 mm×156 mm wafers);
Also compatible with full-square master cell substrates, for example with L₁=L₂=3.9 cm as shown;
Providing efficient PV system arrangement for both 600 VDC and 1,000 VDC systems (as well as other system voltages) with reduced BOS cost and higher system efficiency. In some instances, a 1000 VDC PV system may have higher system-level efficiency and lower BOS costs as compared to a 600 VDC system. (It has been noted, due to higher efficiency and lower BOS cost, a higher string voltage (1,000 VDC vs. 600 VDC) may provide an economic value of approximately $0.10/W for an installed PV system). If desired, the module voltages can be set (e.g., lowered compared to an all-series module arrangement) by interconnections of the icells within the module according to a hybrid parallel-series configuration.
Integration of low-cost distributed shade-management (similar to a 1×16S design);
Integration of low-cost remote module ON/OFF (similar to a 1×16S design);
Integration of low-cost distributed cell-level MPPT (similar to a 1×16S design); and
May be considered more tolerant of master cell isle parametrics variations as compared to a 1×16S design.

The benefits of the innovative aspects disclosed herein include but are not limited to: (i) reduced solar cell manufacturing (fab) process equipment and facilities capital expenditures (CAPEX); (ii) substantially reduced hazardous waste byproducts in the solar cell fab; (iii) reduced solar cell microcracks and/or breakage (for instance, due to elimination of the need for copper plating and its associated handling, sealing, and contacting requirements) and enhanced overall manufacturing yield; (iv) improved projected long-term PV module field reliability; (v) reduced bow and mechanical stress for backplane-laminated solar cells due to elimination of the need for thick (typically 10's of microns for IBC solar cells) electroplated copper on the backside.

In operation, the disclosed subject matter provides monolithically isled master cells (icells) which may provide any combination of the following advantages: enhanced flexibility and crack mitigation; reduced cell bow and improved planarity; scaled-up voltage and scaled-down current, resulting in reduced RI2 ohmic losses; a reduction in cell metallization thickness (as much as 10×) may allow for the elimination of copper plating if desired which may reduce cell metallization cost (for example <5 μm Al); the elimination of thick metallization, such as thick-copper, reduces stress effects (and resulting cracks) during module lamination; distributed cell parametrics at test and sort; reduced current allows for an inexpensive shade-management switch; allows for the use of an inexpensive, high-efficiency (>98%) MPPT DC-DC buck converter; and a fully plating-free solar cell.

The foregoing description of the exemplary embodiments is provided to enable any person skilled in the art to make or use the claimed subject matter. Various modifications to these embodiments will be readily apparent to those skilled in the art, and the generic principles defined herein may be applied to other embodiments without the use of the innovative faculty. Thus, the claimed subject matter is not intended to be limited to the embodiments shown herein but is to be accorded the widest scope consistent with the principles and novel features disclosed herein.

1. A monolithic photovoltaic module structure, comprising:
(a) a plurality of monolithically-isled (or monolithically-tiled) solar cells, each of said solar cells comprising:
(i) a semiconductor layer with a background doping, comprising a sunlight-receiving frontside and a backside opposite said sunlight-receiving frontside;
(ii) a patterned first metal layer (M1) disposed on said semiconductor layer backside;
(b) an electrically insulating continuous backplane support layer attached to said semiconductor layer backsides of said plurality of monolithically-isled (or monolithically-tiled) solar cells, said solar cells positioned on and attached to said continuous backplane support layer according to a desired closely-spaced cell array pattern;
(c) a trench isolation pattern partitioning said semiconductor layer in each of said plurality of monolithically-isled (or monolithically-tiled) solar cells into a plurality of solar cell semiconductor regions on said electrically insulating continuous backplane support layer;
(d) a patterned second metal layer (M2) disposed on said electrically insulating continuous backplane support layer attached to said semiconductor layer backsides of said plurality of monolithically-isled (or monolithically-tiled) solar cells;
(e) a plurality of electrically conductive via plugs formed through said electrically insulating continuous backplane support layer interconnecting select portions of said patterned second-level metal layer to select portions of said patterned first-level metal layer in each of said plurality of monolithically-isled (or monolithically-tiled) solar cells;
(f) said patterned first-level metal layer, said patterned second-level metal layer, and said plurality of electrically conductive via plugs designed to complete the electrical metallization and interconnections within each of said monolithically-isled (or monolithically-tiled) solar cells, and among said plurality of monolithically-isled (or monolithically-tiled) solar cells based on a desired electrical interconnection arrangement comprising one or a combination of series, parallel, and hybrid parallel-series interconnections;
(g) optically transparent protective frontside cover and frontside encapsulation sheets attached to said electrically insulating continuous backplane support layer covering said sunlight-receiving frontsides of said plurality of monolithically-isled (or monolithically-tiled) solar cells;
(h) protective backside cover and backside encapsulation sheets attached to said electrically insulating continuous backplane support layer opposite said sunlight-receiving frontsides;
(i) at least a pair of electrical connector leads.

2. The monolithic photovoltaic module structure of claim 1, wherein said monolithic photovoltaic module is a flexible, lightweight module.

3. The monolithic photovoltaic module structure of claim 1, wherein said monolithic photovoltaic module is a rigid glass-covered module.

4. The monolithic photovoltaic module structure of claim 1, wherein said monolithic photovoltaic module is a building-integrated photovoltaic (BIPV) rooftop shingle module.

5. The monolithic photovoltaic module structure of claim 1, wherein said monolithic photovoltaic module is a building-integrated photovoltaic (BIPV) rooftop tile module.

6. The monolithic photovoltaic module structure of claim 1, wherein said monolithic photovoltaic module is an automotive sunroof module.

7. The monolithic photovoltaic module structure of claim 1, further comprising a plurality of bypass switches associated with said plurality of monolithically-isled (or monolithically-tiled) solar cells for distributed shade management.

8. The monolithic photovoltaic module structure of claim 1, further comprising a plurality of bypass Schottky diodes associated with said plurality of monolithically-isled (or monolithically-tiled) solar cells for distributed shade management.

9. The monolithic photovoltaic module structure of claim 1, further comprising a plurality of bypass pn junction diodes associated with said plurality of monolithically-isled (or monolithically-tiled) solar cells for distributed shade management.

10. The monolithic photovoltaic module structure of claim 1, further comprising a plurality of maximum-power-point-tracking (MPPT) power optimizers associated with said plurality of monolithically-isled (or monolithically-tiled) solar cells for enhanced power harvest.

11. A method of producing photovoltaic module laminate comprising a plurality of monolithically-integrated solar cell and bypass switch semiconductor structures, comprising:
(a) producing each of said monolithically-integrated solar cell and bypass switch semiconductor structures using a plurality of fabrication processes, comprising:
(i) performing at least a portion of said plurality of fabrication processes on a semiconductor layer, comprising a frontside surface and a backside surface;
(ii) attaching an electrically insulating continuous backplane to said backside surface of said semiconductor layer;
(iii) producing an isolation pattern through said semiconductor layer to form a plurality of isles, and to partition said solar cell and said bypass switch into separate semiconductor layer regions on said electrically insulating continuous backplane;
(iv) performing the remaining portion of said plurality of fabrication processes;
(b) electrically interconnecting and laminating said plurality of monolithically-integrated solar cell and bypass switch semiconductor structures to produce said photovoltaic module laminate.

12. The method of claim 11, wherein said photovoltaic module laminate is formed of a flexible photovoltaic material.

13. The method of claim 11, wherein said photovoltaic module laminate is formed of a rigid glass-covered photovoltaic material.

14. A method of producing photovoltaic module laminate comprising a plurality of integrated solar cell and bypass switch structures, comprising:
(a) producing each of said integrated solar cell and bypass switch structures using a plurality of processes, comprising:
(i) performing at least a portion of said plurality of processes on a semiconductor layer;
(ii) attaching a continuous backplane to a surface of said semiconductor layer;
(iii) producing an isolation pattern through said semiconductor layer to form a plurality of isles, and to partition said solar cell and said bypass switch on said continuous backplane;
(iv) performing the remaining portion of said plurality of processes;
(b) electrically interconnecting and laminating said plurality of integrated solar cell and bypass switch structures to produce said photovoltaic module laminate.

15. The method of claim 14, wherein said photovoltaic module laminate is formed of a flexible photovoltaic material.

16. The photovoltaic module laminate of claim 14, wherein said photovoltaic module laminate is formed of a rigid glass-covered photovoltaic material.

17. A monolithically isled semiconductor solar cell, comprising:
a master cell semiconductor substrate attached to a backside backplane, said master cell comprising a plurality of electrically isolated isles, each of said isles electrically isolated by isolation trenches formed through said master cell semiconductor substrate to said backside backplane, each of said isles comprising a light capturing frontside surface and a backside surface for forming emitter and base contacts; and
emitter regions and base regions positioned on said backside surface of said isles; said backside backplane comprising an electrically conductive metallization layer having a pattern of emitter electrodes and base electrodes corresponding to said emitter regions and said base regions.

67.-76. (canceled)

101.-107. (canceled)
